(19) United States
(12) Patent Application Publication
(10) Pub. No.: US 2026/0206416 A1
(43) Pub. Date: Jul. 16, 2026

(54) SEMICONDUCTOR DEVICE AND ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Takanori MATSUZAKI, Atsugi, Kanagawa (JP); Yoshiaki OIKAWA, Atsugi, Kanagawa (JP); Kensuke YOSHIZUMI, Atsugi, Kanagawa (JP); Natsuko TAKASE, Isehara, Kanagawa (JP); Atsushi MIYAGUCHI, Hadano, Kanagawa (JP)

(21) Appl. No.: 19/135,126

(22) PCT Filed: Dec. 21, 2023
(86) PCT No.: PCT/IB2023/063062

§ 371 Date: Jun. 3, 2025

(30) Foreign Application Priority Data
Dec. 28, 2022 (JP) 2022-211818

(51) Int. Cl. H10K 59/121; H10D 86/40; H10D 86/60; H10K 59/12

(52) U.S. Cl. CPC H10K 59/1213; H10D 86/423; H10D 86/60; H10K 59/1201

(57) ABSTRACT

Provided is an electronic device with a novel structure. A display portion includes a first element layer including a light-emitting device, a second element layer including a first transistor, and a third element layer including a second transistor. The second element layer is positioned below the first element layer. The third element layer is positioned below the second element layer. The first transistor is a transistor included in a pixel circuit. The second transistor is a transistor included in a driver circuit. The light-emitting device is an organic EL element. The pixel circuit has a function of controlling luminance of the organic EL element. The driver circuit has a function of controlling driving of the pixel circuit. The display portion has a diagonal size greater than or equal to 1.0 inches and less than or equal to 2.5 inches.

### TECHNICAL FIELD

One embodiment of the present invention relates to a semiconductor device. Another embodiment of the present invention relates to an electronic device including the semiconductor device.

One embodiment of the present invention is not limited to the above technical field. Examples of a technical field of one embodiment of the present invention disclosed in this specification and the like include a display apparatus, a light-emitting apparatus, a power storage device, a memory device, an electronic device, a lighting device, an input device, an input/output device, a driving method thereof, and a manufacturing method thereof.

### BACKGROUND ART

In recent years, electronic devices including semiconductor devices have been widely used. Examples of the electronic devices include HMDs (Head Mounted Displays) suitable for an XR (Extended Reality or Cross Reality) application such as virtual reality (VR) and augmented reality (AR). HMDs are capable of displaying a video showing 360-degree view of the user's surroundings in accordance with the motion of the user's head or the user's gaze or operation; thus, the user can have a high sense of immersion and a high realistic sensation.

An HMD has a structure in which the user sees an image displayed on a semiconductor device and magnified by an optical member or the like. In this case, there is a possibility that the size of a housing is increased because of the presence of the optical member or a possibility that the user easily sees pixels and strongly senses graininess; hence, the semiconductor device is required to have high resolution and a smaller size. For example, an HMD that includes minute pixels using transistors capable of high-speed driving is disclosed (see Patent Document 1).

Wearable devices that perform mobile communication or the like are also electronic devices utilizing semiconductor devices. For example, an arm-worn electronic device may have a structure in which, in addition to a display, a variety of sensors, a CPU for controlling the sensors, a memory for storing data, and the like are included (see Patent Document 2).

### REFERENCES

### Patent Documents

[Patent Document 1] Japanese Published Patent Application No. 2000-2856
[Patent Document 2] PCT International Publication No. 2016/036472

### SUMMARY OF THE INVENTION

### Problems to be Solved by the Invention

A semiconductor device that can be used for a VR device, an AR device, a wearable device, or the like, in particular, an electronic device including the semiconductor device, is required to have a screen as large as possible while manufacturing cost is reduced.

In order to improve the display quality, a semiconductor device including a high-luminance and high-resolution display portion is required. Meanwhile, when the pixel density of the semiconductor device including a high-luminance and high-resolution display portion is increased, a problem of color mixture between adjacent pixels might arise. Furthermore, the semiconductor device including a high-resolution display portion has a problem in that power consumption is increased because it is necessary to transmit and receive an enormous amount of image data or it is necessary to perform arithmetic processing necessary for drawing processing.

In view of the above problems, an object of one embodiment of the present invention is to provide a novel semiconductor device. Alternatively, an object of one embodiment of the present invention is to provide a semiconductor device with an optimized screen size. Alternatively, an object of one embodiment of the present invention is to provide a semiconductor device with increased resolution and reduced color mixture between pixels. Alternatively, an object of one embodiment of the present invention is to provide a semiconductor device with reduced power consumption. Alternatively, an object of one embodiment of the present invention is to provide a semiconductor device with reduced weight. Alternatively, an object of one embodiment of the present invention is to provide a semiconductor device with high drawing processing capability.

The description of these objects does not preclude the existence of other objects. One embodiment of the present invention does not need to achieve all of these objects. Objects other than these can be derived from the description of the specification, the drawings, the claims, and the like.

### Means for Solving the Problems

One embodiment of the present invention is a semiconductor device including a display portion. The display portion includes a first element layer including a light-emitting device and a second element layer including a first transistor. The second element layer is positioned below the first element layer. The first transistor includes an oxide semiconductor in a semiconductor layer including a channel formation region. The first transistor is a transistor included in a pixel circuit for controlling driving of the light-emitting device. The display portion has a diagonal size greater than or equal to 1.0 inches and less than or equal to 2.5 inches.

One embodiment of the present invention is a semiconductor device including a display portion. The display portion includes a first element layer including a light-emitting device and a second element layer including a first transistor. The second element layer is positioned below the first element layer. The first transistor includes an oxide semiconductor in a semiconductor layer including a channel formation region. The first transistor is a transistor included in a pixel circuit. The light-emitting device is an organic EL element. The pixel circuit has a function of controlling luminance of the organic EL element. The display portion has a diagonal size greater than or equal to 1.0 inches and less than or equal to 2.5 inches.

One embodiment of the present invention is a semiconductor device including a display portion. The display portion includes a first element layer including a light-emitting device, a second element layer including a first transistor, and a third element layer including a second transistor. The second element layer is positioned below the first element layer. The third element layer is positioned below the second element layer. The first transistor is a transistor included in a pixel circuit. The second transistor is a transistor included in a driver circuit. The light-emitting device is an organic EL element. The pixel circuit has a function of controlling luminance of the organic EL element. The driver circuit has a function of controlling driving of the pixel circuit. The display portion has a diagonal size greater than or equal to 1.0 inches and less than or equal to 2.5 inches.

In the semiconductor device of one embodiment of the present invention, each of the first transistor and the second transistor preferably includes an oxide semiconductor in a semiconductor layer including a channel formation region.

In the semiconductor device of one embodiment of the present invention, the first transistor preferably includes an oxide semiconductor in a semiconductor layer including a channel formation region, and the second transistor preferably includes silicon in a semiconductor layer including a channel formation region.

One embodiment of the present invention is an electronic device in which any one of the above-described semiconductor devices is provided in a housing, and the housing is provided with an operation portion and a band.

### Effect of the Invention

According to one embodiment of the present invention, a novel semiconductor device can be provided. Alternatively, according to one embodiment of the present invention, a semiconductor device with an optimized screen size can be provided. Alternatively, according to one embodiment of the present invention, a semiconductor device with increased resolution and reduced color mixture between pixels can be provided. Alternatively, according to one embodiment of the present invention, a semiconductor device with reduced power consumption can be provided. Alternatively, according to one embodiment of the present invention, a semiconductor device with reduced weight can be provided. Alternatively, according to one embodiment of the present invention, a semiconductor device with high drawing processing capability can be provided.

The description of these effects does not preclude the existence of other effects. One embodiment of the present invention does not necessarily have all of these effects. Effects other than these can be derived from the description of the specification, the drawings, the claims, and the like.

### BRIEF DESCRIPTION OF THE DRAWINGS

FIG. 1A to FIG. 1F are diagrams for illustrating the size of a display portion and a light-exposure region.

FIG. 2A and FIG. 2B are diagrams for illustrating examples of the number of chips obtained from a Si wafer.

FIG. 3A and FIG. 3B are diagrams for illustrating examples of the number of chips obtained from a Si wafer.

FIG. 4A and FIG. 4B are diagrams for illustrating examples of the number of chips obtained from a Si wafer.

FIG. 5A and FIG. 5B are diagrams for illustrating a structure example of a semiconductor device.

FIG. 6A and FIG. 6B are diagrams for illustrating structure examples of a semiconductor device and an electronic device.

FIG. 7A to FIG. 7D are diagrams for illustrating structure examples of a semiconductor device.

FIG. 8A and FIG. 8B are diagrams for illustrating a structure example of a semiconductor device.

FIG. 9A to FIG. 9C are diagrams for illustrating a structure example of a semiconductor device.

FIG. 10A and FIG. 10B are diagrams for illustrating structure examples of an electronic device.

FIG. 11 is a flowchart showing a structure example of an electronic device.

FIG. 12A to FIG. 12F are diagrams for illustrating a structure example of a semiconductor device.

FIG. 13A to FIG. 13C are diagrams illustrating structure examples of a semiconductor device.

FIG. 14A and FIG. 14B are diagrams illustrating a structure example of a semiconductor device.

FIG. 15A and FIG. 15B are diagrams for illustrating a structure example of a semiconductor device.

FIG. 16A and FIG. 16B are diagrams for illustrating structure examples of a semiconductor device.

FIG. 17A and FIG. 17B are diagrams for illustrating a structure example of a semiconductor device.

FIG. 18A to FIG. 18C are diagrams for illustrating a structure example of a semiconductor device or an electronic device.

FIG. 19A and FIG. 19B are circuit diagrams illustrating a structure example of a pixel circuit.

FIG. 20A to FIG. 20D are circuit diagrams illustrating structure examples of pixel circuits.

FIG. 21A to FIG. 21D are circuit diagrams illustrating structure examples of pixel circuits.

FIG. 22 is a block diagram for illustrating a structure example of an arithmetic unit.

FIG. 23A and FIG. 23B are circuit diagrams for illustrating a structure example of an arithmetic unit.

FIG. 24A and FIG. 24B are a block diagram and a circuit diagram illustrating a structure example of a memory circuit.

FIG. 25A to FIG. 25F are circuit diagrams illustrating structure examples of memory circuits.

FIG. 26A to FIG. 26C are diagrams illustrating structure examples of semiconductor devices and input/output systems.

FIG. 27A to FIG. 27D are diagrams illustrating examples of semiconductor devices and an image on an input/output system.

FIG. 28 is a flowchart showing an example of an operation method of an input/output system.

FIG. 29 is a schematic cross-sectional view illustrating a structure example of a semiconductor device.

FIG. 30 is a schematic cross-sectional view illustrating a structure example of a semiconductor device.

FIG. 31 is a schematic cross-sectional view illustrating a structure example of a semiconductor device.

FIG. 32A to FIG. 32C are schematic cross-sectional views illustrating a structure example of a semiconductor device.

FIG. 33A and FIG. 33B are schematic cross-sectional views illustrating a structure example of a semiconductor device.

FIG. 34A is a schematic top view illustrating a structure example of a semiconductor device. FIG. 34B to FIG. 34D are schematic cross-sectional views illustrating the structure example of the semiconductor device.

FIG. 35A to FIG. 35D are schematic cross-sectional views illustrating an example of a manufacturing method of a device.

FIG. 36A to FIG. 36F are schematic cross-sectional views illustrating structure examples of a light-emitting device.

FIG. 37A to FIG. 37C are schematic cross-sectional views illustrating structure examples of a light-emitting device.

### MODE FOR CARRYING OUT THE INVENTION

Embodiments of the present invention will be described below. Note that one embodiment of the present invention is not limited to the following description, and it will be readily understood by those skilled in the art that modes and details of the present invention can be modified in various ways without departing from the spirit and scope of the present invention. One embodiment of the present invention therefore should not be construed as being limited to the following description of the embodiments.

Ordinal numbers such as “first”, “second”, and “third” in this specification and the like are used in order to avoid confusion among components. Thus, the ordinal numbers do not limit the number of components. In addition, the ordinal numbers do not limit the order of components. Furthermore, in this specification and the like, for example, a “first” component in one embodiment can be referred to as a “second” component in other embodiments or the scope of claims. Moreover, in this specification and the like, for example, a “first” component in one embodiment can be omitted in other embodiments or the scope of claims.

In some cases, the same components, components having similar functions, components made of the same material, components formed at the same time, or the like are denoted by the same reference numerals in the drawings and repeated description thereof is omitted.

In this specification, for example, a power supply potential VDD is sometimes abbreviated to a potential VDD, VDD, or the like. The same applies to other components (e.g., a signal, voltage, a circuit, an element, an electrode, and a wiring).

In the case where a plurality of components are denoted by the same reference numerals, and, particularly when they need to be distinguished from each other, an identification sign such as “_1”, “_2”, “[n]”, or “[m,n]” is sometimes added to the reference numerals. For example, a second wiring GL is referred to as a wiring GL_2.

### Embodiment 1

In this embodiment, a semiconductor device of one embodiment of the present invention will be described.

The semiconductor device of one embodiment of the present invention can be used for an electronic device including a display portion. In particular, the semiconductor device of one embodiment of the present invention can be suitably used for an electronic device for an AR device, an electronic device for a VR device, or an electronic device for a wearable device (typified by a watch-type device). The semiconductor device of one embodiment of the present invention can include a display portion, and the pixel density (resolution) of the display portion can be higher than or equal to 1000 ppi and lower than or equal to 10000 ppi. The pixel density can be, for example, higher than or equal to 2000 ppi and lower than or equal to 6000 ppi, or higher than or equal to 3000 ppi and lower than or equal to 5000 ppi.

There is no particular limitation on the screen ratio (aspect ratio) of the display portion. The display portion is compatible with a variety of screen ratios such as 1:1 (a square), 4:3, 16:9, and 16:10, for example. There is no particular limitation on the outer shape of the display portion, and a variety of structures such as a square, a rectangle, and a circle can be employed.

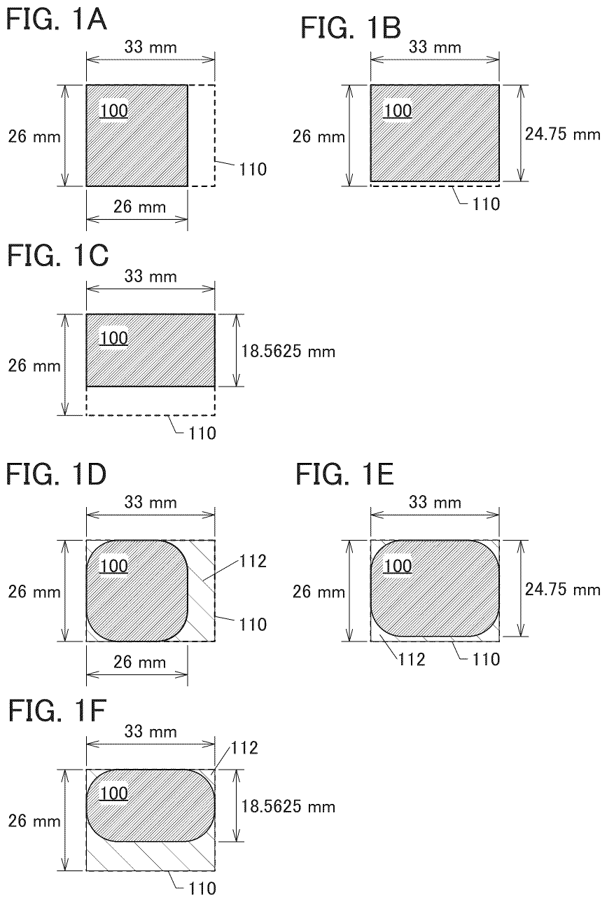

Here, the relation between the size of the semiconductor device and a light-exposure region of a light-exposure apparatus will be described with reference to FIG. TA to FIG. 1F. The following description is made using a semiconductor device 100 and a light-exposure region 110 that is a light-exposure region of a light-exposure apparatus. The semiconductor device 100 in FIG. 1 is described by being rephrased as a chip in some cases. Alternatively, the semiconductor device 100 is described as a display portion of an electronic device in some cases.

### <Size of Semiconductor Device and Light-Exposure Region>

As illustrated in FIG. TA to FIG. 1C, in the case where the maximum value of the light-exposure region 110 of the light-exposure apparatus is “26 mm×33 mm”, the maximum size of the semiconductor device 100 that can be manufactured in one light exposure is “26 mm×26 mm” when the aspect ratio is 1:1, “33 mm×24.75 mm” when the aspect ratio is 4:3, and “33 mm×18.5625 mm” when the aspect ratio is 16:9.

As the maximum value of the light-exposure region 110 of the light-exposure apparatus, “26 mm×33 mm” is a current mainstream; therefore, the description below is considered with reference to “26 mm×33 mm”. When the maximum value of the light-exposure region 110 is “26 mm×33 mm”, the size of the semiconductor device 100 that can be obtained with one light exposure (1 shot) is “26 mm×33 mm”.

By considering the size of the semiconductor device 100 based on the light-exposure region 110 of the light-exposure apparatus as illustrated in FIG. 1A to FIG. 1C, a semiconductor device with an optimal manufacturing cost can be manufactured. As the light-exposure apparatus, for example, a stepper, a scanner, and the like can be used. A light source that can be used for the light-exposure apparatus has a wavelength of 13 nm (EUV (Extreme Ultra Violet)), 157 nm (F₂), 193 nm (ArF), 248 nm (KrF), 308 nm (XeCl), 365 nm (an i-line), 436 nm (a g-line), and the like. With the light source having a short wavelength, a high-resolution or miniaturized semiconductor device can be obtained.

In the case where the semiconductor device of one embodiment of the present invention is used for an electronic device for XR (AR, VR, or the like), the size of a display portion of the electronic device is suitably greater than or equal to the size of an eyeball of a human being (approximately 23-24 mm) because in that case, the entire eye or the entire field of view can be covered. For example, when the display portion has a diagonal length (diagonal size) of greater than or equal to 1.0 inches and less than or equal to 2.5 inches, preferably greater than or equal to 1.4 inches and less than or equal to 2.5 inches, further preferably greater than or equal to 1.5 inches and less than or equal to 2.5 inches, the semiconductor device can be placed such that the user's field of view is entirely covered with the display portion. Thus, the use of the semiconductor device of one embodiment of the present invention for an electronic device or an input/output system can provide a higher level of one or more selected from immersion, realistic sensation, and sense of depth.

The above values are each the maximum size of the display portion; thus, the actual outer shape size of the semiconductor device is larger than or equal to that of the display portion, in some cases. In addition, the aspect ratio of the outer shape of the semiconductor device may be the same as or different from the aspect ratio of the display portion.

The size of the display portion is not limited to the above sizes. For example, in the case where the semiconductor device of one embodiment of the present invention is used for a wearable device (e.g., a watch-type device) or an electronic device such as a smartphone or a TV, the size can be greater than 2.5 inches, for example, greater than or equal to 3 inches and less than or equal to 100 inches.

Next, variation examples of the semiconductor device 100 illustrated in FIG. 1A to FIG. 1C are illustrated in FIG. 1D to FIG. 1F.

FIG. 1D to FIG. 1F each illustrate a shape in which fillets are added to corner portions of the semiconductor device 100 (a shape obtained by a process of rounding the corner portions). Although not illustrated, a shape in which the corner portions of the semiconductor device 100 are chamfered (a shape in which the corner portions are removed) may be employed. When the corner portions of the semiconductor device 100 have shapes in which fillets or chamfers are added, a well-designed electronic device including a display portion can be obtained. In the case where the semiconductor device 100 is used for an AR device or a VR device, a lens for zooming in or out the screen is provided in the vicinity of the semiconductor device 100 in some cases. General-use lenses often have circular shapes and thus have structures that make it difficult to efficiently use the corner portions of the semiconductor device 100. Accordingly, even when the semiconductor device 100 has a shape in which the corner portions are rounded or a shape in which the corner portions are chamfered, the display quality of an image seen by the user is unlikely to be reduced.

In FIG. 1D to FIG. 1F, a region 112 is illustrated as a region where the semiconductor device 100 and the light-exposure region 110 do not overlap with each other. An alignment marker or the like used in light exposure is provided in the region 112, for example. Providing the alignment marker or the like in the region 112 can increase the manufacturing yield of the semiconductor device and can increase the number of chips obtained from a silicon wafer (hereinafter, also referred to as a Si wafer). That is, a semiconductor device with reduced manufacturing cost can be provided. As well as the alignment marker, a variety of markers necessary for the manufacturing process such as length measurement markers and evaporation markers may be provided in the region 112.

### <Number of Chips Obtained>

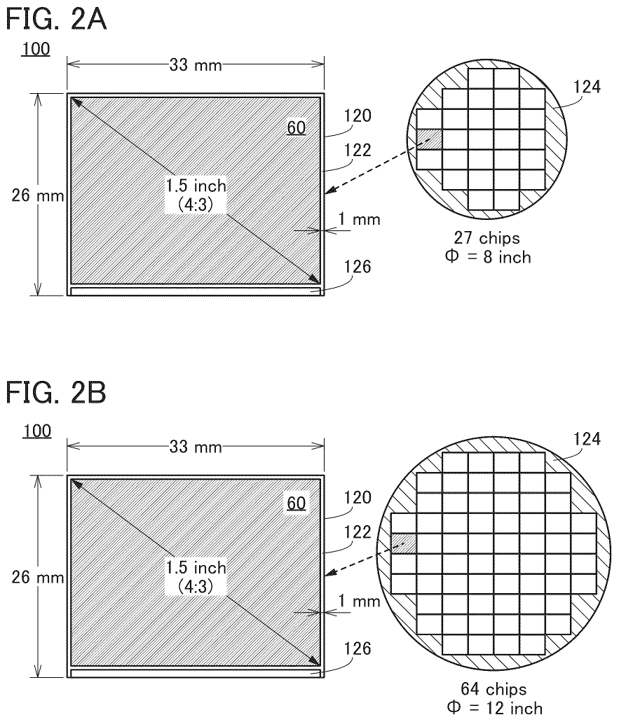

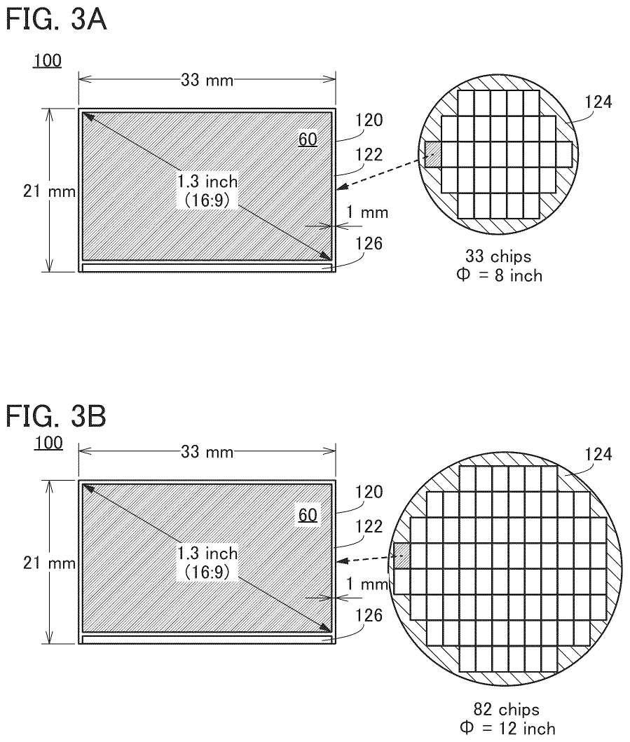

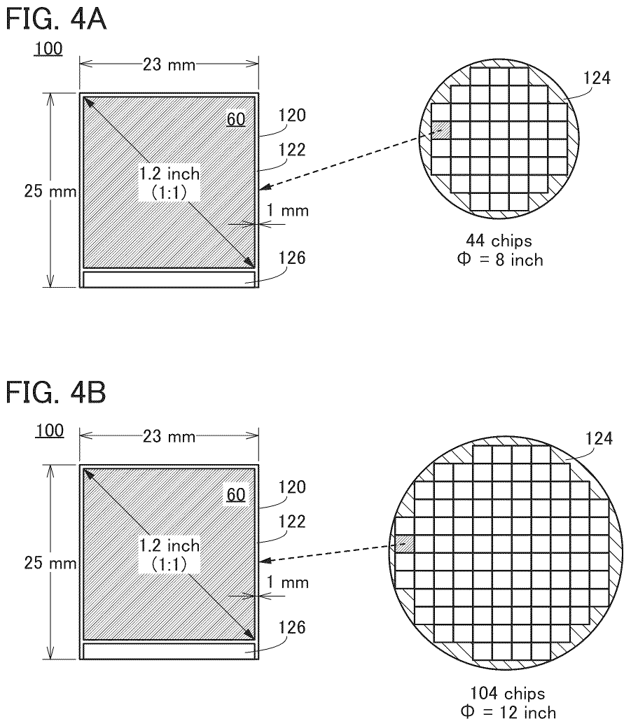

Next, examples of the number of chips obtained from a Si wafer are described. FIG. 2A, FIG. 3A, and FIG. 4A each illustrate the number of chips obtained from one Si wafer, assuming a 48-inch Si wafer, and FIG. 2B, FIG. 3B, and FIG. 4B each illustrate the number of chips obtained from one Si wafer, assuming a φ12-inch Si wafer. In the following description, “#” in “φ8-inch” and “412-inch” means the diameter of a Si wafer. A 48-inch Si wafer is referred to as a “48-inch wafer” in some cases.

Referring to FIG. 2A to FIG. 4B, the description is made using a light-exposure region 120 that is a light-exposure region of a light-exposure apparatus, a display portion 60 provided inside the light-exposure region 120, a sealing region 122 that is a region provided between the display portion 60 and the light-exposure region 120, and a terminal region 126 that is a region provided on one side of the light-exposure region 120, in the semiconductor device 100, and an out-of-chip region 124 that is a region not used after chips are obtained from a Si wafer. A marker region or the like may be provided in the sealing region 122.

Although FIG. 2A to FIG. 4B each illustrate a structure example in which a terminal region that can be connected to an external device is provided as the terminal region 126, one embodiment of the present invention is not limited thereto. For example, a structure may be employed in which the terminal region 126 is not provided and an external device can be connected to the back surface of a chip using a through electrode or the like. Such a structure achieves a large display region. A structure in which the terminal region 126 is provided as illustrated in FIG. 2A to FIG. 4B, on the other hand, brings about an effect of reducing manufacturing cost because there is no need to newly form a terminal that can be connected to an external device.

FIG. 2A and FIG. 2B each illustrate an example in which the sealing region 122 with a width of 1 mm is provided inside the light-exposure region 120 of 33 mm×26 mm. Note that here, the sealing region 122 indicates a region from an end portion of the display portion 60 to a dividing position of a substrate or a position of a terminal, and not necessarily indicates a region to which a sealant is applied. In that case, the display portion 60 has a diagonal size of approximately 1.5 inches and the aspect ratio thereof is 4:3 (hereinafter referred to as 1.5 inches (4:3)).

As illustrated in FIG. 2A, 27 chips with 1.5 inches (4:3) can be obtained from a φ8-inch Si wafer, and as illustrated in FIG. 2B, 64 chips with 1.5 inches (4:3) can be obtained from a φ12-inch Si wafer. At this time, the out-of-chip region 124 illustrated in FIG. 2A accounts for 26% of the φ8-inch Si wafer, assuming the area of the wafer is 100%. Furthermore, the out-of-chip region 124 illustrated in FIG. 2B accounts for 22% of the φ12-inch Si wafer, assuming the area of the wafer is 100%.

As illustrated in FIG. 2A and FIG. 2B, the number of chips obtained can be larger and the proportion of the out-of-chip region 124 can be lower in the case of using the φ12-inch Si wafer than in the case of using the φ8-inch Si wafer, and the number of chips obtained from the φ12-inch Si wafer can be 2.37 times as large as the number of chips obtained from the φ8-inch Si wafer.

FIG. 3A and FIG. 3B each illustrate an example in which the sealing region 122 with a width of 1 mm is provided inside the light-exposure region 120 of 33 mm×21 mm. Here, the structure of the sealing region 122 is similar to the structure illustrated in FIG. 2A and FIG. 2B. In that case, the display portion 60 has a diagonal size of approximately 1.3 inches and the aspect ratio thereof is 16:9 (hereinafter referred to as 1.3 inches (16:9)).

As illustrated in FIG. 3A, 33 chips with 1.3 inches (16:9) can be obtained from a φ8-inch Si wafer, and as illustrated in FIG. 3B, 82 chips with 1.3 inches (16:9) can be obtained from a φ12-inch Si wafer. At this time, the out-of-chip region 124 illustrated in FIG. 3A accounts for 27% of the φ8-inch Si wafer, assuming the area of the wafer is 100%. Furthermore, the out-of-chip region 124 illustrated in FIG. 3B accounts for 20% of the φ12-inch Si wafer, assuming the area of the wafer is 100%.

As illustrated in FIG. 3A and FIG. 3B, the number of chips obtained can be larger and the proportion of the out-of-chip region 124 can be lower in the case of using the φ12-inch Si wafer than in the case of using the φ8-inch Si wafer, and the number of chips obtained from the φ12-inch Si wafer can be 2.48 times as large as the number of chips obtained from the φ8-inch Si wafer.

FIG. 4A and FIG. 4B each illustrate an example in which the sealing region 122 with a width of 1 mm is provided inside the light-exposure region 120 of 23 mm×25 mm. Here, the structure of the sealing region 122 is similar to the structure illustrated in FIG. 2A and FIG. 2B. In that case, the display portion 60 has a diagonal size of approximately 1.2 inches and the aspect ratio thereof is 1:1 (hereinafter referred to as 1.2 inches (1:1)).

As illustrated in FIG. 4A, 44 chips with 1.2 inches (1:1) can be obtained from a φ8-inch Si wafer, and as illustrated in FIG. 4B, 104 chips with 1.2 inches (1:1) can be obtained from a φ12-inch Si wafer. At this time, the out-of-chip region 124 illustrated in FIG. 4A accounts for 19% of the 48-inch Si wafer, assuming the area of the wafer is 100%. Furthermore, the out-of-chip region 124 illustrated in FIG. 4B accounts for 15% of the 412-inch Si wafer, assuming the area of the wafer is 100%.

As illustrated in FIG. 4A and FIG. 4B, the number of chips obtained can be larger and the proportion of the out-of-chip region 124 can be lower in the case of using the 4φ12-inch Si wafer than in the case of using the φ8-inch Si wafer, and the number of chips obtained from the 4φ12-inch Si wafer can be 2.36 times as large as the number of chips obtained from the φ8-inch Si wafer.

Here, Table 1 shows the numbers of chips obtained from a φ8-inch Si wafer and a φ12-inch Si wafer. Table 1 is a table summarizing the structures illustrated in FIG. 2A to FIG. 4B.

TABLE 1

| | 4:3 (1.5 | 16:9 (1.3 | 1:1 (1.2 |
|---|---|---|---|
| | inches) | inches) | inches) |
| The number of chips obtained from a | 27 | 33 | 44 |
| φ8-inch wafer | | | |
| The number of chips obtained from a | 64 | 82 | 104 |
| φ12-inch wafer | | | |

As shown in Table 1, a reduction in the diagonal size of a chip can increase the number of chips obtained from a Si wafer. In the case where the display portion (screen size) of the semiconductor device is desired to be increased, on the other hand, a structure with 4:3, that is, a structure with 1.5 inches is preferable.

### Structure Example of Semiconductor Device

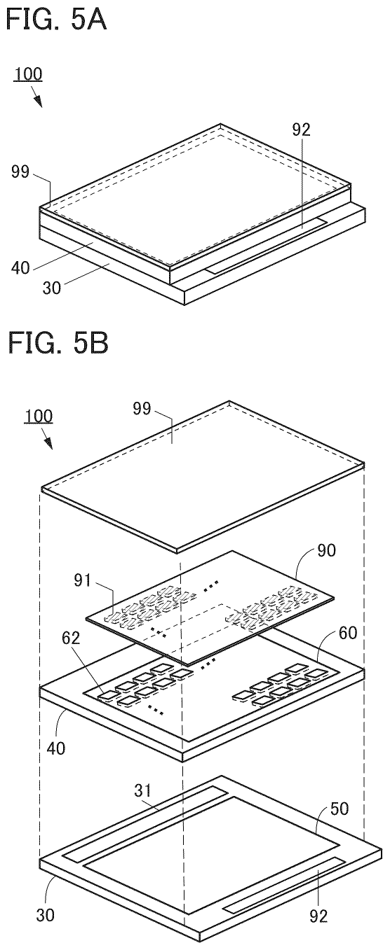

Next, a structure example of the semiconductor device of one embodiment of the present invention will be described with reference to FIG. 5A and FIG. 5B. FIG. 5A and FIG. 5B are perspective views for illustrating the semiconductor device of one embodiment of the present invention.

The semiconductor device 100 includes an element layer 30, an element layer 40, and an element layer 90 provided with elements such as transistors and light-emitting elements. The semiconductor device 100 includes, in the element layer 40, the display portion 60 in a region where a pixel circuit 62 is provided. The semiconductor device 100 includes, in the element layer 40, a region where a light-emitting device 91 such as an organic EL element is provided. The display portion 60 is a region where the pixel circuit 62 and the light-emitting device 91 are stacked and is a region where an image is displayed in the semiconductor device 100. The pixel circuit 62 and the light-emitting device 91 are collectively referred to as a pixel, which is the minimum unit for displaying an image, in some cases.

By using pixels arranged in a matrix of 1920×1080, the display portion 60 can achieve display with a definition of a so-called full hi-vision (also referred to as “2K definition”, “2K1K”, “2K”, or the like). For example, by using pixels arranged in a matrix of 3840×2160, the display portion 60 can achieve display with a definition of a so-called ultra hi-vision (also referred to as “4K definition”, “4K2K”, “4K”, or the like). For example, by using pixels arranged in a matrix of 7680×4320, the display portion 60 can achieve display with a definition of a so-called super hi-vision (also referred to as “8K definition”, “8K4K”, “8K”, or the like). By increasing the number of pixels, the display portion 60 that can achieve display with 16K or 32K definition can also be obtained.

The semiconductor device 100 can display an image in the following manner: a variety of signals and power supply potentials are input from the outside via a terminal portion 92, the display portion 60 controls the pixel circuit 62, and the luminance of the light-emitting device 91 is controlled. A variety of elements can be used as the light-emitting device 91. A light-emitting device having a function of emitting light, such as an organic EL element or an LED element can be typically used. Instead of a light-emitting device, a liquid crystal element, a MEMS (Micro Electro Mechanical Systems) element, or the like may be employed.

The semiconductor device 100 is provided with, in the element layer 30, a display control portion 50 including a driver circuit having a function of controlling the pixel circuit 62, a logic circuit portion 31 that controls the display control portion 50 in accordance with image data displayed on the display portion 60, and the like. FIG. 5A illustrates a structure example in which the element layer 40 is provided over the element layer 30 and a sealing substrate 99 is provided thereover.

In the element layer 30, a transistor containing silicon in its channel formation region (also referred to as a “Si transistor” or a “SiFET”) or a transistor containing an oxide semiconductor in its channel formation region (also referred to as an “OS transistor” or an “OSFET”) can be used. With the use of a Si transistor in the element layer 30, a semiconductor device with increased driving capability can be obtained. With the use of an OS transistor in the element layer 30, on the other hand, a semiconductor device with reduced power consumption can be obtained. An OS transistor has a characteristic of an extremely low off-state current. Thus, when an OS transistor is used as, in particular, a transistor provided in a pixel circuit, analog data written to the pixel circuit can be retained for a long period.

In this embodiment, a structure using a silicon substrate is described as an example of the element layer 30. A silicon substrate is preferable because of having higher thermal conductivity than a glass substrate. By providing the terminal portion 92, the display control portion 50, and the logic circuit portion 31 in the same layer, wirings electrically connecting the terminal portion 92, the display control portion 50, and the logic circuit portion 31 can be short. As a result, charging and discharging time of a control signal for controlling the terminal portion 92, the display control portion 50, and the logic circuit portion 31 becomes short, leading to a reduction in power consumption.

A transistor containing polycrystalline silicon in its channel formation region (also referred to as a “Poly-Si transistor”) may be provided in the element layer 30. As the polycrystalline silicon, low-temperature polysilicon (LTPS) may be used. A transistor containing LTPS in its channel formation region is also referred to as an “LTPS transistor”.

A variety of circuits such as a shift register, a level shifter, an inverter, a latch, an analog switch, and a logic circuit can be used as the display control portion 50. The display control portion 50 is provided with a plurality of driver circuit portions including a gate driver circuit, a source driver circuit, and the like, for example. In addition, an arithmetic circuit, a memory circuit, a power supply circuit, and the like may be included. Since the display control portion 50 can be placed to overlap with the display portion 60, the width of a non-display region (also referred to as a bezel) present along the outer periphery of the display portion 60 of the semiconductor device 100 can be extremely narrow as compared with the case where the display control portion 50 and the display portion 60 are arranged side by side, whereby the semiconductor device 100 can be downsized.

The logic circuit portion 31 has a function of an application processor for controlling the circuits in the semiconductor device 100 and generating signals used for controlling the circuits, for example. The logic circuit portion 31 may include a circuit for correcting image data, like a CPU and an accelerator such as a GPU. The logic circuit portion 31 may include an LVDS (Low Voltage Differential Signaling) circuit, an MIPI (Mobile Industry Processor Interface) circuit, and a D/A (Digital to Analog) converter circuit, for example, having a function of an interface for receiving image data or the like from the outside of the semiconductor device 100. The logic circuit portion 31 may include a circuit for compressing and decompressing image data and a power supply circuit, for example.

The element layer 40 is provided over the element layer 30. The element layer 40 includes a plurality of the pixel circuits 62. An OS transistor may be provided in the element layer 40. Each of the pixel circuits 62 may include an OS transistor. The element layer 40 can be stacked over the element layer 30.

A Si transistor may be provided in the element layer 40. The pixel circuits 62 may each include a transistor containing single crystal silicon or polycrystalline silicon in its channel formation region, for example. As the polycrystalline silicon, LTPS may be used. The element layer 40 can be formed over another substrate and bonded to the element layer 30, for example.

As another example, the pixel circuits 62 may each include a plurality of kinds of transistors using different semiconductor materials. In the case where the pixel circuits 62 each include a plurality of kinds of transistors using different semiconductor materials, the transistors may be provided in different layers for each kind of transistor. For example, in the case where the pixel circuits 62 each include a Si transistor and an OS transistor, the Si transistor and the OS transistor may be provided to overlap with each other. Providing the transistors to overlap with each other reduces the area occupied by the pixel circuits 62. Thus, the resolution of the semiconductor device 100 can be improved. A structure in which an LTPS transistor and an OS transistor are combined is referred to as LTPO in some cases.

The element layer 90 is provided over the element layer 40. The sealing substrate 99 is provided over the element layer 90. The sealing substrate 99 is preferably a light-transmitting substrate or a layer formed of a light-transmitting material. The element layer 90 includes a plurality of the light-emitting devices 91. The element layer 90 can be stacked over the element layer 40. As the light-emitting device 91, an organic electroluminescent element (also referred to as an organic EL element) or the like can be used, for example. However, the light-emitting device 91 is not limited thereto, and an inorganic EL element formed of an inorganic material may be used, for example. An “organic EL element” and an “inorganic EL element” are collectively referred to as an “EL element” in some cases. The light-emitting device 91 may contain an inorganic compound such as quantum dots. For example, when used for a light-emitting layer, the quantum dots can function as a light-emitting material.

As illustrated in FIG. 5B, the semiconductor device 100 of one embodiment of the present invention can have a structure in which the light-emitting devices 91, the pixel circuits 62, and the display control portion 50 are stacked; thus, the aperture ratio (effective display area ratio) of the pixels can be extremely high. For example, the pixel aperture ratio can be higher than or equal to 40% and lower than 100%, preferably higher than or equal to 50% and lower than or equal to 95%, further preferably higher than or equal to 60% and lower than or equal to 95%. Furthermore, the pixel circuits 62 can be arranged extremely densely, and thus the pixels can have extremely high resolution. For example, the pixels can be arranged in the display portion 60 of the semiconductor device 100 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

The semiconductor device 100 described above has extremely high resolution, and thus can be suitably used for a device for VR such as a head-mounted display or a glasses-type device for AR. Even in the case of a structure in which the display portion of the semiconductor device 100 is seen through an optical member such as a lens, for example, the pixels of the extremely-high-resolution display portion included in the semiconductor device 100 are not seen when the display portion is magnified by the lens, so that display providing a high sense of immersion can be performed.

At least part of this embodiment can be implemented in appropriate combination with the other embodiments described in this specification.

### Embodiment 2

In this embodiment, structure examples of a wearable electronic device, in particular, an arm-worn electronic device, that can include the semiconductor device 100 described above in Embodiment 1 will be described. The arm-worn electronic device can have a structure including, in addition to a display portion and a driver circuit for driving the display portion, a variety of sensors, a CPU (Central Processing Unit) for controlling the variety of sensors, a memory for storing data, and the like.

### Structure Examples of Electronic Device

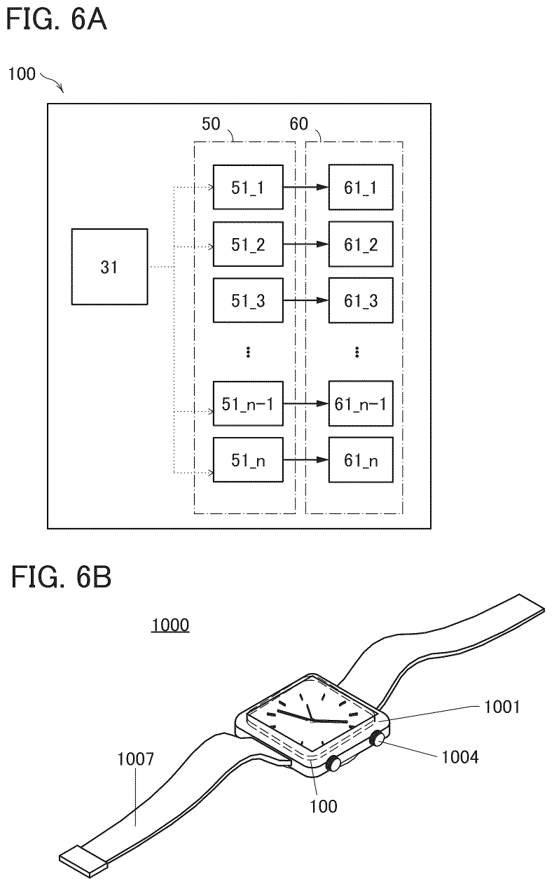

FIG. 6A is a block diagram for illustrating the semiconductor device included in the electronic device of one embodiment of the present invention. The semiconductor device 100 illustrated in FIG. 6A includes the logic circuit portion 31, the display control portion 50, and the display portion 60, for example.

FIG. 6B is an example of a perspective view of an electronic device 1000 including the semiconductor device 100 illustrated in FIG. 6A. The electronic device 1000 illustrated in FIG. 6B is a watch-type electronic device having a function of displaying an analog watch with a minute hand, an hour hand, and a second hand, for example. The electronic device 1000 has a structure in which the semiconductor device 100 illustrated in FIG. 6A is stored in a housing 1001 to which an operation portion 1004 and a band 1007 are attached. The electronic device 1000 illustrated in FIG. 6B has a function of what is called a smartwatch (registered trademark).

The logic circuit portion 31 has a function of controlling the display control portion 50 in accordance with image data. Specifically, the logic circuit portion 31 has a function of controlling, in accordance with image data, pause operations or restart operations of driver circuit portions 51, which are obtained by dividing the display control portion 50. In the pause operation of the driver circuit portion 51, an operation of not outputting image data is performed in addition to an operation of retaining a scan signal at a low level in a driver circuit included in the driver circuit portion 51, so that the driver circuit portion 51 is brought into a stop state. Furthermore, supply of a control signal such as a clock signal to the driver circuit may be stopped. This operation allows image data supplied in the previous period to be retained in pixel circuits included in the display portion 60. In the restart operation of the driver circuit portion 51, image data is supplied to the driver circuit of the driver circuit portion 51, so that a state in which a scan signal and image data are supplied is obtained. In the case where supply of a control signal such as a clock signal to the driver circuit of the driver circuit portion 51 is stopped in the pause operation of the driver circuit portion 51, supply of the control signal is restarted, so that the driver circuit portion 51 is brought into an operation state. With this structure, power consumption of the driver circuit portion 51 in a period during which image data is not updated can be reduced.

The display control portion 50 includes driver circuits for controlling the pixel circuits included in the display portion 60. The display control portion 50 includes the driver circuit portions 51 (driver circuit portions 51_1 to 51_n) (n is an integer greater than or equal to 2). The driver circuit portions 51_1 to 51_n have a structure in which a driver circuit is provided for each of a plurality of regions (sections).

The driver circuits included in the driver circuit portions 51_1 to 51_n are connected to the pixel circuits included in the display portion 60. The driver circuits each have a function of supplying image data and a scan signal to the display portion 60. A driver circuit that supplies a scan signal to the display portion 60 is referred to as a gate driver circuit or a scan line driver circuit in some cases. A driver circuit that supplies image data to the display portion 60 is referred to as a source driver circuit or a signal line driver circuit in some cases. A variety of circuits such as a shift register, a level shifter, an inverter, a latch, an analog switch, and a logic circuit can be used as the driver circuit.

The display portion 60 includes a plurality of pixel circuits for displaying an image based on image data. The pixel circuits are each a circuit that controls a display device such as a light-emitting device. The display portion 60 includes a plurality of display regions 61 (display regions 61_1 to 61_n). Each of the display regions 61_1 to 61_n is referred to as a sub-display portion in some cases. The display regions 61_1 to 61_n have a structure in which a pixel circuit is provided for each of a plurality of regions (sections).

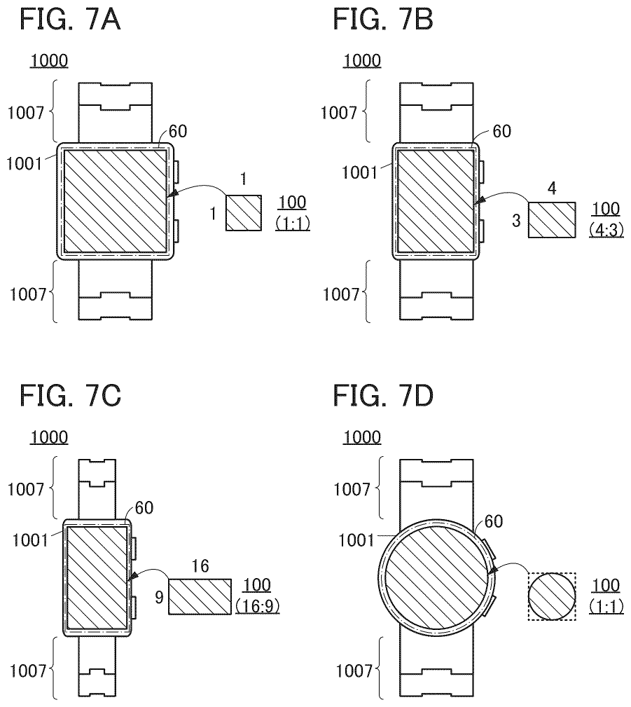

FIG. 7A to FIG. 7D illustrates examples of the screen ratio of the display portion in the semiconductor device 100 described in Embodiment 1. FIG. 7A illustrates an example of the case where the display portion 60 has a screen ratio of 1:1. FIG. 7B illustrates an example of the case where the display portion 60 has a screen ratio of 4:3. FIG. 7C illustrates an example of the case where the display portion 60 has a screen ratio of 16:9.

The shape of the display region of the semiconductor device 100 is not limited to a rectangle such as a square. As illustrated in FIG. 7D, a shape in which fillets are added to corner portions of the display portion (a shape obtained by a process of rounding the corner portions) can be employed to obtain a circular display region. When the corner portions of the display portion 60 have shapes in which fillets or chamfers are added, a well-designed electronic device including a display portion can be obtained.

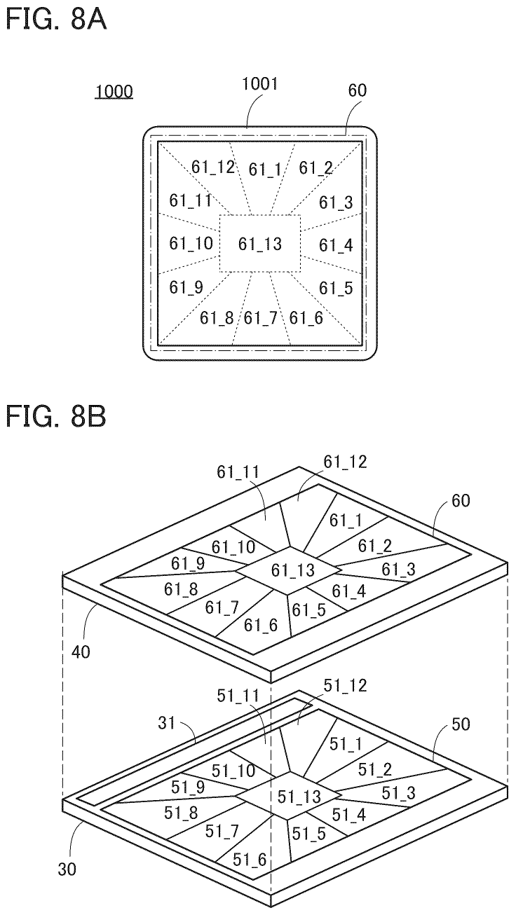

The structures of the display control portion 50 and the display portion 60 included in the semiconductor device 100 will be described with reference to FIG. 8A and FIG. 8B.

FIG. 8A is a diagram illustrating the display portion 60 when the semiconductor device 100 is stored in the housing 1001 of the electronic device 1000. In FIG. 8A, the display control portion 50 (not illustrated) is placed at a position overlapping with the display portion 60. The display portion 60 includes the display regions 61_1 to 61_13.

In the display portion 60 illustrated in FIG. 8A, the number of divided regions is 13. With this structure, when an analog watch with, for example, a minute hand, an hour hand, and a second hand is displayed, a middle portion of a dial can serve as a display region as well as 12 divided regions corresponding to numerals on the dial displayed on the analog watch.

The number of divided display regions in the display portion 60 may be other than 13. For example, the number of divided display regions may be 12 which corresponds to the number of numerals on the dial displayed on the analog watch. Alternatively, 7 divided display regions may be employed, obtained by dividing the region of the dial of the analog watch into 6 equal parts and adding the display region in the middle portion. Alternatively, 5 divided display regions may be employed, obtained by dividing the region of the dial of the analog watch into 4 equal parts and adding the display region in the middle portion. Alternatively, 3 divided display regions may be employed, obtained by dividing the region of the dial of the analog watch into 2 equal parts and adding the display region in the middle portion. In the case where the display portion 60 has a rectangular shape or a substantially rectangular shape, the display portion 60 may be divided into 2 or more equal parts having the same shape, for example, 4 parts, 8 parts, 16 parts, or 32 parts.

FIG. 8B is a schematic perspective view for illustrating the element layer 30 and the element layer 40 provided with the display control portion 50 and the display portion 60, respectively. The element layer 40 and the element layer 30 are provided to be stacked. The display control portion 50 provided in the element layer 30 is provided at a position overlapping with the display portion 60 provided in the element layer 40.

The display control portion 50 included in the element layer 30 is formed using a Si CMOS, i.e., transistors including silicon in their channel formation regions (Si transistors). That is, the element layer 30 is a layer including Si transistors. When the element layer 30 is formed using the Si transistors, a circuit required to operate at high speed, such as the display control portion 50, can be provided in the element layer 30.

For the Si transistors, the use of silicon having high crystallinity, such as single crystal silicon or polycrystalline silicon, is particularly preferable because high field-effect mobility can be achieved and a higher-speed operation becomes possible.

The display portion 60 included in the element layer 40 is formed using OS transistors, i.e., transistors including an oxide semiconductor in their channel formation regions. That is, the element layer 40 is a layer including OS transistors. When the element layer 40 is formed using the OS transistors, the element layer 40 and the element layer 30 can be provided to be stacked.

An OS transistor has a characteristic of an extremely low off-state current. Thus, when OS transistors are used as the transistors of the display portion 60 provided with the pixel circuits, image data written to the pixel circuits can be retained for a long period. Accordingly, the frequency of image data rewriting can be reduced, and low power consumption can be achieved.

The display portion 60 includes the plurality of display regions 61 (61_1 to 61_13). The display control portion 50 includes the driver circuit portions 51 (51_1 to 51_13). The driver circuit portions 51 include the driver circuits that can separately drive the plurality of display regions 61.

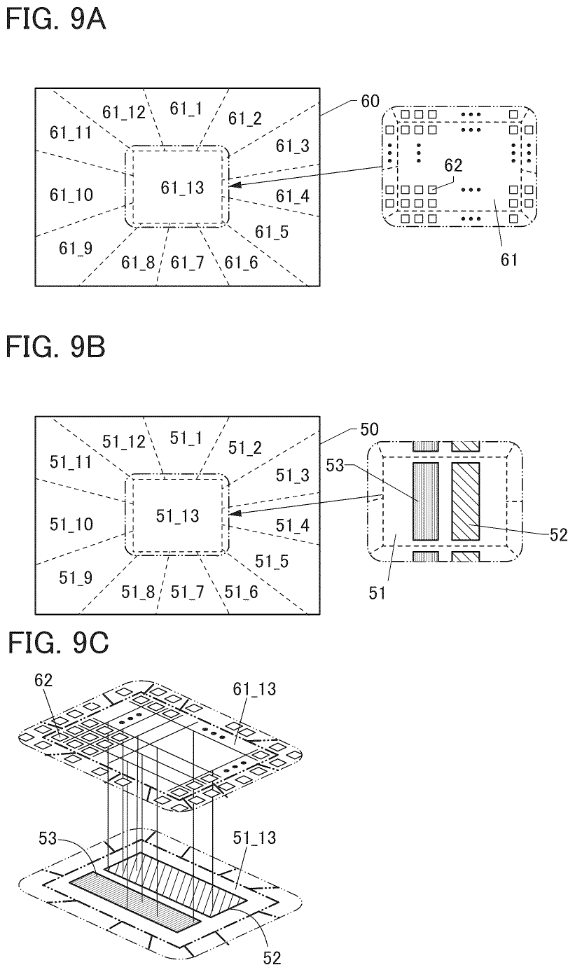

FIG. 9A is a schematic view for illustrating a structure of the display portion 60 included in the semiconductor device 100. FIG. 9A illustrates a structure example of the display region 61_13 provided with the pixel circuits 62, for example.

FIG. 9B is a schematic view for illustrating a structure of the display control portion 50 included in the semiconductor device 100. FIG. 9B illustrates a structure example of the driver 30 circuit portion 51_13 including driver circuits 52 and 53 for driving the pixel circuits 62 included in the display region 61_13, for example. The driver circuit 52 and the driver circuit 53 correspond to a source driver circuit and a gate driver circuit, respectively, for example. That is, a structure in which the display region 61 and the display control portion 50 are each divided into 13 sections is illustrated.

One of the display regions 61 and one of the driver circuit portions 51 are provided to overlap with each other (see FIG. 9C). For example, the display region 61_13 and the driver circuit portion 51_13 are provided to overlap with each other. The driver circuit 52 included in the driver circuit portion 51_13 is connected to a wiring for transmitting image data to the pixel circuits 62 included in the display region 61_13. The driver circuit 53 included in the driver circuit portion 51_13 is connected to a wiring for selecting the pixel circuit 62, which is included in the display region 61_13, to which the image data is to be transmitted. The driver circuits 52 and 53 included in the driver circuit portion 51_13 have a function of controlling the plurality of pixel circuits 62 included in the display region 61_13. The driver circuit portions 51_1 to 51_12 also have a function of controlling the pixel circuits 62 included in the display regions 61_1 to 61_12 which are provided to overlap with the driver circuit portions 51_1 to 51_12.

In FIG. 9A and FIG. 9B, the display regions 61_1 to 61_12 other than the display region 61_13 each have a polygonal shape other than a rectangular shape. In that case, in each of the driver circuit portions 51 provided to overlap with the corresponding display region 61 having a polygonal shape, the driver circuits 52 and 53 are placed in accordance with the shape of the display region 61. Since the driver circuit portions 51 are arranged at positions overlapping with the display regions 61, the degree of freedom in the arrangement of the driver circuits 52 and 53 can be increased.

With the above structure, when the semiconductor device 100 is stored in the housing 1001 of the electronic device 1000, the display control portion 50 can be placed at a position overlapping with the display portion 60 including the display regions 61_1 to 61_13. When one of the display regions 61 and one of the driver circuit portions 51 are provided to overlap with each other, the connection distance (wiring length) between the pixel circuits 62 included in the display region 61 and the driver circuits 52 and 53 included in the driver circuit portion 51 can be extremely short. As a result, the wiring resistance and the parasitic capacitance are reduced, and thus time taken for charging and discharging can be reduced and high-speed driving can be achieved. Moreover, power consumption can be reduced. Furthermore, reduction in size and weight can be achieved.

The semiconductor device 100 includes the driver circuits 52 and 53 in each of the driver circuit portions 51. Thus, the display portion 60 can be divided into the display regions 61 corresponding to the driver circuit portions 51 and image data update can be performed for each display region 61. For example, in the display portion 60, image data update is performed only in the display region 61 where an image is changed, whereas a potential corresponding to image data is retained in the pixel circuit 62 in the display region 61 where an image is not changed, so that an operation of the corresponding driver circuit portion 51 can be stopped. As a result, a reduction in power consumption of the semiconductor device 100 can be achieved.

The semiconductor device 100 of one embodiment of the present invention can have a structure in which the display portion 60 including the pixel circuits and the display control portion 50 including the driver circuits are stacked; thus, the aperture ratio (effective display area ratio) of the pixels can be extremely high. For example, the pixel aperture ratio can be higher than or equal to 40% and lower than 100%, preferably higher than or equal to 50% and lower than or equal to 95%, further preferably higher than or equal to 60% and lower than or equal to 95%. Furthermore, the pixel circuits can be arranged extremely densely, and thus the pixels can have extremely high resolution. For example, the pixels can be arranged in the display portion 60 of the semiconductor device 100 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

### Operation Example of Electronic Device

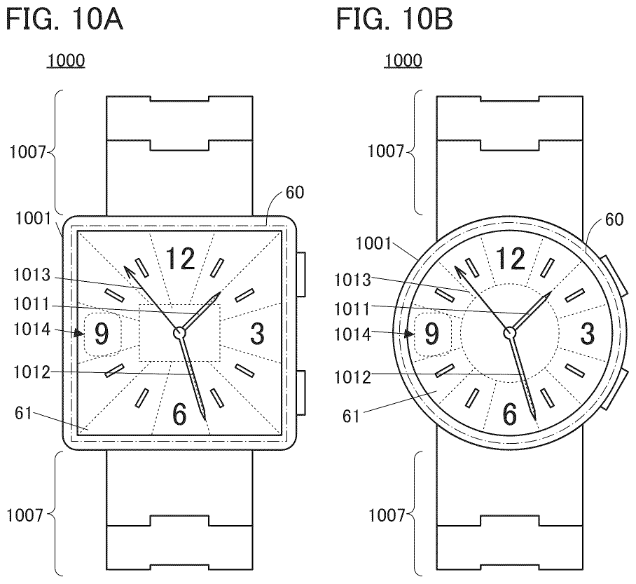

FIG. 10A and FIG. 10B are diagrams for illustrating an operation example of the electronic device 1000 including the semiconductor device 100. For a display portion of the electronic device 1000, the display portion 60 included in the above-described semiconductor device 100 is used. Although FIG. 10A illustrates an example in which the display portion 60 of the electronic device 1000 has a rectangular shape, the operation example of the electronic device 1000 described below can also be applied to the display portion 60 having a circular shape as illustrated in FIG. 10B.

FIG. 10A and FIG. 10B are schematic views of the electronic device 1000 seen from the front surface side. FIG. 10A and FIG. 10B each illustrate the case where a dial of an analog watch is displayed on the display portion 60 including the plurality of display regions 61. FIG. 10A and FIG. 10B each illustrate, in addition to the housing 1001 and the band 1007 illustrated in FIG. 6B, an hour hand 1011, a minute hand 1012, a second hand 1013, and a dial 1014 that are displayed on the display portion 60. The second hand 1013 or the dial 1014 is not necessarily required. In FIG. 10A and FIG. 10B, boundaries between the display regions 61 in the display portion 60 are shown by dotted lines. FIG. 10A and FIG. 10B each illustrate a state where the display region is divided into 13 parts as described with reference to FIG. 8A and FIG. 8B.

Each of the display regions 61 illustrated in FIG. 10A and FIG. 10B is provided to overlap with any one of the plurality of driver circuit portions 51 as described with reference to FIG. 8A and FIG. 8B, and control of the pixel circuits can be performed for each display region 61. Thus, for each display region 61, a pause operation or image data update (restart operation) of the driver circuit included in the driver circuit portion 51 can be performed in accordance with image data.

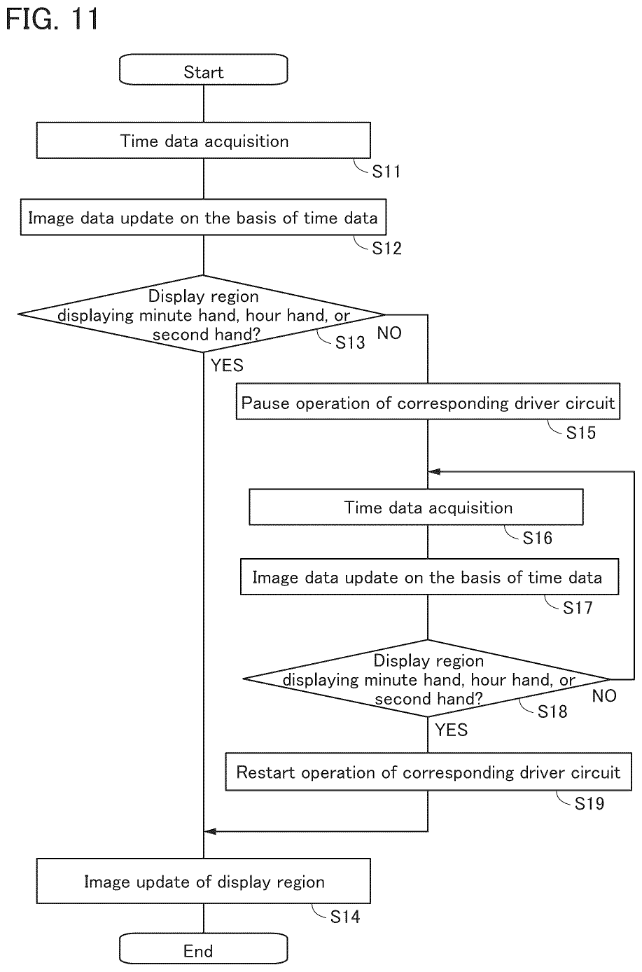

FIG. 11 is an example of a flowchart showing the operation example of the electronic device 1000.

In the logic circuit portion 31, time data is acquired (Step S11). The time data is data acquired with a timer or the like. On the basis of the time data, image data for displaying an analog watch on the display portion 60 is generated.

On the basis of the time data, update to image data to be supplied to the driver circuit portions 51 included in the display control portion 50 is performed (Step S12). The image data update is performed for each display region 61 included in the display portion 60, that is, for each driver circuit portion 51 corresponding to the display region 61.

Whether or not the display region 61 is a display region where the minute hand, the hour hand, or the second hand is displayed is determined in accordance with the image data based on the time data (Step S13). In the case where no second hand is displayed, the design may be changed as appropriate so that whether or not the display region 61 is a display region where the minute hand or the hour hand is displayed is determined. In the case where the display region 61 displays the minute hand, the hour hand, or the second hand on the basis of the time data (YES), the image data is transmitted to the driver circuit portion 51 corresponding to the display region 61 and an image on the display region 61 is updated on the basis of the image data that has been transmitted (Step S14).

In Step S13, in the case where the display region 61 does not display the minute hand, the hour hand, or the second hand on the basis of the time data (NO), the pause operation of the driver circuit included in the driver circuit portion 51 corresponding to the display region 61 is performed (Step S15). The pause operation is, for example, a stop of supply of a scan signal or a stop of supply of image data from the driver circuit to pixel circuits. This pause operation reduces the frequency of supplying a signal by the driver circuit portion 51.

After the pause operation of the driver circuit included in the driver circuit portion 51 is performed in Step S15, time data is acquired in an arithmetic unit 10 (Step S16). In the case where time data acquisition is performed at regular intervals, such as once per second when there is the second hand and once per minute when there is no second hand, power gating of the arithmetic unit 10 or the like can be performed periodically. Thus, power consumption can be reduced.

On the basis of the time data, update to image data to be supplied to the driver circuit portions 51 included in the display control portion 50 is performed (Step S17). The image data update is performed for each display region 61 included in the display portion 60, that is, for each driver circuit portion 51 corresponding to the display region 61.

Whether or not the display region 61 is a display region where the minute hand, the hour hand, or the second hand is displayed is determined in accordance with the image data based on the time data (Step S18). In the case where the display region 61 displays the minute hand, the hour hand, or the second hand on the basis of the time data (YES), the restart operation of the driver circuit included in the driver circuit portion 51 corresponding to the display region 61 is performed (Step S19), and then the image data is transmitted to the driver circuit portion 51 corresponding to the display region 61 and an image on the display region 61 is updated on the basis of the image data that has been transmitted (Step S14). In the case where the display region 61 does not display the minute hand, the hour hand, or the second hand on the basis of the time data (NO), the pause operation is continuously performed for the driver circuit included in the driver circuit portion 51 corresponding to the display region 61, and Step S16 for acquiring time data and Step S17 for updating image data are performed in the arithmetic unit 10.

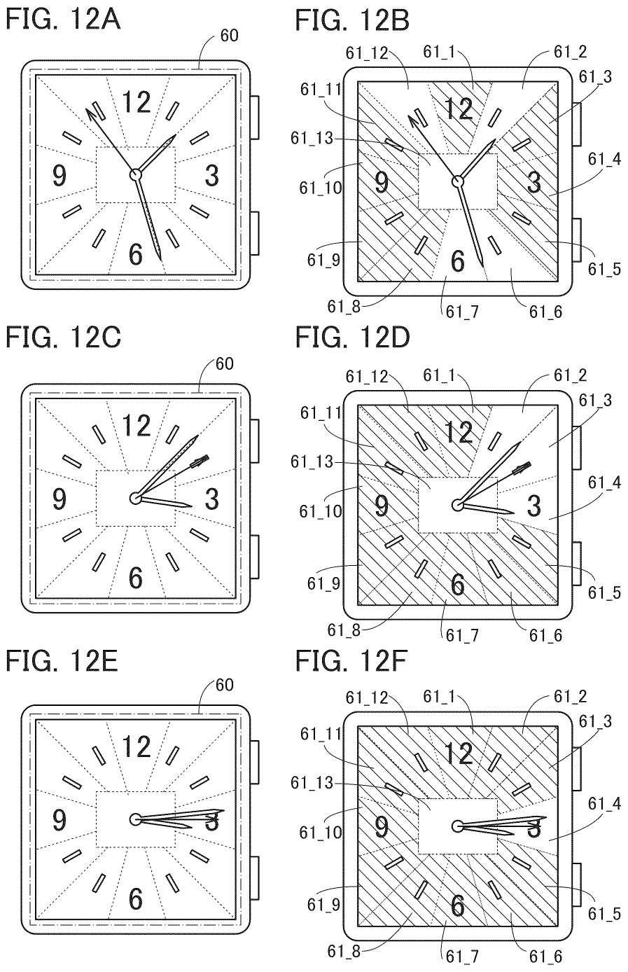

The states of the display portion 60 and the display control portion 50 in the electronic device 1000 based on the flowchart shown in FIG. 11 are specifically described with reference to FIG. 12A to FIG. 12F. In FIG. 12A to FIG. 12F, boundaries between the display regions 61 in the display portion 60 are shown by dotted lines. FIG. 12A to FIG. 12F illustrate state where the display region is divided into 13 parts as described with reference to FIG. 8A and FIG. 8B. Thus, in the description of FIG. 12A to FIG. 12F, the display regions 61 are described as the display regions 61_1 to 61_13 when their positions need to be specified. In a similar manner, the driver circuit portions 51 are described as the driver circuit portions 51_1 to 51_13 when their positions need to be specified.

FIG. 12A is a diagram illustrating a state where the display of the analog watch on the display portion 60 shows “one twenty-eight and fifty-four seconds”. In this case, the hour hand is displayed on the display regions 61_2 and 61_13 in the display portion 60 as illustrated in FIG. 12B. The minute hand is displayed on the display region 61_6 and the display regions 61_7 and 61_13 in the display portion 60 as illustrated in FIG. 12B. The second hand is displayed on the display regions 61_12 and 61_13 in the display portion 60 as illustrated in FIG. 12B.

Accordingly, the display regions 61_2, 61_6, 61_7, 61_12, and 61_13 are subjected to image data update based on the time data. The other display regions only display the dial and thus are not subjected to image data update. Thus, the display regions not subjected to image data update are shown by hatching in FIG. 12B.

FIG. 12C is a diagram illustrating a state where the display of the analog watch on the display portion 60 shows “three seven and ten seconds”. In this case, the hour hand is displayed on the display regions 61_4 and 61_13 in the display portion 60 as illustrated in FIG. 12D. The minute hand is displayed on the display region 61_2 and the display regions 61_3 and 61_13 in the display portion 60 as illustrated in FIG. 12D. The second hand is displayed on the display regions 61_3 and 61_13 in the display portion 60 as illustrated in FIG. 12D.

Accordingly, the display regions 61_2, 61_3, 61_4, and 61_13 are subjected to image data update based on the time data. The other display regions only display the dial and thus are not subjected to image data update. Thus, the display regions not subjected to image data update are shown by hatching in FIG. 12D.

FIG. 12E is a diagram illustrating a state where the display of the analog watch on the display portion 60 shows “three fourteen and fifteen seconds”. In this case, the hour hand is displayed on the display regions 61_4 and 61_13 in the display portion 60 as illustrated in FIG. 12F. The minute hand is displayed on the display regions 61_4 and 61_13 in the display portion 60 as illustrated in FIG. 12F. The second hand is displayed on the display regions 61_4 and 61_13 in the display portion 60 as illustrated in FIG. 12F.

Accordingly, the display regions 61_4 and 61_13 are subjected to image data update based on the time data. The other display regions only display the dial and thus are not subjected to image data update. Thus, the display regions not subjected to image data update are shown by hatching in FIG. 12F.

As described above, in the structure of the semiconductor device of one embodiment of the present invention, the driver circuit portions 51 that separately drive the plurality of display regions 61 are provided to overlap with the respective display region 61. The driver circuit portions 51_1 to 51_13, which correspond to the display regions 61_1 to 61_13 shown by hatching in FIG. 12A to FIG. 12F, can perform the pause operation or the restart operation of the driver circuits on the basis of whether or not image data update is performed. Thus, power consumption of the electronic device 1000 including the semiconductor device 100 can be reduced.

### Structure Example of Semiconductor Device

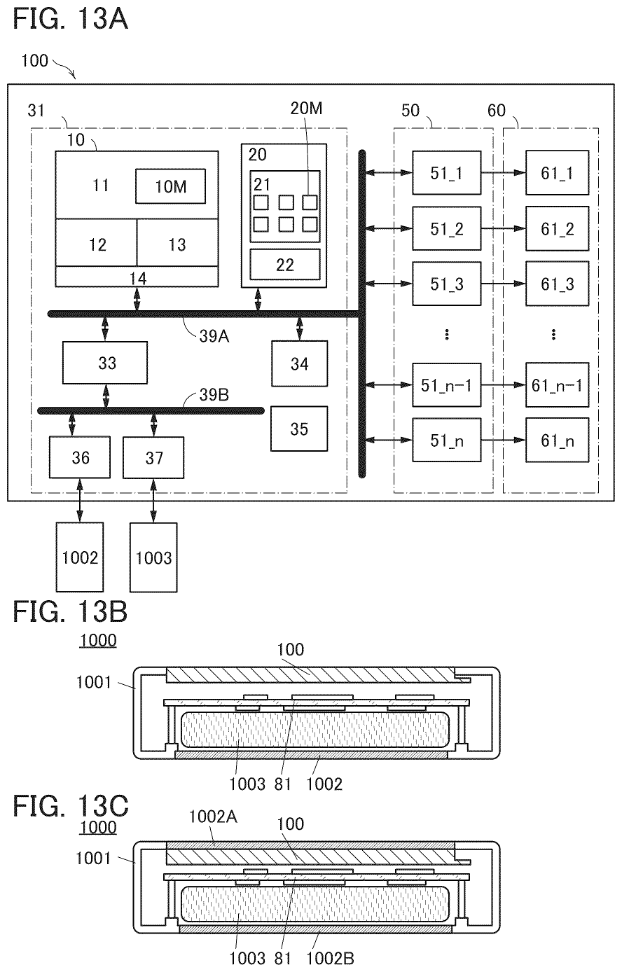

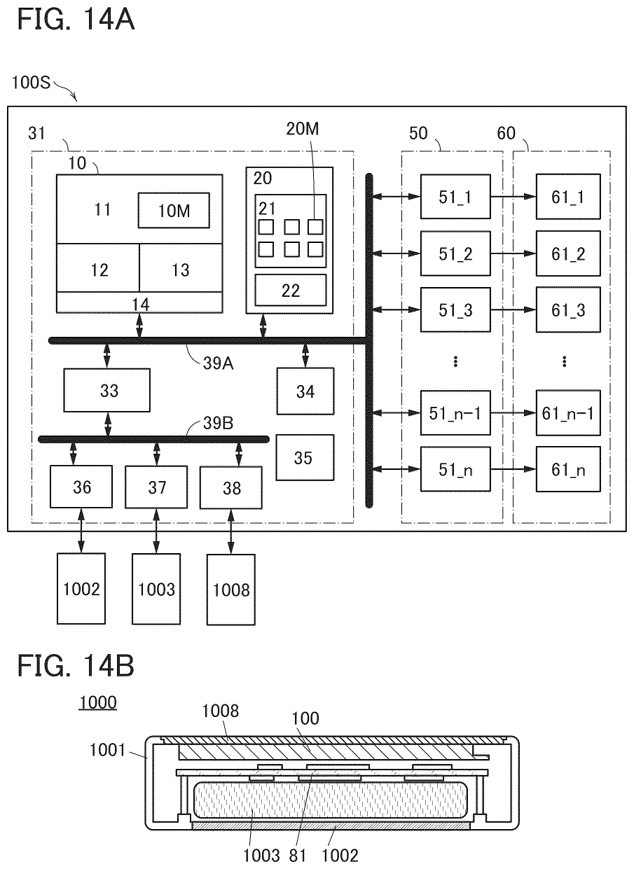

FIG. 13A and FIG. 14A are each a block diagram for illustrating a structure example of the logic circuit portion 31 included in the semiconductor device 100. The logic circuit portion 31 illustrated in FIG. 13A includes, for example, the arithmetic unit 10, a memory device 20, a bridge circuit 33, a power management unit (PMU) 34, a power supply circuit 35, a sensor control circuit 36, and a battery control circuit 37.

The arithmetic unit 10 includes, for example, a CPU core 11, an L1 cache memory device 12, an L2 cache memory device 13, and a bus interface portion 14. The L1 cache memory device 12 is referred to as an instruction cache in some cases. The L2 cache memory device 13 is referred to as a data cache in some cases.

The arithmetic unit 10 corresponds to a circuit for processing image data, such as a CPU (Central Processing Unit). The arithmetic unit 10 is referred to as a CPU, a processor device, or the like in some cases.

The CPU core 11 includes a plurality of CPU cores. The CPU core includes a backup circuit 10M connected to a scan flip-flop. The L1 cache memory device 12 has a function of temporarily storing an instruction to be executed by the CPU core 11. The L2 cache memory device 13 has a function of temporarily storing data to be processed by the CPU core 11 or data obtained by the processing. The bus interface portion 14 can have any circuit configuration as long as signals such as data and address can be transmitted and received to and from a bus for connecting the arithmetic unit 10 and other circuits in the semiconductor device 100.

The scan flip-flop in the arithmetic unit 10 is formed using a circuit including a Si transistor, that is, a Si CMOS. The backup circuit TOM, on the other hand, includes an OS transistor. The backup circuit TOM including an OS transistor can function as an OS memory having a function of retaining electric charge for a long time when the OS transistor is brought into an off state.

The scan flip-flop has a function of retaining data held by the arithmetic unit 10 and sequentially outputting the data in accordance with a clock signal or the like. The scan flip-flop is connected to the backup circuit TOM. With this structure, data held by the scan flip-flop can be output (backed up) to the backup circuit TOM, and data retained in the backup circuit TOM can be input (recovered) to the scan flip-flop. Thus, the semiconductor device 100 can significantly reduce sleep power (electric power in a non-display period) when the electronic device 1000 is brought into a sleep state; thus, the convenience can be increased even when the capacity of a battery is small.

A metal oxide has a band gap of 2.5 eV or wider; thus, an OS transistor has an extremely low off-state current. For example, an off-state current per micrometer in channel width at a source-drain voltage of 3.5 V and room temperature (25° C.) can be lower than 1×10⁻²⁰ A, lower than 1×10⁻²² A, or lower than 1×10⁻²⁴ A. Therefore, in an OS memory, the amount of electric charge that leaks from a retention node through an OS transistor is extremely small. Accordingly, the OS memory can function as a nonvolatile memory circuit; thus, power gating of the arithmetic unit 10 can be performed.

A highly integrated semiconductor device generates heat due to driving of a circuit in some cases. This heat generation increases the temperature of a transistor to change the characteristics of the transistor, and the field-effect mobility thereof might be changed or the operation frequency thereof might be decreased, for example. Since an OS transistor has higher heat resistance than a Si transistor, a change in field-effect mobility and a decrease in operating frequency due to a temperature change do not easily occur. Even when having a high temperature, an OS transistor is likely to keep a property of the drain current increasing exponentially with respect to the gate-source voltage. Thus, the use of an OS transistor enables a stable operation in a high-temperature environment.

A metal oxide used for an OS transistor is an In oxide, a Zn oxide, a Zn—Sn oxide, a Ga—Sn oxide, an In—Ga oxide, an In—Zn oxide, an In-M-Zn oxide (M is Ti, Ga, Y, Zr, La, Ce, Nd, Sn, or Hf), or the like. The use of a metal oxide containing Ga as M for the OS transistor is particularly preferable because the electrical characteristics such as field-effect mobility of the transistor can be made excellent by adjusting a ratio of elements. An oxide containing indium and zinc may contain one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like.

Accordingly, the arithmetic unit 10 can retain data owing to the backup circuit 10M, which is an OS memory, even when supply of power supply voltage is stopped. Thus, the power gating of the arithmetic unit 10 can be performed and power consumption can be reduced greatly. The backup circuit 10M, which is an OS memory, can be provided to be stacked over a circuit which is included in the CPU core 11 and which is composed of a Si transistor, such as a scan flip-flop circuit. Consequently, the backup circuit TOM can be provided without increasing in the circuit area.

The memory device 20 functions as an on-chip memory. The on-chip memory is a memory device for storing data or a program to be input to and output from the circuit included in the semiconductor device 100, such as the arithmetic unit 10.

The memory device 20 includes a memory cell array 21 and a peripheral circuit 22. The memory cell array 21 includes memory cells 20M. As a circuit that can be used for each of the memory cells 20M, a memory including a Si transistor, such as an SRAM (Static RAM) or a DRAM (Dynamic RAM), and a memory including an OS transistor, such as a DOSRAM or a NOSRAM, can be used. A DOSRAM (registered trademark) is an abbreviation of “Dynamic Oxide Semiconductor RAM”, which indicates a RAM including a 1T (transistor) 1C (capacitor)-type memory cell. The DOSRAM, as well as the NOSRAM, is a memory utilizing a low off-state current of an OS transistor.

The DOSRAM is a DRAM formed using an OS transistor and is a memory that temporarily stores information transmitted from the outside. When the DOSRAM is employed, in the memory device 20, the memory cell 20M including an OS transistor and the peripheral circuit 22 including a Si transistor (a transistor containing silicon in a channel formation region) can be provided in different layers stacked; thus, the entire circuit area can be reduced with the DOSRAM. Furthermore, the DOSRAM can be efficiently placed, with a memory cell array being finely divided. DOSRAMs can be stacked when including OS transistors that are provided in a plurality of layers.

A bus 39A is a bus for transmitting and receiving various signals at high speed between the arithmetic unit 10, the memory device 20, and the PMU 34. As an example, an AMBA (Advanced Microcontoroller Bus Artcitecture)-AHB (Advanced High-performance Bus) can be used as the bus. The bus 39A is also a bus for transmitting and receiving various signals at high speed between the plurality of driver circuit portions 51_1 to 51_n included in the display control portion 50. A circuit connected to the bus 39A included in the logic circuit portion 31 may include an accelerator, a memory controller, a direct memory access controller, an interface circuit, or the like.

The PMU 34 has a circuit configuration for controlling power gating of a circuit such as the CPU core 11 of the arithmetic unit 10 included in the semiconductor device 100.

The power supply circuit 35 is a circuit for generating voltage used in the semiconductor device 100.

A bus 39B is a bus for transmitting and receiving various signals at low speed between the sensor control circuit 36 and the battery control circuit 37. As an example, an AMBA-APB (Advanced Peripheral Bus) can be used as the bus. Transmission and reception of various signals between the bus 39A and the bus 39B are performed through the bridge circuit 33. A circuit connected to the bus 39B included in the logic circuit portion 31 may include an interrupt control circuit, an accelerator, an interface circuit, a timer circuit, a watch dog circuit, or the like.

The sensor control circuit 36 has a circuit configuration for transmitting and receiving data related to charging and discharging of a sensor 1002 outside the semiconductor device 100. The sensor control circuit 36 supplies electric power necessary for the sensor 1002. The sensor control circuit 36 receives input from the sensor 1002, and converts the input into a control signal and outputs it to the arithmetic unit 10 through the bus 39B or the like. In the sensor control circuit 36, error management of the sensor 1002 may be performed or correction processing of the sensor control circuit 36 may be performed. The sensor control circuit 36 may include a plurality of control circuits for controlling the sensor 1002.

The sensor 1002 has a function of acquiring information on one or more of the sense of sight, the sense of hearing, the sense of touch, the sense of taste, and the sense of smell of a human. More specifically, the sensor 1002 has at least one of functions of sensing or measuring force, displacement, position, speed, acceleration, angular velocity, rotational frequency, distance, light, magnetism, temperature, sound, time, electric field, current, voltage, electric power, radiation, humidity, gradient, oscillation, a smell, and infrared rays. As the sensor 1002, an imaging element, a sensor such as a gyroscope sensor or an acceleration sensor, or a sensor that measures a heart rate, a surface temperature, a blood oxygen concentration, or the like by touch on part of a human body can be used, for example. As the sensor 1002, a digital pressure sensor that can measure the depth of water may be provided. When a sensor such as a three-axis gyroscope sensor or an acceleration sensor is mounted, a state such as an orientation, motion, or the like of the electronic device 1000 can be detected. The on/off state of a function of the electronic device 1000 can be switched in accordance with the state of the electronic device 1000, so that power consumption can be reduced.

The battery control circuit 37 can manage the charging and discharging state of a battery 1003 outside the semiconductor device 100. The battery control circuit 37 may include, for example, a power converter or inverter having a plurality of channels, a protection circuit, or the like. The battery control circuit 37 supplies electric power from the battery 1003 to the power supply circuit 35, and electric power is supplied from the power supply circuit 35 to each component through a power supply line (not illustrated). The battery control circuit 37 has a function of receiving electric power supplied from the outside to charge the battery 1003. The battery control circuit 37 can control the charging operation of the battery 1003 in accordance with the charging state of the battery 1003.

The battery control circuit 37 preferably has a function of reducing power consumption. Examples of the function of reducing power consumption include, when no input of data or the like to the semiconductor device 100 is detected for a given time, lowering the clock frequency of a clock signal generation circuit (not illustrated) that supplies a clock signal to the arithmetic unit 10 or stopping input of a clock signal, stopping the operation of the arithmetic unit 10 itself, stopping the operation of the memory device 20, and reducing power supply to the components in order to reduce power consumption. Such a function can be performed either with the battery control circuit 37 alone or with the battery control circuit 37 in conjunction with the arithmetic unit 10.

As the battery 1003, a secondary battery such as a lithium-ion battery or a lithium-sulfur (Li—S) battery, a solar cell, or the like can be used, for example. The battery 1003 may be provided with a protection circuit for preventing overcharging, overdischarging, and the like of the battery 1003. A battery is referred to as a power storage device in some cases. A solar cell is referred to as a photoelectric conversion device in some cases. The battery 1003 may have flexibility, that is, the battery 1003 may be a flexible battery. When the battery 1003 has flexibility, the degree of freedom in design of the electronic device can be increased.

Although not illustrated in FIG. 13A, the semiconductor device 100 may include a control circuit that responds to the operation of the operation portion 1004. In the case where the semiconductor device 100 is connected to a touch panel in addition to the operation portion 1004, the touch panel may include a control circuit like the operation portion.

Although not illustrated in FIG. 13A, the semiconductor device 100 may include a module having a function of communicating with the outside (also referred to as a communication module). The communication module is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication apparatus using the electromagnetic signal. Several tens of kilohertz to several tens of gigahertz are a practical frequency band that is generally used. A structure can be employed in which the high frequency circuit connected to an antenna includes a high frequency circuit portion compatible with a plurality of frequency bands and the high frequency circuit portion includes an amplifier, a mixer, a filter, a DSP, an RF transceiver, or the like. In the case of performing wireless communication, it is possible to use, as a communication protocol or a communication technology, a communication standard defined by the 3GPP (Third Generation Partnership Project) (registered trademark), such as LTE (Long Term Evolution) (registered trademark), LTE-Advanced compatible with the fourth-generation mobile communication system, the fifth-generation mobile communication system (5G), or the sixth-generation mobile communication system (6G), or a communication standard defined by IEEE (Institute of Electrical and Electronics Engineers) (registered trademark), such as Wi-Fi (registered trademark) or Bluetooth (registered trademark), for example.

FIG. 13B is a schematic cross-sectional view of the electronic device 1000 including the semiconductor device 100, the sensor 1002, and the battery 1003 described with reference to FIG. 13A. In the housing 1001, the semiconductor device 100, the sensor 1002, and the battery 1003 are provided to overlap with one another. In addition, in the housing 1001, an electronic substrate 81 provided with an electronic component for controlling the electronic device 1000 is provided. In the case where the semiconductor device 100 including the display portion 60 is placed on the front surface side of the housing 1001 and the sensor 1002 is placed on the back surface side of the housing 1001 as illustrated in FIG. 13B, a sensor that measures a heart rate, a surface temperature, a blood oxygen concentration, or the like by touch on part of a human body is preferably provided as the sensor 1002. With this structure, accurate data can be acquired.

The position of the sensor 1002 in the housing 1001 is not limited to the back surface side of the housing 1001. For example, a structure illustrated in FIG. 13C may be employed in which a sensor 1002A is placed on the front surface side of the housing 1001 that overlaps with the semiconductor device 100 including the display portion 60, and a sensor 1002B is placed on the back surface side of the housing 1001. In the case where such a structure is employed and the sensor 1002A is a touch sensor, the semiconductor device 100 can be used as a touch panel, leading to an improvement in convenience. When the logic circuit portion 31 controls the display portion 60 and the display control portion 50 in accordance with the operation of the sensor 1002A functioning as a touch sensor, for example, an electronic device with reduced power consumption can be obtained.

FIG. 14A is a diagram illustrating a variation example of the block diagram of the semiconductor device 100 illustrated in FIG. 13A. A block diagram of a semiconductor device 100S illustrated in FIG. 14A illustrates a structure in which a solar cell 1008 and a control circuit 38 for converting electric power obtained by the solar cell 1008 are included in addition to the components of the semiconductor device 100 illustrated in FIG. 13A.

As the solar cell 1008, for example, a silicon solar cell using crystalline silicon for a photoelectric conversion layer, a solar cell with a tandem structure of a silicon solar cell and a perovskite type solar cell, or the like can be used. As the solar cell 1008, for example, an amorphous silicon solar cell, a CIGS (Cu—In—Ga—Se) type solar cell, an organic solar cell, a perovskite type solar cell, or the like can be used. An organic solar cell or a perovskite type solar cell has a high light-transmitting property and thus can be provided to overlap with the display portion 60. The solar cell 1008 may have flexibility, that is, the solar cell 1008 may be a flexible solar cell. When the solar cell 1008 has flexibility, the degree of freedom in design of the electronic device can be increased.

FIG. 14B is a schematic cross-sectional view of the electronic device 1000 in which the solar cell 1008 is placed to overlap with the semiconductor device 100 including the display portion 60. In the housing 1001, the solar cell 1008, the semiconductor device 100, the sensor 1002, and the battery 1003 are provided to overlap with one another. In addition, in the housing 1001, the electronic substrate 81 provided with an electronic component for controlling the electronic device 1000 is provided. In the case where the solar cell 1008 is provided at a position overlapping with the semiconductor device 100 including the display portion 60 as illustrated in FIG. 14B, a structure is preferable in which the above-described solar cell with a high light-transmitting property, such as a perovskite type solar cell, is employed. With this structure, an electronic device with excellent visibility can be obtained.

The control circuit 38 has a function of detecting a power generation state or the like of the solar cell 1008. The control circuit 38 can control whether generated electric power is used as electric power for driving the semiconductor device 100 or is used for charging the battery 1003 depending on the power generation state.

When the electronic device 1000 includes a solar cell, the usage time of the battery can be extended; thus, a more convenient semiconductor device and a more convenient electronic device including a semiconductor device can be obtained.

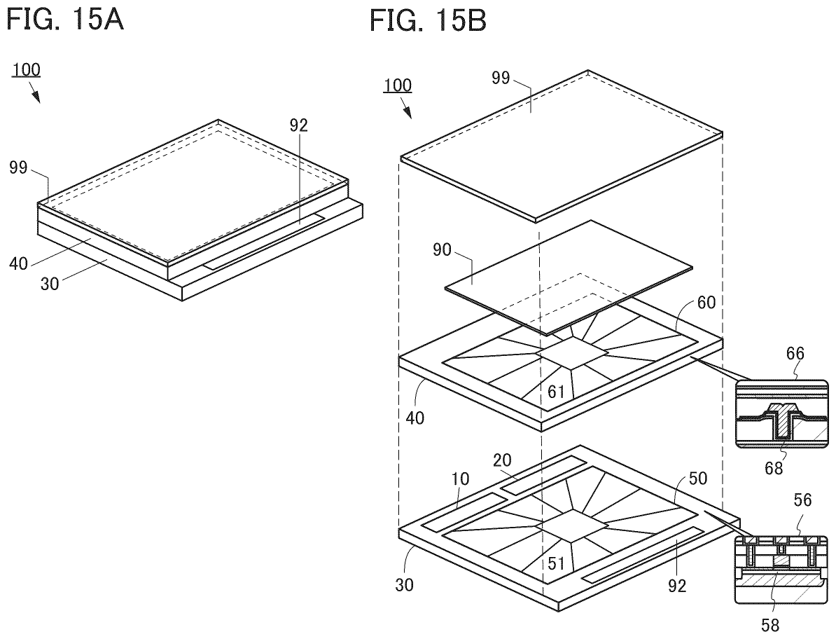

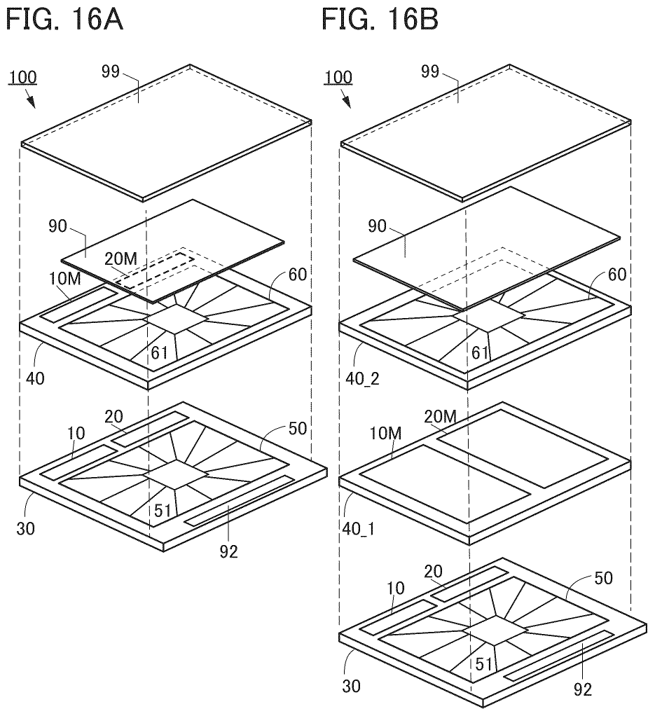

Next, structure examples of the element layers provided with the semiconductor device 100 will be described with reference to FIG. 15A to FIG. 16B.

The semiconductor device 100 illustrated in FIG. 15A includes the element layer 40 over the element layer 30 and the sealing substrate 99 over the element layer 40. The element layer 90 (not illustrated) is provided between the sealing substrate 99 and the element layer 40. The semiconductor device 100 illustrated in FIG. 15B is illustrated such that the element layer 30, the element layer 40, the element layer 90, the sealing substrate 99, and the like illustrated in FIG. 15A are separated from one another.

As illustrated in FIG. 15A and FIG. 15B, the element layer 30 includes the terminal portion 92. As illustrated in FIG. 15B, the element layer 30 includes the arithmetic unit 10, the memory device 20, and the display control portion 50 in a region overlapping with the element layer 40. The display control portion 50 includes the plurality of driver circuit portions 51 each provided with the driver circuits.

FPC (Flexible printed circuits) or the like are connected to the terminal portion 92. Thus, the element layer 40 and the sealing substrate 99 are not formed in a region overlapping with the terminal portion 92.

Although the arithmetic unit 10 and the memory device 20 are illustrated in FIG. 15B as the logic circuit portion 31 included in the element layer 30, other structures may be employed. For example, all of the other components illustrated in FIG. 15A may be included, or components other than these may be included.

The element layer 90 includes a light-emitting device (not illustrated) such as an organic EL element. Light emission of the light-emitting device is controlled by a pixel circuit included in a subpixel for color display. Thus, the element layer 90 can be regarded as part of the display portion 60.

In this specification and the like, the term “element” can be replaced with the term “device” in some cases. For example, a display element and a light-emitting element can be rephrased as a display device and a light-emitting device, respectively.

As described above, the element layer 30 includes a transistor 56 containing silicon in a semiconductor layer 58 including a channel formation region. When the arithmetic unit 10, the memory device 20, and the display control portion 50 are provided in the same element layer 30, wirings connected to the arithmetic unit 10, the memory device 20, and the display control portion 50 can be shortened. Thus, charging and discharging time of a wiring for transmitting a control signal that allows the arithmetic unit 10 to control the display control portion 50 can be shortened, so that power consumption can be reduced.

As described above, the element layer 40 includes a transistor 66 containing a metal oxide in a semiconductor layer 68 including a channel formation region. When an OS transistor is used as the transistor included in the pixel circuit provided in the display portion 60, a potential corresponding to a signal of image data can be retained in the pixel circuit; thus, a still image can be displayed without image data update.

The arithmetic unit 10 and the memory device 20 may be placed in the display control portion 50. For example, in the driver circuit portion 51 included in the display control portion 50, the arithmetic unit 10 and the memory device 20 may be provided separately in regions other than regions where the driver circuit 52 and the driver circuit 53 are placed. With this structure, circuit arrangement can be efficiently performed using extra space in the case where the area of the driver circuit portion 51 provided with the driver circuit 52 and the driver circuit 53 is larger than the area where the driver circuits 52 and 53 are provided.

The element layer 40 preferably has a structure in which the backup circuit 10M included in the arithmetic unit 10 and the memory cells 20M included in the memory device 20 are provided. That is, a structure is employed in which transistors provided in the same element layer as the pixel circuit 62 are used in the backup circuit TOM and the memory cells 20M. The backup circuit 10M and the memory cells 20M provided in the element layer 40 are preferably placed at positions overlapping with the arithmetic unit 10 and the memory device 20 provided in the element layer 30, respectively, as illustrated in FIG. 16A.

With this structure, the backup circuit 10M can be placed directly over a scan flip-flop included in the arithmetic unit 10. Thus, wirings for connecting the scan flip-flop and the backup circuit TOM can be shortened. Thus, wiring resistance and parasitic capacitance can be lowered, and the operation speed of the semiconductor device 100 can be increased. Furthermore, power consumption of the semiconductor device 100 is reduced.

When being placed in a peripheral portion of the display portion 60, the backup circuit 10M included in the arithmetic unit 10 and the memory cells 20M included in the memory device 20 can be provided in a region of the semiconductor device 100 that is covered with the housing 1001 of the electronic device 1000, for example. Thus, the backup circuit TOM included in the arithmetic unit 10 and the memory cells 20M included in the memory device 20 can be placed utilizing a region of the element layer 40 where the display portion 60 is not placed; hence, the backup circuit 10M and the memory cells 20M can be placed without reducing the display quality of the display portion 60.

The element layer 40 including the transistor 66 may be a plurality of element layers such as element layers 40_1 and 40_2 as illustrated in FIG. 16B, for example. With this structure, element layers including transistors having different transistor characteristics can be stacked using the element layer 40_1 and the element layer 40_2. Alternatively, element layers including transistors having different transistor shapes can be stacked using the element layer 40_1 and the element layer 40_2. Alternatively, element layers including transistors having different transistor sizes, i.e., a channel length and a channel width, can be stacked using the element layer 40_1 and the element layer 402.

In FIG. 16B, the backup circuit 10M included in the arithmetic unit 10 and the memory cells 20M included in the memory device 20 are provided in the element layer 40_1 over the element layer 30, and the pixel circuits, i.e., the display portion 60 including the display regions 61, are provided in the element layer 40_2 below the element layer 90. In this case, the element layer 401 can be an element layer including a transistor having a higher driving frequency in order that the performance of the backup circuit 10M and the memory cells 20M be improved, and the element layer 402 can be an element layer including a transistor having a high withstand voltage in order that the performance of the pixel circuits be improved. Thus, the semiconductor device 100 can be a semiconductor device that can achieve higher performance.

### Variation Example of Electronic Device

Variation examples of the electronic device will be described.

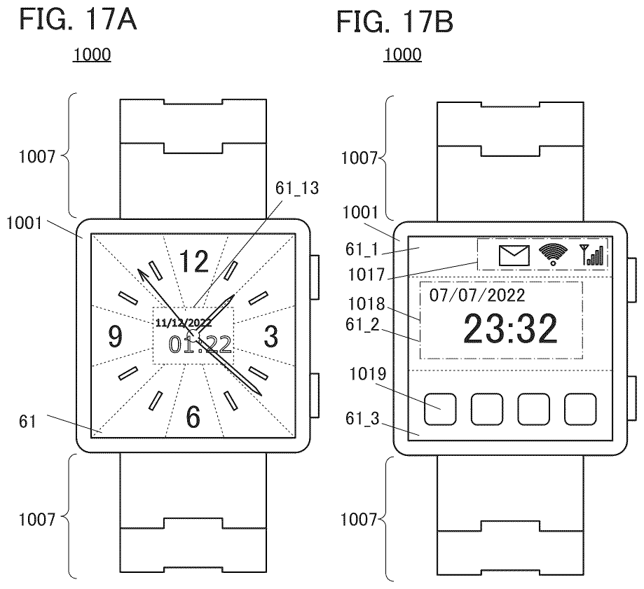

FIG. 17A is a diagram illustrating a structure with a design different from that of the display portion 60 described with reference to FIG. 10A. FIG. 17A illustrates a structure in which, as well as the dial of the analog watch illustrated in FIG. 10A, a digital watch is displayed on the display region 61_13 in the display portion 60.

In the case where the display portion 60 in the above-described structure is divided into 13 display regions as described with reference to FIG. 8A and FIG. 8B, the driver circuit portion 51_13 corresponding to the display region 61_13 in the middle is not stopped by image data update. Thus, displaying a digital watch enables highly convenient display. In addition to a digital watch, a date display function (calendar), a moon age display function (moon phase), power reserve, or the like may be displayed on the display region 61_13 in the middle.

The display region 61 in the display portion 60 is not necessarily divided into 13 display regions based on the dial of the analog watch illustrated in FIG. 10A. For example, in the case where notification information 1017, date and time information 1018, and a plurality of icons 1019 are displayed as illustrated in FIG. 17B, the display region 61 can be divided into three regions, the display regions 61_1 to 61_3, in the display portion 60.

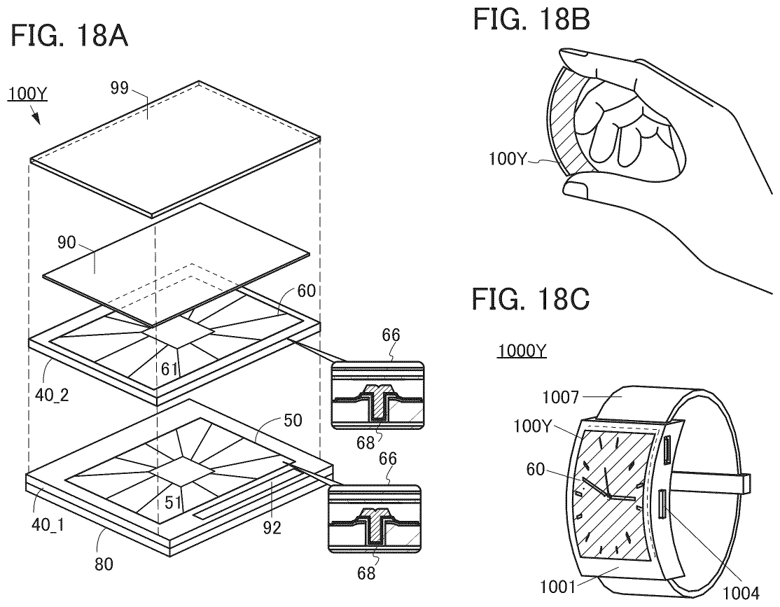

Although FIG. 16B illustrates a structure in which the element layers 401 and 40_2 provided with OS transistors are provided over the element layer 30 provided with Si transistors, another structure may be employed. For example, as in a semiconductor device 100Y illustrated in FIG. 18A, a flexible substrate 80 may be used instead of the element layer 30 and the element layers 401 and 40_2 and the like may be formed over the flexible substrate. Alternatively, a peeling layer may be provided between the element layers 40_1 and 40_2 and a substrate provided with the element layers 40_1 and 402, for example. The peeling layer can be used when part or the whole of the semiconductor device formed over the peeling layer is separated from the substrate and transferred to another substrate. In that case, the element layers 40_1 and 40_2 and the like can be transferred to a flexible substrate or the like. As the above-described peeling layer, a stacked-layer structure of a tungsten film and a silicon oxide film that are inorganic films, a structure in which an organic resin film of polyimide or the like is formed over a substrate, a silicon film including hydrogen, or the like can be used, for example.

Including the element layers 40_1 and 40_2 over the flexible substrate 80 in the semiconductor device can result in a semiconductor device that inhibits an increase in weight and is not easily broken.

In the case where the element layer 30 provided with the display control portion 50 (the driver circuit portion 51) includes Si transistors, breakage due to force by bending, twisting, or the like might be caused because a silicon substrate where the Si transistors are provided is poor in flexibility. Each of the element layers 40_1 and 40_2 provided over the flexible substrate 80 illustrated in FIG. 18A, on the other hand, includes the transistor 66 containing a metal oxide in the semiconductor layer 68 including a channel formation region. In that case, when the flexible substrate 80 is a substrate having flexibility made of a polyimide resin or the like, the semiconductor device 100Y which can be freely changed in shape as illustrated in FIG. 18B can be obtained. In addition, the risk of the semiconductor device 100Y being broken by impact can be reduced.

Thus, an electronic device 1000Y including the semiconductor device 100Y can have a structure in which the display portion 60 having a curved surface is stored in the housing 1001 as illustrated in FIG. 18C. Since a structure can be employed in which the electronic device 1000Y has a curved surface, the electronic device 1000Y can be worn to fit a curved surface of an arm. With this structure, a well-designed electronic device in which a semiconductor device can be inhibited from being damaged by impact can be obtained.

### Structure Example of Pixel Circuit

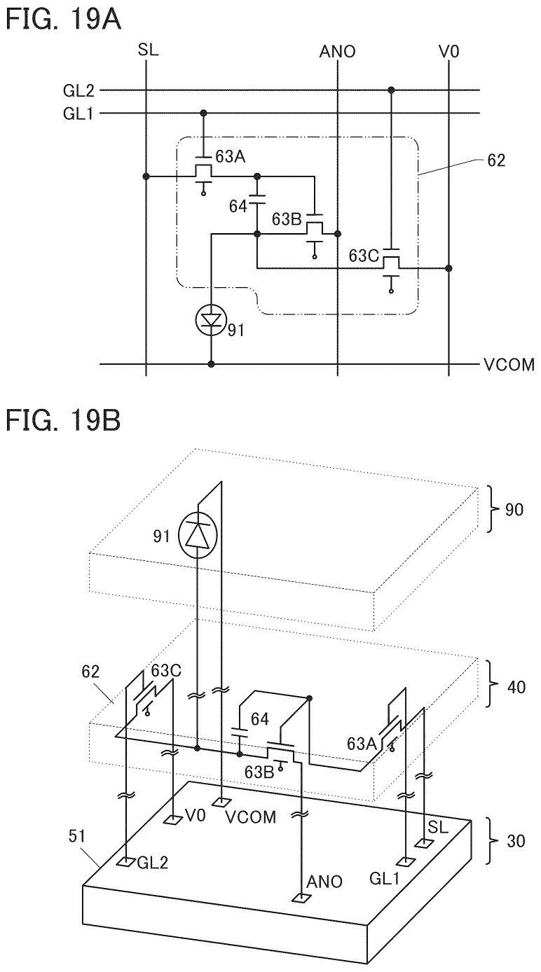

FIG. 19A and FIG. 19B illustrate a structure example of the pixel circuit 62, and the light-emitting device 91 connected to the pixel circuit 62. FIG. 19A is a diagram illustrating connection between elements, and FIG. 19B is a diagram schematically illustrating the vertical positional relation of the element layer 30 including the driver circuit portion 51, the element layer 40 including the pixel circuit 62, and the element layer 90 including the light-emitting device 91.

The pixel circuit 62 illustrated as an example in FIG. 19A and FIG. 19B includes a transistor 63A, a transistor 63B, a transistor 63C, and a capacitor 64. The transistor 63A, the transistor 63B, and the transistor 63C can be OS transistors. Each of the OS transistors of the transistor 63A, the transistor 63B, and the transistor 63C preferably includes a back gate electrode, in which case a structure in which the back gate electrode is supplied with the same signals as those supplied to gate electrode or a structure in which the back gate electrode is supplied with signals different from those supplied to the gate electrode can be used.

The transistor 63B includes the gate electrode electrically connected to the transistor 63A, a first electrode electrically connected to the light-emitting device 91, and a second electrode electrically connected to a wiring ANO. The wiring ANO is a wiring for supplying a potential for supplying current to the light-emitting device 91.

The transistor 63A includes a first terminal electrically connected to the gate electrode of the transistor 63B, a second terminal electrically connected to a wiring SL which functions as a source line, and the gate electrode having a function of controlling the conduction state or non-conduction state on the basis of the potential of a wiring GL1 which functions as a gate line.

The transistor 63C includes a first terminal electrically connected to a wiring V0, a second terminal electrically connected to the light-emitting device 91, and the gate electrode having a function of controlling the conduction state or non-conduction state on the basis of the potential of a wiring GL2 which functions as agate line. The wiring V0 is a wiring for supplying a reference potential and a wiring for outputting current flowing through the pixel circuit 62 to the driver circuit portion 51.

The capacitor 64 includes a conductive film electrically connected to the gate electrode of the transistor 63B and a conductive film electrically connected to a second electrode of the transistor 63C.

The light-emitting device 91 includes a first electrode electrically connected to the first electrode of the transistor 63B and a second electrode electrically connected to a wiring VCOM. The wiring VCOM is a wiring for supplying a potential for supplying current to the light-emitting device 91.

Accordingly, the intensity of light emitted from the light-emitting device 91 can be controlled in accordance with an image signal supplied to the gate electrode of the transistor 63B. Furthermore, variations in voltage between the gate and a source of the transistor 63B can be inhibited by the reference potential of the wiring V0 supplied through the transistor 63C.

A current value that can be used for setting of a pixel parameter can be output from the wiring V0. Specifically, the wiring V0 can function as a monitor line for outputting current flowing through the transistor 63B or current flowing through the light-emitting device 91 to the outside. Current output to the wiring V0 is converted into voltage by a source follower circuit or the like and output to the outside. Alternatively, the current can be converted into a digital signal by an A-D converter or the like and output to the arithmetic unit 10.

The light-emitting device described in one embodiment of the present invention refers to a self-luminous display element such as an organic EL element (also referred to as an OLED (Organic Light Emitting Diode)). Note that the light-emitting device electrically connected to the pixel circuit can be a self-luminous light-emitting device such as an LED (Light Emitting Diode), a micro LED, a QLED (Quantum-dot Light Emitting Diode), or a semiconductor laser.

In the structure illustrated as an example in FIG. 19B, the wirings electrically connecting the pixel circuit 62 and the driver circuit portion 51 can be shortened, so that wiring resistance of the wirings can be reduced. Thus, data can be written at high speed, which enables high-speed driving of the display portion 60. Therefore, even when the number of the pixel circuits 62 included in the display portion 60 is increased, a sufficient frame period can be ensured, and thus, the pixel density of the display portion 60 can be increased. In addition, the increased pixel density of the display portion 60 can increase the resolution of an image displayed by the display portion 60.

Although FIG. 19A and FIG. 19B illustrate, as an example, the pixel circuit 62 including three transistors in total, one embodiment of the present invention is not limited thereto. Structure examples and a driving method example of a pixel circuit which can be used for the pixel circuit 62 will be described below.

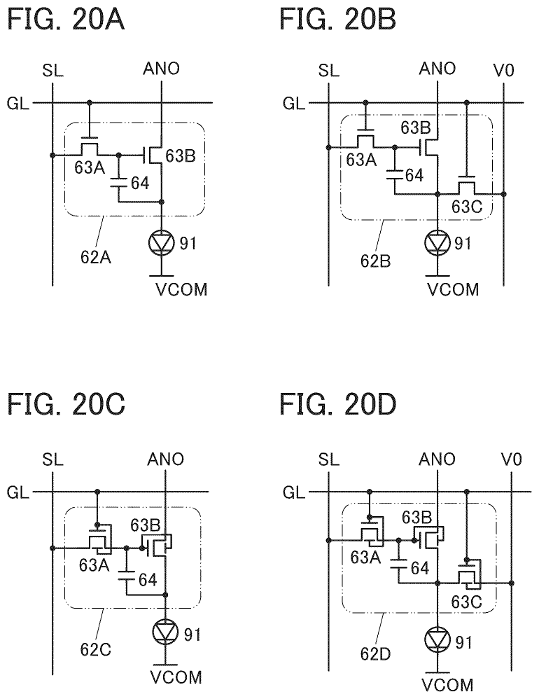

A pixel circuit 62A illustrated in FIG. 20A includes the transistor 63A, the transistor 63B, and the capacitor 64. FIG. 20A illustrates the light-emitting device 91 connected to the pixel circuit 62A. The wiring SL, the wiring GL, the wiring ANO, and the wiring VCOM are electrically connected to the pixel circuit 62A. The pixel circuit 62A has a structure in which the transistor 63C is removed from the pixel circuit 62 illustrated in FIG. 19A and the wiring GL1 and the wiring GL2 are replaced with the wiring GL.

The gate of the transistor 63A is electrically connected to the wiring GL, one of a source and a drain of the transistor 63A is electrically connected to the wiring SL, and the other of the source and the drain of the transistor 63A is electrically connected to the gate of the transistor 63B and one electrode of a capacitor C1. One of a source and a drain of the transistor 63B is electrically connected to the wiring ANO and the other of the source and the drain of the transistor 63B is electrically connected to an anode of the light-emitting device 91. The other electrode of the capacitor C1 is electrically connected to the anode of the light-emitting device 91. A cathode of the light-emitting device 91 is electrically connected to the wiring VCOM.

A pixel circuit 62B illustrated in FIG. 20B has a structure in which the transistor 63C is added to the pixel circuit 62A. In addition, the wiring V0 is electrically connected to the pixel circuit 62B.

A pixel circuit 62C illustrated in FIG. 20C is an example of the case where a transistor in which a pair of gates are electrically connected to each other is used as each of the transistor 63A and the transistor 63B of the pixel circuit 62A. A pixel circuit 62D illustrated in FIG. 20D is an example of the case where such transistors are used in the pixel circuit 62B. With these structures, current that can flow through the transistors can be increased. Although a transistor in which a pair of gates are electrically connected to each other is used for each of the transistors here, one embodiment of the present invention is not limited thereto. A transistor that includes a pair of gates electrically connected to different wirings may be used. When, for example, a transistor in which one of gates is electrically connected to a source is used, the reliability can be increased.

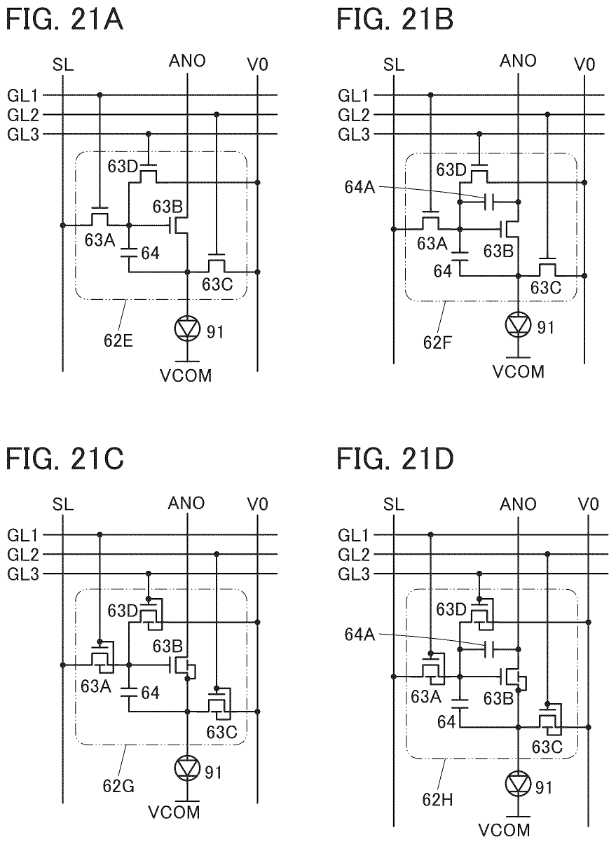

A pixel circuit 62E illustrated in FIG. 21A has a structure in which a transistor 63D is added to the pixel circuit 62B. The wiring GL1, the wiring GL2, and a wiring GL3 functioning as gate lines are electrically connected to the pixel circuit 62E. In this embodiment and the like, the wiring GL1, the wiring GL2, and the wiring GL3 are collectively referred to as the wiring GL in some cases. Thus, the wiring GL is not limited to one wiring and includes a plurality of wirings in some cases.

A gate of the transistor 63D is electrically connected to the wiring GL3, one of a source and a drain of the transistor 63D is electrically connected to the gate of the transistor 63B, and the other of the source and the drain of the transistor 63D is electrically connected to the wiring V0. The gate of the transistor 63A is electrically connected to the wiring GL1, and the gate of the transistor 63C is electrically connected to the wiring GL2.

When the transistor 63C and the transistor 63D are brought into a conduction state at the same time, the source and the gate of the transistor 63B have the same potential, so that the transistor 63B can be brought into a non-conduction state. Thus, current flowing to the light-emitting device 91 can be blocked forcibly. Such a pixel circuit is suitable for the case of using a display method in which a display period and a non-lighting period are alternately provided.

A pixel circuit 62F illustrated in FIG. 21B is an example of the case where a capacitor 64A is added to the pixel circuit 62E. The capacitor 64A functions as a storage capacitor.

A pixel circuit 62G illustrated in FIG. 21C and a pixel circuit 62H illustrated in FIG. 21D are respectively examples of the cases where transistors each including a pair of gates are used in the pixel circuit 62E and the pixel circuit 62F. A transistor in which a pair of gates are electrically connected to each other is used as each of the transistor 63A, the transistor 63C, and the transistor 63D, and a transistor in which one of gates is electrically connected to a source is used as the transistor 63B.

### Structure Example of Arithmetic Unit

An example of the arithmetic unit 10 including a CPU core capable of power gating will be described.

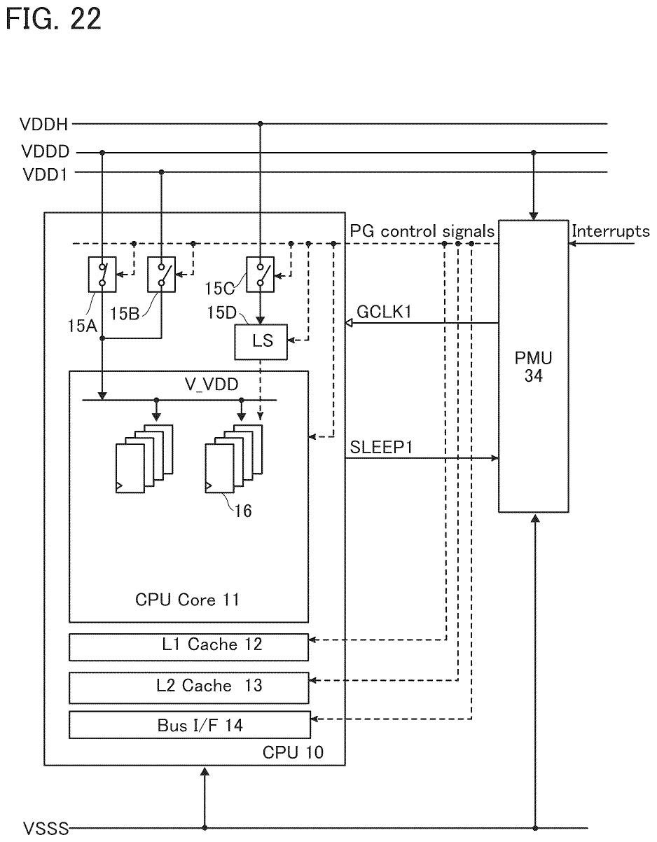

FIG. 22 illustrates a structure example of the arithmetic unit 10. The arithmetic unit (CPU) 10 includes the CPU core (CPU Core) 11, the L1 cache memory device (L1 Cache) 12, the L2 cache memory device (L2 Cache) 13, the bus interface portion (Bus I/F) 14, power switches 15A to 15C, and a level shifter (LS) 15D. The CPU core 11 includes a flip-flop 16.

Through the bus interface portion 14, the CPU core 11, the L1 cache memory device 12, and the L2 cache memory device 13 are mutually connected to one another.

The PMU 34 generates a clock signal GCLK1 and various PG (power gating) control signals (PG control signals) in response to signals such as interrupt signals (Interrupts) input from the outside and a signal SLEEP1 issued from the arithmetic unit 10. The clock signal GCLK1 and the PG control signal are input to the arithmetic unit 10. The PG control signal controls the power switches 15A to 15C and the flip-flop 16.

The power switches 15A and 15B control supply of voltages VDDD (high-level-side power supply voltage) and VDD1 to a virtual power supply line V_VDD (hereinafter referred to as a V_VDD line), respectively. The power switch 15C controls supply of a voltage VDDH to the level shifter (LS) 15D. A voltage VSSS is input to the arithmetic unit 10 and the PMU 34 without passing through the power switches. The voltage VDDD is input to the PMU 34 without passing through the power switches.

The voltages VDDD and VDD1 are driving voltages for a CMOS circuit. The voltage VDD1 is lower than the voltage VDDD and is a drive voltage in asleep state. The voltage VDDH is a driving voltage for an OS transistor and is higher than the voltage VDDD.

The L1 cache memory device 12, the L2 cache memory device 13, and the bus interface portion 14 each include at least one power domain capable of power gating. The power domain capable of power gating is provided with one or a plurality of power switches. These power switches are controlled by the PG control signal.

The flip-flop 16 is used for a register. The flip-flop 16 is provided with a backup circuit. The flip-flop 16 is described below.

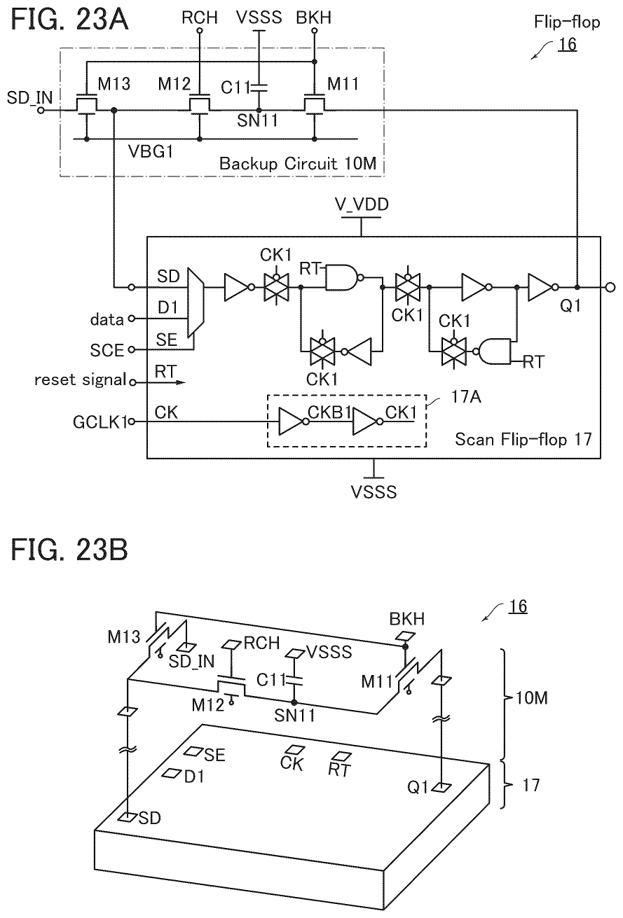

FIG. 23A shows a circuit configuration example of the flip-flop 16 (Flip-flop). The flip-flop 16 includes a scan flip-flop (Scan Flip-flop) 17 and the backup circuit (Backup Circuit) 10M.

The scan flip-flop 17 includes nodes D1, Q1, SD, SE, RT, and CK and a clock buffer circuit 17A.

The node D1 is a data (data) input node, the node Q1 is a data output node, and the node SD is a scan test data input node. The node SE is a signal SCE input node. The node CK is a clock signal GCLK1 input node. The clock signal GCLK1 is input to the clock buffer circuit 17A. Analog switches in the scan flip-flop 17 are connected to nodes CK1 and CKB1 of the clock buffer circuit 17A. The node RT is a reset signal (reset signal) input node.

The signal SCE is a scan enable signal and is generated in the PMU 34. The signal generated in the PMU 34 is level-shifted by the level shifter 15D to generate signals BKH and RCH. The signals BKH and RCH are a backup signal and a recovery signal, respectively.

The circuit configuration of the scan flip-flop 17 is not limited to that in FIG. 23A. A flip-flop prepared in a standard circuit library can be used.

The backup circuit TOM includes nodes SD_IN and SN11, transistors M11 to M13, and a capacitor C11.

The node SD_IN is a scan test data input node and is connected to the node Q1 of the scan flip-flop 17. The node SN11 is a retention node of the backup circuit TOM. The capacitor C11 is a storage capacitor for retaining the voltage of the node SN11.

The transistor M11 controls electrical continuity between the node Q1 and the node SN11. The transistor M12 controls electrical continuity between the node SN11 and the node SD. The transistor M13 controls electrical continuity between the node SD_IN and the node SD. The on/off of the transistors M11 and M13 is controlled by the signal BKH, and the on/off of the transistor M12 is controlled by the signal RCH.

The transistors M11 to M13 are OS transistors. The transistors M11 to M13 have back gates in the illustrated structure. The back gates of the transistors M11 to M13 are connected to a power supply line for supplying a voltage VBGT.

At least the transistors M11 and M12 are preferably OS transistors. Owing to an extremely low off-state current, which is a feature of an OS transistor, a decrease in the voltage of the node SN11 can be inhibited and almost no power is consumed to retain data; therefore, the backup circuit TOM has nonvolatile characteristics. Data is rewritten by charging and discharging of the capacitor C11; hence, there is theoretically no limitation on the number of times of rewriting of the backup circuit 10M, and data can be written and read out with low energy.

It is highly preferable that all of the transistors in the backup circuit TOM be OS transistors. As illustrated in FIG. 23B, the backup circuit TOM can be stacked over the scan flip-flop 17 formed using a silicon CMOS circuit.

The number of elements in the backup circuit 10M is much smaller than the number of elements in the scan flip-flop 17; hence, there is no need to change the circuit configuration and layout of the scan flip-flop 17 in order to stack the backup circuit 10M. That is, the backup circuit TOM is a backup circuit that has very broad utility. In addition, the backup circuit TOM can be provided in a region where the scan flip-flop 17 is formed; thus, even when the backup circuit TOM is incorporated, the area overhead of the flip-flop 16 can be zero. Accordingly, providing the backup circuit TOM in the flip-flop 16 enables power gating of the CPU core 11. The power gating of the CPU core 11 is possible with high efficiency owing to little energy necessary for the power gating.

When the backup circuit TOM is provided, parasitic capacitance due to the transistor M11 is added to the node Q1; however, the parasitic capacitance is lower than parasitic capacitance due to a logic circuit connected to the node Q1, and thus does not adversely affect the operation of the scan flip-flop 17. That is, even when the backup circuit TOM is provided, the performance of the flip-flop 16 does not substantially decrease.

The CPU core 11 can be set to a clock gating state, a power gating state, or a resting state (non-operation) as a low power consumption state, for example. The PMU 34 selects the low power consumption mode of the CPU core 11 on the basis of the interrupt signal, the signal SLEEP1, and the like. In the case of transition from a normal operation state to a clock gating state, for example, the PMU 34 stops generation of the clock signal GCLK1.

In the case of transition from a normal operation state to a resting state (non-operation state), for example, the PMU 34 performs voltage and/or frequency scaling. For example, when the voltage scaling is performed, the PMU 34 turns off the power switch 15A and turns on the power switch 15B to input the voltage VDD1 to the CPU core 11. The voltage VDD1 is voltage at which data in the scan flip-flop 17 is not lost. When the frequency scaling is performed, the PMU 34 reduces the frequency of the clock signal GCLK1.

In the case where the CPU core 11 transitions from a normal operation state to a power gating state, data in the scan flip-flop 17 is backed up to the backup circuit 10M. When the CPU core 11 is returned from the power gating state to the normal operation state, a recovery operation of writing back data in the backup circuit 10M to the scan flip-flop 17 is performed.

### Structure Examples of Memory Device

Here, structure examples of the memory device 20 that is provided with the memory cell 20M including an OS transistor will be described.

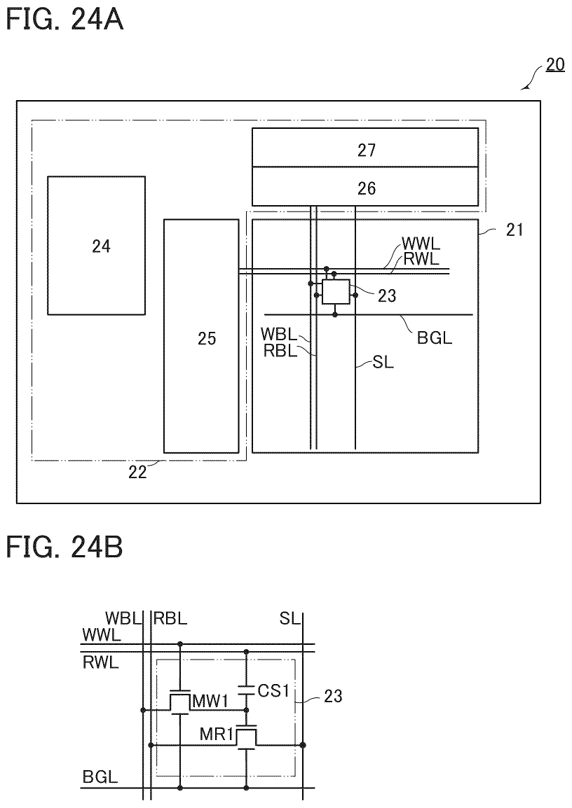

The memory device 20 illustrated in FIG. 24A includes the memory cell array 21 and the peripheral circuit 22. A control circuit 24, a row circuit 25, a column circuit 26, and an input/output circuit 27 are provided to form the peripheral circuit 22.

The memory cell array 21 includes a memory cell 23, a read word line RWL, a write word line WWL, a read bit line RBL, a write bit line WBL, the wiring SL, and a wiring BGL. The read word line RWL and the write word line WWL are referred to as a word line RWL and a word line WWL, respectively, in some cases. The read bit line RBL and the write bit line WBL are referred to as a bit line RBL and a bit line WBL, respectively, in some cases.

The control circuit 24 controls the memory device 20 as a whole and performs data writing and data reading. The control circuit 24 processes command signals (e.g., a chip enable signal, a write enable signal, and the like) from the outside and generates control signals for other circuits of the peripheral circuit 22.

The row circuit 25 has a function of selecting a row to be accessed. For example, the row circuit 25 includes a row decoder and a word line driver. The column circuit 26 has a function of precharging the bit lines WBL and RBL, a function of writing data to the bit line WBL, a function of amplifying data of the bit line RBL, a function of reading data from the bit line RBL, and the like. The input/output circuit 27 has a function of retaining writing data, a function of retaining data read out, and the like.

The structure of the peripheral circuit 22 is changed as appropriate depending on the structure, reading method, writing method, or the like of the memory cell array 21.

FIG. 24B illustrates a circuit configuration example of the memory cell 23. The memory cell 23 here is a 2-transistor (2T) gain cell. The memory cell 23 includes transistors MW1 and MR1 and a capacitor CS1. The transistor MW1 is a write transistor, and the transistor MR1 is a read transistor. Back gates of the transistors MW1 and MR1 are electrically connected to the wiring BGL.

Since the read transistor is composed of an OS transistor, the memory cell 23 does not consume power for data retention. Thus, the memory cell 23 is a memory cell with low power consumption that can retain data for a long time, and the memory device 20 can be used as a nonvolatile memory device. The OS transistor and the capacitor can be provided to be stacked over a Si transistor. Accordingly, the memory cell array 21 can be provided to be stacked over the peripheral circuit 22, resulting in an improvement in the integration degree of the memory cell array 21.

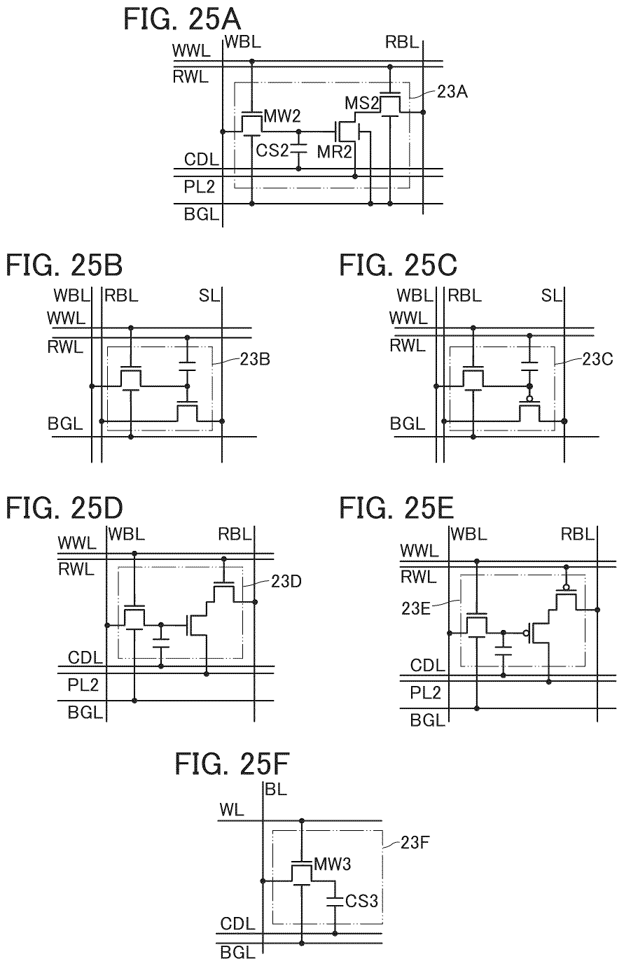

Other configuration examples of a memory cell will be described with reference to FIG. 25A to FIG. 25F.

A memory cell 23A illustrated in FIG. 25A is a 3T gain cell, which includes transistors MW2, MR2, and MS2, and a capacitor CS2. The transistors MW2, MR2, and MS2 are a write transistor, a read transistor, and a selection transistor, respectively. Back gates of the transistors MW2, MR2, and MS2 are electrically connected to the wiring BGL. The memory cell 23A is electrically connected to the word lines RWL and WWL, the bit lines RBL and WBL, a capacitor line CDL, and a power supply line PL2. A voltage GND (low-level-side power supply voltage) is input to the capacitor line CDL and the power supply line PL2, for example.

FIG. 25B and FIG. 25C illustrate other configuration examples of a 2T gain cell. In a memory cell 23B illustrated in FIG. 25B, a read transistor is composed of an n-channel Si transistor. In a memory cell 23C illustrated in FIG. 25C, a read transistor is composed of a p-channel Si transistor. As illustrated in FIG. 25B and FIG. 25C, a configuration may be employed in which an OS transistor and a Si transistor are used as the transistors in the memory cell in combination.

FIG. 25D and FIG. 25E illustrate other configuration examples of a 3T gain cell. In a memory cell 23D illustrated in FIG. 25D, a read transistor and a selection transistor are composed of n-channel Si transistors. In a memory cell 23E illustrated in FIG. 25E, a read transistor and a selection transistor are composed of p-channel Si transistors. In the example of FIG. 25E, the voltage VDDD is input to the power supply line PL2.

In the above-described gain cells, a bit line serving as both the bit line RBL and the bit line WBL may be provided.

FIG. 25F illustrates an example of a 1T1C (capacitor) memory cell. A memory cell 23F illustrated in FIG. 25F is electrically connected to a word line WL, a bit line BL, the capacitor line CDL, and the wiring BGL. The memory cell 23F includes a transistor MW3 and a capacitor CS3. A back gate of the transistor MW3 is electrically connected to the wiring BGL.

A circuit configuration of the memory cell 20M in the memory device 20 can be a circuit configuration in which a Si transistor is combined, for example, in addition to a circuit configuration including only OS transistors.

In the above-described semiconductor device of one embodiment of the present invention and the electronic device including the semiconductor device, electronic components such as semiconductor devices including the display portion, the arithmetic unit, and the memory device are stored in the housing 1001 with a limited volume. In the semiconductor device, the frequency of image data update in the display portion and the driving control portion is reduced, whereby power consumption can be reduced.

In the semiconductor device of one embodiment of the present invention and the electronic device including the semiconductor device, when the semiconductor device has a structure in which the backup circuit is provided in the arithmetic unit and a structure in which the memory cell including an OS transistor in the memory device is provided, electric power when the electronic device 1000 is brought into a sleep state can be significantly reduced; thus, the convenience can be improved even when the capacity of the battery is small. As a result, the electronic device can be reduced in weight.

At least part of this embodiment can be implemented in appropriate combination with the other embodiments described in this specification.

### Embodiment 3

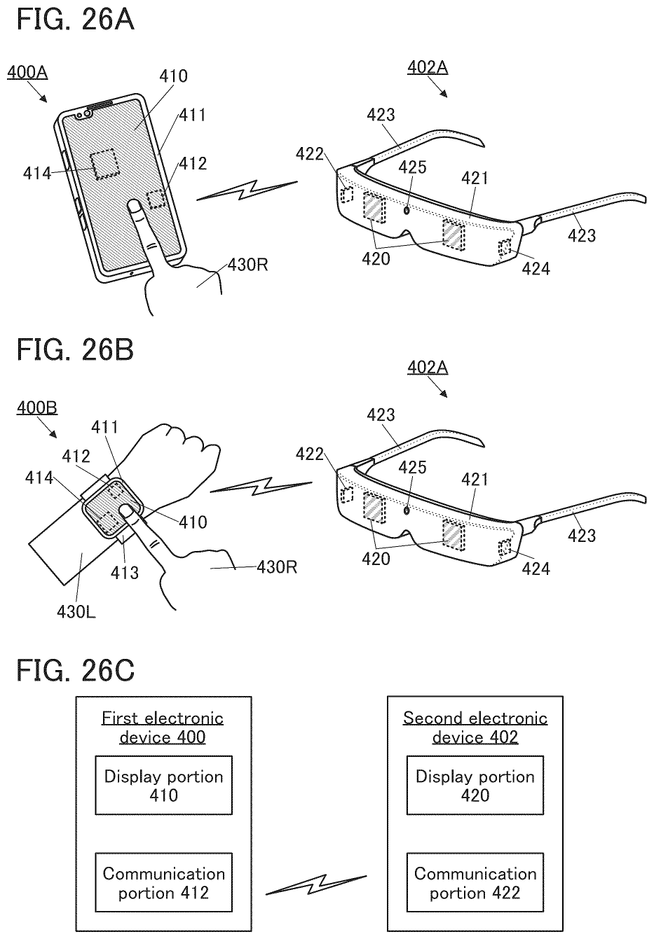

In this embodiment, electronic devices and input/output systems of one embodiment of the present invention will be described with reference to FIG. 26 to FIG. 28.

### Structure Examples of Electronic Devices and Input/Output Systems

FIG. 26A to FIG. 26C are diagrams for illustrating structure examples of electronic devices and input/output systems of one embodiment of the present invention.

As illustrated in FIG. 26A, an input/output system of one embodiment of the present invention includes a first electronic device 400A and a second electronic device 402A. The first electronic device 400A and the second electronic device 402A each have a wireless communication function. The second electronic device 402A includes a region having a pixel density (also referred to as resolution) higher than that of the first electronic device 400A. With the use of the above wireless communication function, a screen of the first electronic device 400A or part of the screen can be displayed on the second electronic device 402A.

As illustrated in FIG. 26A, the input/output system of one embodiment of the present invention includes the plurality of electronic devices. The plurality of electronic devices can exchange data using the wireless communication function, and image data displayed on the screen of one electronic device can be displayed on another electronic device after part of the data is processed by a processing method such as up-conversion or down-conversion. Such an input/output system can offer improved user convenience, enables an image to be displayed with an optimal image quality for each of the electronic devices, or can lower the power consumption of the electronic devices.

The first electronic device 400A includes a display portion 410, a housing 411, a communication portion 412, and a control portion 414. FIG. 26A illustrates a right hand 430R of the user. The second electronic device 402A includes a display portion 420, a housing 421, a communication portion 422, a wearing portion 423, a control portion 424, and a camera portion 425. Wireless communication between the first electronic device 400A and the second electronic device 402A can be performed between the communication portion 412 and the communication portion 422, as illustrated in FIG. 26A. The communication portion 412 has a function of transmitting information to the second electronic device 402A in response to the manipulation with the first electronic device 400A. The communication portion 422 has a function of transmitting information to the first electronic device 400A in response to the manipulation with the second electronic device 402A.

The camera portion 425 included in the second electronic device 402A has a function of acquiring external information. Data acquired by the camera portion 425 can be output to the display portion 420 or the display portion 410 included in the first electronic device 400A, for example. The wearing portion 423 included in the second electronic device 402A enables the user to put the second electronic device 402A on the head. Although FIG. 26A illustrates an example in which the wearing portion has a shape like a temple of glasses, one embodiment of the present invention is not limited thereto. The wearing portion 423 can have any shape with which the user can wear, and can have a shape of a helmet or a band, for example.

Although an example in which the camera portion 425 is included is described here, a range sensor (hereinafter, also referred to as a sensing portion) that is capable of measuring a distance to an object just needs to be provided. This means that the camera portion 425 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be acquired and a gesture operation with higher accuracy becomes possible.

The user can manipulate an image (also referred to as data or an object) displayed on the display portion 420 of the second electronic device 402A with an intuitive gesture operation as if the image is an actual object. The user may pre-register a specific gesture operation with the second electronic device 402A and may link it to specific processing.

It is preferable to provide a plurality of sensing portions in an electronic device so that a highly accurate gesture operation by the user using a plurality of actions such as a movement using both hands can be provided for the operation of the electronic device. This enables three-dimensional positional information on a plurality of objects to be detected with higher accuracy, so that input with a complicated gesture operation becomes possible.

The processing that can be executed by the first electronic device 400A and the second electronic device 402A in this embodiment is merely an example, and various types of processing can be executed in accordance with application software incorporated in the first electronic device 400A or the second electronic device 402A.

Next, a structure example different from the structure illustrated in FIG. 26A will be described with reference to FIG. 26B.

A first electronic device 400B illustrated in FIG. 26B includes the display portion 410, the housing 411, the communication portion 412, a band 413, and the control portion 414. FIG. 26B illustrates the right hand 430R and a left hand 430L of the user. The structure of the second electronic device 402A illustrated in FIG. 26B is similar to the structure illustrated in FIG. 26A; thus, the description thereof is omitted here.

The first electronic device 400A illustrated in FIG. 26A has a function of what is called a portable information terminal (typified by a smartphone or the like), and the first electronic device 400B illustrated in FIG. 26B has a function of what is called a watch-type portable information terminal. The first electronic device 400A and the first electronic device 400B each have at least one or both of a telephone function and a time display function. The second electronic device 402A has a function of displaying contents of augmented reality (AR), virtual reality (VR), substitutional reality (SR), or mixed reality (MR).

Next, the electronic devices and the input/output systems of one embodiment of the present invention will be described with reference to FIG. 26C.

FIG. 26C is a diagram for illustrating the electronic devices and the input/output systems of one embodiment of the present invention. As illustrated in FIG. 26C, a first electronic device 400 includes at least the display portion 410 and the communication portion 412, and a second electronic device 402 includes the display portion 420 and the communication portion 422.

The electronic device described in Embodiment 1 as an example can be used for the display portion 420. The electronic device described in Embodiment 1 as an example can also be used for the display portion 410 of the first electronic device 400B, which is a watch-type portable information terminal. If possible, the electronic device can also be used for the display portion 410 of the first electronic device 400A.

Although FIG. 26C illustrates a structure example in which the first electronic device 400 and the second electronic device 402 have the same functions, the structure is not limited thereto and the first electronic device 400 and the second electronic device 402 may have different functions.

The display portion 420 preferably has higher definition than the display portion 410. The display portion 420 preferably has a higher pixel density (resolution) than the display portion 410. The display portion 410 and the display portion 420 may have different screen ratios (aspect ratios).

The input/output system of one embodiment of the present invention can have a structure in which two electronic devices that differ in at least one of definition and a pixel density are included. In that case, a part or the whole of image data that can be displayed on one of the electronic devices is compressed or extended to obtain image data suitable for the other electronic device. Two electronic devices with the same definition and the same pixel density may be used, in which case the same image data can be used.

By increasing the definition or resolution of the display portion 420, pixels can be imperceptible (e.g., lines that might be caused between pixels can be invisible) to the user and accordingly the user can reach a higher level of immersion, realistic sensation, and sense of depth.

As illustrated in FIG. 26A, the first electronic device 400A has a period during which no image is displayed on the display portion, and functions as an input/output means (e.g., a controller) of the second electronic device 402A in that period. Such a function can extend the usage period of a power source included in the first electronic device 400A. That is, the input/output system of one embodiment of the present invention can achieve power saving.

Next, the components of the electronic devices and the input/output systems in FIG. 26A to FIG. 26C will be described below.

### <Display Portion>

The display portion 410 and the display portion 420 each have a function of performing display. For the display portion 410 and the display portion 420, one or more selected from a liquid crystal display device, a light-emitting device including organic EL, and a light-emitting device including a light-emitting diode such as a micro LED can be used, for example. In consideration of productivity and emission efficiency, a light-emitting device including organic EL is suitably used for the display portion 410 and the display portion 420.

The display portion 410 preferably has a function of a touch panel. It is particularly preferable to use a capacitive touch sensor because in that case, the thickness can be reduced. When the display portion 410 functions as a touch panel, the first electronic device 400A (or the first electronic device 400B) can be used alone as a portable information terminal. The display portion 410 can be used as an input device such as a touch pad when the second electronic device 402 is worn, which is preferable because in that case, there is no need to connect another input device such as a controller.

### <Communication Portion>

The communication portion 412 and the communication portion 422 each have a wireless or wired communication function. It is particularly suitable that the communication portion 412 and the communication portion 422 each have a wireless communication function, in which case the number of components such as a cable for connection can be reduced.

When the communication portion 412 and the communication portion 422 each have a wireless communication function, the communication portion 412 and the communication portion 422 can communicate through an antenna. Examples of a communication means (communication method) between the communication portion 412 and the communication portion 422 include computer networks such as the Internet, which is the infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), and a GAN (Global Area Network). In the case of performing wireless communication, it is possible to use, as a communication protocol or a communication technology, a communications standard such as the fourth-generation mobile communication system (4G) or the fifth-generation mobile communication system (5G), or a communications standard developed by IEEE such as Wi-Fi (registered trademark) or Bluetooth (registered trademark).

The first electronic device 400 and the second electronic device 402 may each independently include a component described below.

### <Control Portion>

A control portion has a function of controlling the display portion. The control portion includes a pixel circuit, a backup circuit, and an image conversion circuit, for example. The image conversion circuit can perform amp-conversion processing or down-conversion processing of image data. Thus, image data with low definition can be up-converted or image data with high definition can be down-converted according to the definition of the display portion, which enables the display portion to display an image with a high display quality.

### <Power Supply Portion>

A power supply portion has a function of supplying electric power to the display portion. As the power supply portion, a primary battery or a secondary battery can be used, for example. A lithium-ion secondary battery can be suitably used as the secondary battery, for example.

### <Sensor Portion>

A sensor portion has a function of acquiring information on any one or more of the sense of sight, the sense of hearing, the sense of touch, the sense of taste, and the sense of smell of the user. Specifically, the sensor portion has a function of measuring at least one of force, displacement, position, speed, acceleration, angular velocity, rotational frequency, distance, light, magnetism, temperature, sound, time, electric field, current, voltage, electric power, radiation, humidity, gradient, oscillation, smell, and infrared rays.

The sensor portion preferably has a function of measuring brain waves in addition to the above function. For example, the sensor portion has a mechanism of measuring brain waves from weak current flowing through a plurality of electrodes in contact with the user's head. When the sensor portion has a function of measuring brain waves, an image can be displayed on the display portion 420 at the user's intended coordinates. In that case, the user does not need to use both hands to operate the electronic device and can perform an input operation or the like with holding nothing in both hands (in a state where both hands are free).

### Example of Image

Next, examples of the electronic device and an image on the input/output system of one embodiment of the present invention will be described.

Hereinafter, examples of a manipulation method that the user can experience with the input/output system of one embodiment of the present invention and examples of an image that can be presented to the user will be described.

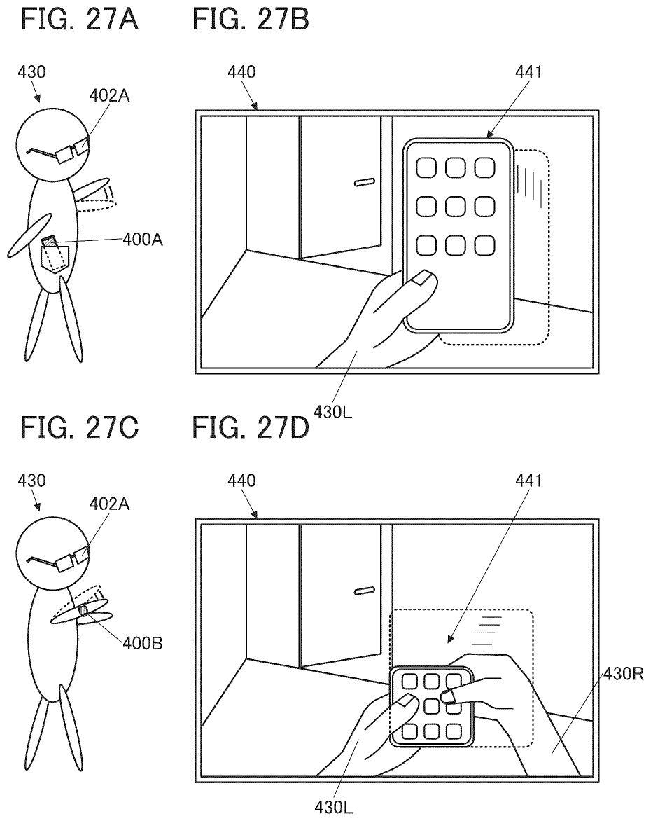

FIG. 27A illustrates a state where a user 430 wearing the second electronic device 402A with an eyeglass-like shape performs a gesture operation. At this time, the display portion of the first electronic device 400A is off, so that the power consumption of the first electronic device 400A can be reduced. In addition, the first electronic device 400A is in a pocket of the clothes of the user 430; thus, the user 430 can operate the input/output system with both hands being free.

FIG. 27B illustrates an example of an image 440 in the field of view of the user 430 illustrated in FIG. 27A in a room. In the image 440 illustrated in FIG. 27B, image information 441 is superimposed on a captured image of a real-world indoor scenery including a floor, a wall, a door, and the like. Here, the image information 441 is part of an image displayed on the display portion of the first electronic device 400A. The user 430 wearing the second electronic device 402A can operate the first electronic device 400A (e.g., a smartphone or the like) that is paired with the second electronic device 402A.

When the user 430 performs a movement of holding a space where the image information 441 is shown with the left hand 430L, the second electronic device 402A recognizes this movement as a gesture operation and makes the position of the image information 441 changeable. The movement of the left hand 430L of the user 430 in this state can change the position of the image information 441 in accordance with the movement of the left hand 430L, as illustrated in FIG. 27B. At this time, the image information 441 can be not only moved left and right, up and down, and back and forth but also rotated in accordance with the movement of the left hand 430L. The image information 441 may be scrolled.

FIG. 27C illustrates a state where the user 430 performs a gesture movement using both hands. The user 430 wears the first electronic device 400B in which the display portion is in a state of being off on his/her arm.

When the user 430 performs a movement of holding a space where the image information 441 is shown with the left hand 430L and the right hand 430R as illustrated in FIG. 27D, the second electronic device 402A recognizes this movement as a gesture operation and makes the shape of the image information 441 changeable. When the left hand 430L and the right hand 430R become close to each other in this state, the shape of the image information 441 is changed such that the image information 441 is downsized as illustrated in FIG. 27D. By contrast, when the left hand 430L and the right hand 430R become apart from each other, the image information 441 can be enlarged. At this time, the image information 441 can be moved or rotated in accordance with the movements of the left hand 430L and the right hand 430R. The image information 441 may be scrolled.

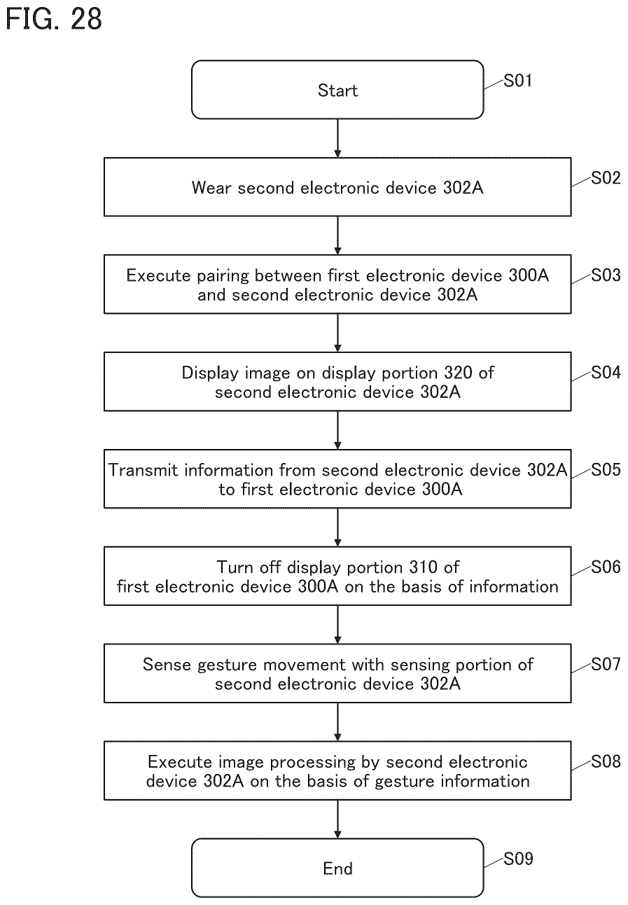

Next, an example of an operation method of the input/output system of one embodiment of the present invention will be described with reference to FIG. 28.

### Operation Method Example of Input/Output System

An example of an operation method of the input/output system will be described below. FIG. 28 is a flowchart for the operation method of the input/output system.

In Step S01, the operation starts. At this time, the first electronic device 400A is in a start-up state (a state where a manipulation is possible), and the second electronic device 402A is in a power-on state.

In Step S02, the second electronic device 402A is worn. The second electronic device 402A recognizes being worn, and a system starts. In Step S02, for example, when the second electronic device 402A has a goggles-type shape, an image taken by a camera on the front may be presented to the user or an image of other contents may be displayed.

In Step S03, pairing between the first electronic device 400A and the second electronic device 402A is executed. When the pairing is completed, the first electronic device 400A and the second electronic device 402A are in a state where two-way data exchange is possible.

In Step S04, a first image displayed on the display portion 410 of the first electronic device 400A is displayed on the display portion 420 of the second electronic device 402A. Accordingly, the user can see information displayed on the second electronic device 402A without looking at the screen of the first electronic device 400A.

At this time, since the pixel density of the display portion differs between the first electronic device 400A and the second electronic device 402A, instead of displaying the first image as it is, a second image, which is obtained by performing image processing such as up-conversion or down-conversion on the first image so that the image can have an optimal size when displayed on the display portion 420 of the second electronic device 402A, is preferably displayed on the second electronic device 402A.

In Step S05, information is transmitted from the second electronic device 402A to the first electronic device 400A. The information includes, for example, a code that means the completion of display of the first image.

In Step S06, the display portion 410 of the first electronic device 400A is turned off on the basis of the received information. At this time, the first electronic device 400A maintains a touch sensor of the display portion 410 in an active state. Accordingly, the display portion 410 of the first electronic device 400A functions as an input means (touch pad) or the like.

In Step S07, the second electronic device 402A senses a gesture movement of the user with the sensing portion included in the second electronic device 402A and acquires gesture information corresponding to the gesture movement. In the case where the second electronic device 402A includes a plurality of sensing portions, all of or two or more of the plurality of sensing portions sense the gesture movement. This enables three-dimensional positional information on a plurality of objects to be detected with higher accuracy, so that input with a complicated gesture operation becomes possible.

In Step S08, the second electronic device 402A executes various types of processing on the basis of the gesture information. For example, image processing can be performed on image information displayed on the display portion 420 of the second electronic device 402A, and the image information that has been subjected to the image processing can be displayed on the display portion 420.

In Step S09, the processing ends. Step S09 corresponds to detaching the second electronic device 402A, turning off the power of the first electronic device 400A or the second electronic device 402A, or canceling the pairing between the first electronic device 400A and the second electronic device 402A, for example.

The above is the description of the operation method example of the input/output system of one embodiment of the present invention.

At least part of this embodiment can be implemented in appropriate combination with the other embodiments described in this specification.

### Embodiment 4

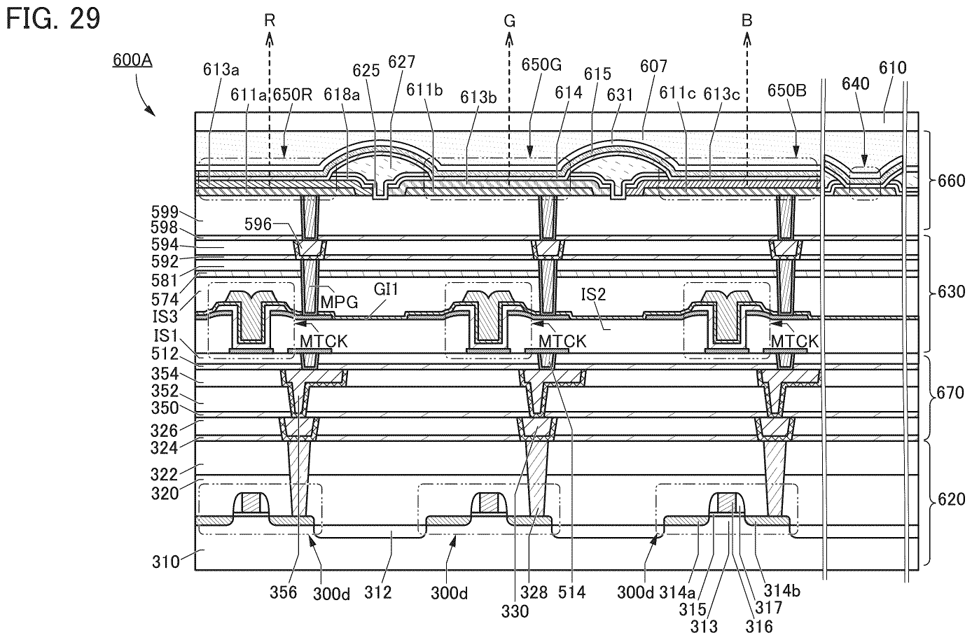

In this embodiment, a semiconductor device of one embodiment of the present invention will be described with reference to FIG. 29 to FIG. 35.

### Structure Example 1 of Semiconductor Device

FIG. 29 illustrates a cross-sectional view of a semiconductor device 600A. The semiconductor device 600A is an example of a semiconductor device having an MML (metal maskless) structure. In other words, the semiconductor device 600A includes a light-emitting device that is formed without using a fine metal mask.

An island-shaped light-emitting layer of the light-emitting device included in the semiconductor device having an MML structure is formed by depositing a light-emitting layer on the entire surface and then processing the light-emitting layer by a photolithography method. Accordingly, a high-resolution semiconductor device or a semiconductor device with a high aperture ratio, which has been difficult to achieve, can be manufactured. Moreover, light-emitting layers can be formed separately for the respective colors, enabling the semiconductor device to perform extremely clear display with high contrast and high display quality. For example, in the case where the semiconductor device includes three types of light-emitting devices, which are a light-emitting device that emits blue light, a light-emitting device that emits green light, and a light-emitting device that emits red light, three types of island-shaped light-emitting layers can be formed by repeating formation of a light-emitting layer and processing by photolithography three times.

A device having an MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. Furthermore, for processing by photolithography, an apparatus that is the same as or similar to that used for manufacturing a transistor can be used; thus, there is no need to introduce a special apparatus to manufacture the device having an MML structure. An MML structure can reduce the manufacturing cost as described above, and thus is suitable for mass production of the device.

It is not necessary to conduct a pseudo improvement in resolution by employing a unique pixel arrangement such as a PenTile arrangement in a semiconductor device employing an MML structure, for example; thus, the semiconductor device can achieve high resolution (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

In addition, providing a sacrificial layer over the light-emitting layer can reduce damage to the light-emitting layer in the manufacturing process of the semiconductor device, increasing the reliability of the light-emitting device. The sacrificial layer may remain in the completed semiconductor device or may be removed in the manufacturing process. For example, a sacrificial layer 618a illustrated in FIG. 29 to FIG. 31 is part of the sacrificial layer provided over the light-emitting layer.

Employing a film formation step using an area mask and a processing step using a resist mask enables the light-emitting device to be manufactured by a relatively easy process.

The semiconductor device 600A illustrated in FIG. 29 is a structure example of the semiconductor device 100 described above in Embodiment 1 or the like in a cross-sectional view. The semiconductor device 600A has a structure in which a pixel circuit, a driver circuit, and the like are provided over a substrate 310. In the semiconductor device 600A in FIG. 29, a wiring layer 670 is illustrated in addition to an element layer 620, an element layer 630, and an element layer 660. The wiring layer 670 is a layer provided with a wiring.

A pixel circuit of the semiconductor device is preferably provided in the element layer 630. A driver circuit (one or both of a gate driver and a source driver) of the semiconductor device is preferably provided in the element layer 620. One or more types of a variety of circuits such as an arithmetic circuit and a memory circuit may be provided in the element layer 620.

The element layer 620 includes the substrate 310, for example, and a transistor 300d is formed on the substrate 310. The wiring layer 670 is provided above the transistor 300d, and a wiring for electrically connecting the transistor 300d to a conductive layer, a transistor, or the like (a conductor 514 in FIG. 29) provided in the element layer 630 is provided in the wiring layer 670. The element layer 630 and the element layer 660 are provided above the wiring layer 670, and the element layer 630 includes a transistor MTCK and the like, for example. The element layer 660 includes a light-emitting device 650 (a light-emitting device 650R, a light-emitting device 650G, and a light-emitting device 650B in FIG. 29) and the like.

The transistor 300d is an example of a transistor included in the element layer 620. The transistor MTCK is an example of a transistor included in the element layer 630. The light-emitting device (the light-emitting device 650R, the light-emitting device 650G, and the light-emitting device 650B) is an example of a light-emitting device included in the element layer 660.

As the substrate 310, a semiconductor substrate (e.g., a single crystal substrate containing silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 310. In this embodiment, the substrate 310 is described as a semiconductor substrate containing silicon as a material. Therefore, a transistor included in the element layer 620 can be a Si transistor.

The transistor 300d includes an element isolation layer 312, a conductor 316, an insulator 315, an insulator 317, a semiconductor region 313 that is part of the substrate 310, and a low-resistance region 314a and a low-resistance region 314b that function as a source region and a drain region. Thus, the transistor 300d is a Si transistor. Although FIG. 29 illustrates the structure in which one of the source and the drain of the transistor 300d is electrically connected to the conductor 514 provided in the element layer 630 through a conductor 328, a conductor 330, and a conductor 356, the electrical connection structure of the semiconductor device of one embodiment of the present invention is not limited thereto.

The transistor 300d can be a Fin type when, for example, the top surface and a side surface in the channel width direction of the semiconductor region 313 are covered with the conductor 316 with the insulator 315 functioning as a gate insulator therebetween. The effective channel width can be increased in the fin-type transistor 300d, so that the on-state characteristics of the transistor 300d can be improved. In addition, contribution of the electric field of the gate electrode can be increased, so that the off-state characteristics of the transistor 300d can be improved. The transistor 300d may have a planar structure instead of a Fin-type structure.

The transistor 300d may be either a p-channel type or an n-channel type. Alternatively, a plurality of the transistors 300d may be provided and both the p-channel type and the n-channel type may be used.

A region of the semiconductor region 313 where a channel is formed, a region in the vicinity thereof, and the low-resistance region 314a and the low-resistance region 314b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to a crystal lattice and changing lattice spacing may be employed. Alternatively, the transistor 300d may be a HEMT (High Electron Mobility Transistor) using gallium arsenide and aluminum gallium arsenide, for example.

For the conductor 316 functioning as a gate electrode, a semiconductor material such as silicon containing an element that imparts n-type conductivity, such as arsenic or phosphorus or an element that imparts p-type conductivity, such as boron or aluminum, can be used. Alternatively, for the conductor 316, a conductive material such as a metal material, an alloy material, or a metal oxide material can be used, for example.

Since a work function depends on the material of the conductor, the threshold voltage of the transistor can be adjusted by selecting the material of the conductor. Specifically, it is preferable to use one or both of titanium nitride and tantalum nitride as the material of the conductor. Moreover, for both conductivity and embeddability, it is preferable to use stacked layers of metal materials of one or both of tungsten and aluminum as the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Over the transistor 300d illustrated in FIG. 29, an insulator 320 and an insulator 322 are sequentially stacked from the substrate 310 side.

For the insulator 320 and the insulator 322, one or more selected from silicon oxide, silicon oxynitride, silicon nitride oxide, silicon nitride, aluminum oxide, aluminum oxynitride, aluminum nitride oxide, and aluminum nitride can be used, for example.

The insulator 322 may have a function of a planarization film for reducing a level difference caused by the transistor 300d or the like covered with the insulator 320 and the insulator 322. For example, the top surface of the insulator 322 may be planarized by planarization treatment using a chemical mechanical polishing (CMP) method or the like to have improved planarity.

The conductor 328 connected to the transistor MTCK and the like provided above the insulator 322 is embedded in the insulator 320 and the insulator 322. The conductor 328 functions as a plug or a wiring.

In the semiconductor device 600A, the wiring layer 670 is provided over the transistor 300d. The wiring layer 670 includes, for example, an insulator 324, an insulator 326, the conductor 330, an insulator 350, an insulator 352, an insulator 354, and the conductor 356.

Over the insulator 322 and the conductor 328, the insulator 324 and the insulator 326 are stacked in this order. An opening is formed in the insulator 324 and the insulator 326 in a region overlapping with the conductor 328. In addition, the conductor 330 is embedded in the opening.

The insulator 350, the insulator 352, and the insulator 354 are stacked sequentially over the insulator 326 and the conductor 330. An opening is formed in the insulator 350, the insulator 352, and the insulator 354 in a region overlapping with the conductor 330. In addition, the conductor 356 is embedded in the opening.

The conductor 330 and the conductor 356 have a function of a plug or a wiring that is connected to the transistor 300d.

Like an insulator 592 described later, the insulator 324 and the insulator 350 are preferably formed using an insulator having a barrier property against one or more selected from hydrogen, oxygen, and water, for example. Like an insulator 594 described later, each of the insulator 326, the insulator 352, and the insulator 354 is preferably formed using an insulator having a comparatively low relative permittivity to reduce parasitic capacitance generated between wirings. Each of the insulator 326, the insulator 352, and the insulator 354 has a function of an interlayer insulating film and a planarization film. Furthermore, the insulator 326, the insulator 352, and the insulator 354 preferably include an insulator having a barrier property against one or more selected from hydrogen, oxygen, and water.

For a conductor having a barrier property against hydrogen, tantalum nitride is preferably used, for example. The use of a stack including tantalum nitride and tungsten that has high conductivity can inhibit diffusion of hydrogen from the transistor 300d while the conductivity of a wiring is maintained. In that case, a tantalum nitride layer having a barrier property against hydrogen is preferably in contact with the insulator 350 having a barrier property against hydrogen.

An insulator 512 is provided above the insulator 354 and the conductor 356. An insulator IS1 is provided over the insulator 512. A conductor functioning as a plug or a wiring is embedded in the insulator IS1 and the insulator 512. Thus, the transistor 300d can be electrically connected to the conductor 514 provided in the element layer 630. Alternatively, one of a source and a drain of the transistor MTCK and one of the source and the drain of the transistor 300d may be electrically connected to each other.

The transistor MTCK is provided over the insulator IS1. An insulator IS3, an insulator 574, and an insulator 581 are stacked in this order over the transistor MTCK. A conductor MPG functioning as a plug or a wiring is embedded in the insulator IS3, the insulator 574, and the insulator 581. The transistor MTCK and the semiconductor, and the conductors and the insulators around the transistor MTCK will be described later in this embodiment.

The insulator 574 preferably has a function of inhibiting diffusion of impurities such as water and hydrogen (e.g., one or both of a hydrogen atom and a hydrogen molecule). In other words, the insulator 574 preferably functions as a barrier insulating film that inhibits the entry of the impurities into the transistor MTCK. In addition, it is preferable that the insulator 574 have a function of inhibiting diffusion of oxygen (e.g., one or both of an oxygen atom and an oxygen molecule). For example, the insulator 574 preferably has lower oxygen permeability than an insulator IS2 and the insulator IS3.

Thus, the insulator 574 preferably functions as a barrier insulating film that inhibits diffusion of impurities such as water and hydrogen. Accordingly, it is preferable to use, for the insulator 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulator 574. Accordingly, it is possible to inhibit diffusion of impurities such as water and hydrogen to the transistor MTCK side from above the insulator 574. Alternatively, oxygen contained in the insulator IS3 and the like can be inhibited from diffusing above the insulator 574.

The insulator 581 is preferably a film functioning as an interlayer film and having a lower permittivity than the insulator 574. When a material with a lower permittivity is used for an interlayer film, parasitic capacitance generated between wirings can be reduced. For example, the relative permittivity of the insulator 581 is preferably lower than 4, further preferably lower than 3. The relative permittivity of the insulator 581 is, for example, preferably 0.7 times or less, further preferably 0.6 times or less the relative permittivity of the insulator 574. When the insulator 581 is an interlayer film formed using a material with a low permittivity, the parasitic capacitance generated between wirings can be reduced.

The concentration of impurities such as water and hydrogen in the film of the insulator 581 is preferably reduced. In this case, for the insulator 581, silicon oxide, silicon oxynitride, silicon nitride oxide, or silicon nitride may be used, for example. For the insulator 581, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Moreover, the insulator 581 can be formed using a resin. The material that can be used for the insulator 581 may be an appropriate combination of the above-described materials.

The insulator 592 and the insulator 594 are stacked in this order over the insulator 574 and the insulator 581.

For the insulator 592, it is preferable to use an insulating film having a barrier property (referred to as a barrier insulating film) which can prevent diffusion of impurities such as water and hydrogen from the substrate 310 or the transistor MTCK to a region above the insulator 592 (e.g., a region where the light-emitting device 650R, the light-emitting device 650G, the light-emitting device 650B, and the like are provided). Accordingly, for the insulator 592, it is preferable to use an insulating material that has a function of inhibiting diffusion of impurities such as a hydrogen atom, a hydrogen molecule, and a water molecule (an insulating material through which the above impurities are less likely to pass). Furthermore, depending on the situation, for the insulator 592, it is preferable to use an insulating material that has a function of inhibiting diffusion of impurities such as a nitrogen atom, a nitrogen molecule, a nitrogen oxide molecule (e.g., N₂O, NO, and NO₂), and a copper atom (an insulating material through which the above oxygen is less likely to pass). It is preferable that the insulator 592 have a function of inhibiting diffusion of oxygen (e.g., one or both of an oxygen atom and an oxygen molecule).

For the film having a barrier property against hydrogen, for example, silicon nitride deposited by a CVD method can be used.

The amount of released hydrogen can be analyzed by thermal desorption spectroscopy (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm² in the TDS in a film-surface temperature range of 50° C. to 500° C., for example.

Like the insulator 581, the insulator 594 is preferably an interlayer film with a low permittivity. Thus, the insulator 594 can be formed using any of the materials usable for the insulator 581.

The permittivity of the insulator 594 is preferably lower than that of the insulator 592. For example, the relative permittivity of the insulator 594 is preferably lower than 4, further preferably lower than 3. The relative permittivity of the insulator 594 is, for example, preferably 0.7 times or less, further preferably 0.6 times or less the relative permittivity of the insulator 592. When the insulator 594 is an interlayer film formed using a material with a low permittivity, the parasitic capacitance generated between wirings can be reduced.

The conductor MPG functioning as a plug or a wiring is embedded in an insulator GI1 and the insulator IS3, and a conductor 596 functioning as a plug or a wiring is embedded in the insulator 592 and the insulator 594. In particular, the conductor MPG and the conductor 596 are electrically connected to the light-emitting device or the like provided above the insulator 594. A plurality of conductors each having a function of a plug or a wiring are collectively denoted by the same reference numeral in some cases. In this specification and the like, a wiring and a plug connected to the wiring may be a single component. That is, part of a conductor functions as a wiring in some cases and part of the conductor functions as a plug in other cases.

As a material of each of plugs and wirings (e.g., the conductor MPG, the conductor 328, the conductor 330, the conductor 356, the conductor 514, and the conductor 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

An insulator 598 and an insulator 599 are formed in order over the insulator 594 and the conductor 596.

Like the insulator 592, for example, the insulator 598 is preferably formed using an insulator having a barrier property against one or more selected from hydrogen, oxygen, and water. Like the insulator 594, the insulator 599 is preferably formed using an insulator having a comparatively low relative permittivity to reduce parasitic capacitance generated between wirings. The insulator 599 has functions of an interlayer insulating film and a planarization film.

The light-emitting device 650 and a connection portion 640 are formed over the insulator 599. The detailed structure of the light-emitting device will be described in detail in Embodiment 5.

The connection portion 640 is referred to as a cathode contact portion in some cases, and is electrically connected to cathodes of the light-emitting device 650R, the light-emitting device 650G, and the light-emitting device 650B. In the connection portion 640 illustrated in FIG. 29, a conductor formed using the same material in the same step as a conductor 611a to a conductor 611c is electrically connected to a common electrode 615 described later. Although FIG. 29 illustrates an example in which the conductor is electrically connected to the common electrode 615 through a common layer 614 described later, the conductor and the common electrode 615 may be in direct contact with each other.

The connection portion 640 may be provided to surround four sides of the display portion in a plan view or may be provided in the display portion (e.g., between adjacent light-emitting elements 650) (not illustrated).

The light-emitting device 650R includes the conductor 611a as a pixel electrode. Similarly, the light-emitting device 650G includes the conductor 611b as a pixel electrode, and the light-emitting device 650B includes the conductor 611c as a pixel electrode.

The conductor 611a, the conductor 611b, and the conductor 611c are each connected to the conductor 596 embedded in the insulator 594 through a conductor (plug) embedded in the insulator 599.

The light-emitting device 650R includes a layer 613a, the common layer 614 over the layer 613a, and the common electrode 615 over the common layer 614. The light-emitting device 650G includes a layer 613b, the common layer 614 over the layer 613b, and the common electrode 615 over the common layer 614. The light-emitting device 650B includes a layer 613c, the common layer 614 over the layer 613c, and the common electrode 615 over the common layer 614.

The semiconductor device 600A employs an SBS structure. The SBS structure can optimize materials and structures of light-emitting devices and thus can extend freedom of choice of materials and structures, whereby the luminance and the reliability can be easily improved.

The semiconductor device 600A has a top-emission structure. The aperture ratio of pixels in a top-emission structure can be higher than that of pixels in a bottom-emission structure because a transistor and the like can be provided to overlap with a light-emitting region of a light-emitting device in the top-emission structure.

The layer 613a is formed to cover the top surface and a side surface of the conductor 611a. Similarly, the layer 613b is formed to cover the top surface and a side surface of the conductor 611b. Similarly, the layer 613c is formed to cover the top surface and a side surface of the conductor 611c. Accordingly, regions provided with the conductor 611a, the conductor 611b, and the conductor 611c can be entirely used as light-emitting regions of the light-emitting device 650R, the light-emitting device 650G, and the light-emitting device 650B, whereby the aperture ratio of the pixels can be increased.

In the light-emitting device 650R, the layer 613a and the common layer 614 can be collectively referred to as an EL layer. Similarly, in the light-emitting device 650G, the layer 613b and the common layer 614 can be collectively referred to as an EL layer. Likewise, in the light-emitting device 650B, the layer 613c and the common layer 614 can be collectively referred to as an EL layer

There is no particular limitation on the structure of the light-emitting device in this embodiment, and a single structure or a tandem structure may be employed.

The layer 613a, the layer 613b, and the layer 613c are each processed into an island shape by a photolithography method. At each of end portions of the layer 613a, the layer 613b, and the layer 613c, an angle between the top surface and side surface is approximately 90°. By contrast, for example, an organic film formed using an FMM (Fine Metal Mask) tends to have a thickness that gradually decreases with decreasing distance to an end portion, and has a sloped top surface in an area ranging from 1 μm to 10 μm, both inclusive, for example; thus, such an organic film has a shape whose top surface and side surface cannot be easily distinguished from each other.

The top surface and side surface of each of the layer 613a, the layer 613b, and the layer 613c are clearly distinguished from each other. Accordingly, as for the layer 613a and the layer 613b which are adjacent to each other, one of the side surfaces of the layer 613a and one of the side surfaces of the layer 613b face to each other. This applies to a combination of any of the layer 613a, the layer 613b, and the layer 613c.

The layer 613a, the layer 613b, and the layer 613c each include at least a light-emitting layer. For example, a structure is preferable in which the layer 613a includes a light-emitting layer that emits red light, the layer 613b includes a light-emitting layer that emits green light, and the layer 613c includes a light-emitting layer that emits blue light. Other than the above colors, cyan, magenta, yellow, or white can be employed for the light-emitting layers.

The layer 613a, the layer 613b, and the layer 613c each preferably include a light-emitting layer and a carrier-transport layer (an electron-transport layer or a hole-transport layer) over the light-emitting layer. Since surfaces of the layer 613a, the layer 613b, and the layer 613c may be exposed in the manufacturing process of the semiconductor device, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

The common layer 614 includes, for example, an electron-injection layer or a hole-injection layer. Alternatively, the common layer 614 may include a stack of an electron-transport layer and an electron-injection layer, or may include a stack of a hole-transport layer and a hole-injection layer. The common layer 614 is shared by the light-emitting device 650R, the light-emitting device 650G, and the light-emitting device 650B. The common layer 614 is not necessarily provided, and the whole EL layers included in the light-emitting devices may each be provided in an island shape like the layer 613a, the layer 613b, and the layer 613c.

The common electrode 615 is shared by the light-emitting device 650R, the light-emitting device 650G, and the light-emitting device 650B. As illustrated in FIG. 29, the common electrode 615 shared by the plurality of light-emitting devices is electrically connected to a conductor included in the connection portion 640.

An insulator 625 preferably has a function of a barrier insulating layer against one or both of water and oxygen. Alternatively, the insulator 625 preferably has a function of inhibiting diffusion of one or both of water and oxygen. Alternatively, the insulator 625 preferably has a function of capturing or fixing (also referred to as gettering) one or both of water and oxygen. When the insulator 625 has a function of a barrier insulating layer or a gettering function, entry of impurities (typically, one or both of water and oxygen) that would diffuse into the light-emitting devices from the outside can be inhibited. With this structure, a highly reliable light-emitting device and a highly reliable semiconductor device can be provided.

The insulator 625 preferably has a low impurity concentration. Accordingly, degradation of the EL layer, which is caused by entry of impurities into the EL layer from the insulator 625, can be inhibited. In addition, when the impurity concentration is reduced in the insulator 625, a barrier property against one or both of water and oxygen can be increased. For example, the insulator 625 preferably has one of a sufficiently low hydrogen concentration and a sufficiently low carbon concentration, desirably has both of them.

As an insulator 627, an insulating layer containing an organic material can be suitably used. As the organic material, a photosensitive organic resin is preferably used; for example, a photosensitive resin composition containing an acrylic resin may be used. In this specification and the like, an acrylic resin refers to not only a polymethacrylic acid ester or a methacrylic resin, but also all the acrylic-based polymers in a broad sense in some cases.

An organic material that can be used for the insulator 627 is not limited to the above materials. For the insulator 627, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulator 627 in some cases. For the insulator 627, for example, a photoresist can be used as the photosensitive resin in some cases. As the photosensitive resin, a positive material or a negative material can be used.

For the insulator 627, a material absorbing visible light may be used. When the insulator 627 absorbs light from the light-emitting device, leakage of light (stray light) from the light-emitting device to the adjacent light-emitting device through the insulator 627 can be inhibited. Thus, the display quality of the semiconductor device can be improved. Since the display quality of the semiconductor device can be improved without using a polarizing plate, the weight and thickness of the semiconductor device 1 can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer.

For example, the insulator 627 can be formed by a wet film formation method such as spin coating, dipping, spray coating, inkjetting, dispensing, screen printing, offset printing, doctor blade coating, slit coating, roll coating, curtain coating, or knife coating. Specifically, an organic insulating film that is to be the insulator 627 is preferably formed by spin coating.

The insulator 627 is formed at a temperature lower than the upper temperature limit of the EL layer. The typical substrate temperature in formation of the insulator 627 is lower than or equal to 200° C., preferably lower than or equal to 180° C., further preferably lower than or equal to 160° C., still further preferably lower than or equal to 150° C., yet still further preferably lower than or equal to 140° C.

A side surface of the insulator 627 preferably has a tapered shape. When an end portion of the side surface of the insulator 627 has a forward tapered shape (less than 90°, preferably less than or equal to 60°, further preferably less than or equal to 45°), the common layer 614 and the common electrode 615 that are provided over the end portion of the side surface of the insulator 627 can be formed with good coverage without disconnection, local thinning, or the like. Consequently, the in-plane uniformity of the common layer 614 and the common electrode 615 can be improved, so that the display quality of the semiconductor device can be improved.

The top surface of the insulator 627 preferably has a convex shape in a cross-sectional view of the semiconductor device. The convex shape of the top surface of the insulator 627 is preferably a shape gently bulged toward the center. The convex portion at the center of the top surface of the insulator 627 preferably has a shape connected smoothly to the tapered end portion of the side surface. When the insulator 627 has such a shape, the common layer 614 and the common electrode 615 can be formed with good coverage over the entire insulator 627.

The insulator 627 is formed in a region between two EL layers (e.g., a region between the layer 613a and the layer 613b). At this time, part of the insulator 627 is placed at a position sandwiched between an end portion of a side surface of one of the EL layers (e.g., the layer 613a) and an end portion of the side surface of the other of the EL layers (e.g., the layer 613b).

One end portion of the insulator 627 preferably overlaps with the conductor 611a functioning as a pixel electrode, and the other end portion of the insulator 627 preferably overlaps with the conductor 611b functioning as a pixel electrode. With such a structure, the end portion of the insulator 627 can be formed over a flat or substantially flat region of the layer 613a (the layer 613b). This makes it relatively easy to process the tapered shape of the insulator 627 as described above.

By providing the insulator 627 and the like as described above, a disconnected portion and a locally thinned portion can be prevented from being formed in the common layer 614 and the common electrode 615 from a flat or substantially flat region in the layer 613a to a flat or substantially flat region in the layer 613b. Thus, between the light-emitting devices, a connection defect caused by the disconnected portion and an increase in electric resistance caused by the locally thinned portion can be inhibited from occurring in the common layer 614 and the common electrode 615.

In the semiconductor device of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the semiconductor device of this embodiment includes a region where a distance between two adjacent island-shaped EL layers is less than or equal to 1 μm, preferably less than or equal to 0.5 μm (500 nm), further preferably less than or equal to 100 nm. The distance between light-emitting devices is shortened in this manner, whereby a high-resolution semiconductor device with a high aperture ratio can be provided.

A protective layer 631 is provided over the light-emitting device 650. The protective layer 631 is a film functioning as a passivation film for protecting the light-emitting device 650. Provision of the protective layer 631 covering the light-emitting device can inhibit an impurity such as water and oxygen from entering the light-emitting device, and increase the reliability of the light-emitting device 650. For the protective layer 631, aluminum oxide, silicon nitride, or silicon nitride oxide can be used, for example.

The protective layer 631 and a substrate 610 are bonded to each other with an adhesive layer 607. A solid sealing structure, a hollow sealing structure, or the like can be employed to seal the light-emitting devices. In FIG. 29, a solid sealing structure is employed in which a space between the substrate 310 and the substrate 610 is filled with the adhesive layer 607. Alternatively, a hollow sealing structure may be employed, in which the space is filled with an inert gas (e.g., nitrogen or argon). Here, the adhesive layer 607 may be provided not to overlap with the light-emitting devices. The space may be filled with a resin other than the frame-shaped adhesive layer 607.

For the adhesive layer 607, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet may be used.

The semiconductor device 600A has a top-emission structure. Light from the light-emitting device is emitted toward the substrate 610 side. Thus, for the substrate 610, a material having a high visible-light-transmitting property is preferably used. For example, as the substrate 610, a substrate having a high visible-light-transmitting property may be selected from substrates usable as the substrate 310. The pixel electrode contains a material that reflects visible light, and a counter electrode (the common electrode 615) contains a material that transmits visible light.

The semiconductor device of one embodiment of the present invention may be not a top-emission semiconductor device but a bottom-emission semiconductor device where light from the light-emitting device is emitted to the substrate 310 side. In that case, a substrate having a high visible-light-transmitting property is selected as the substrate 310.

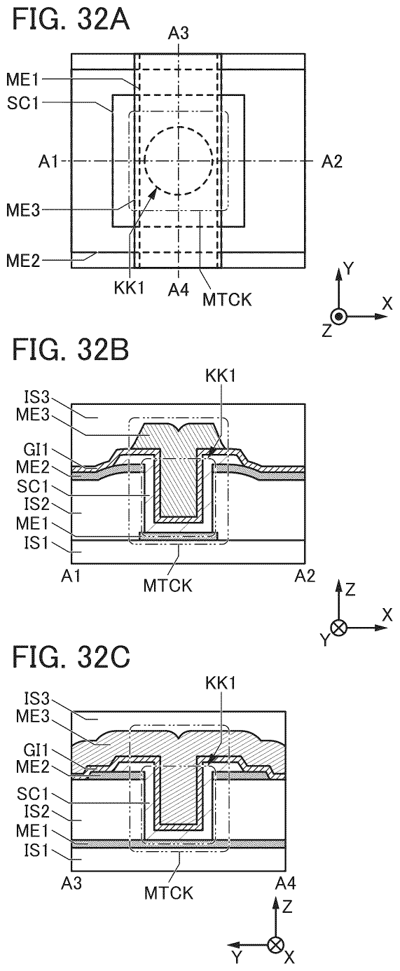

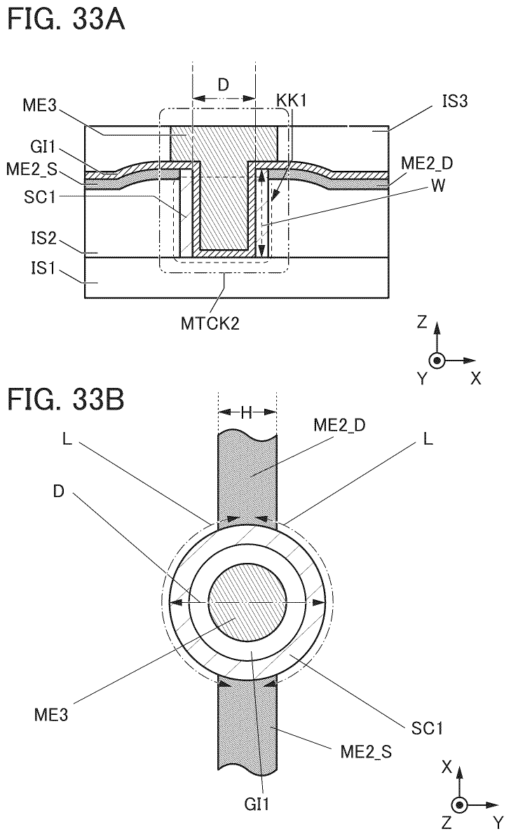

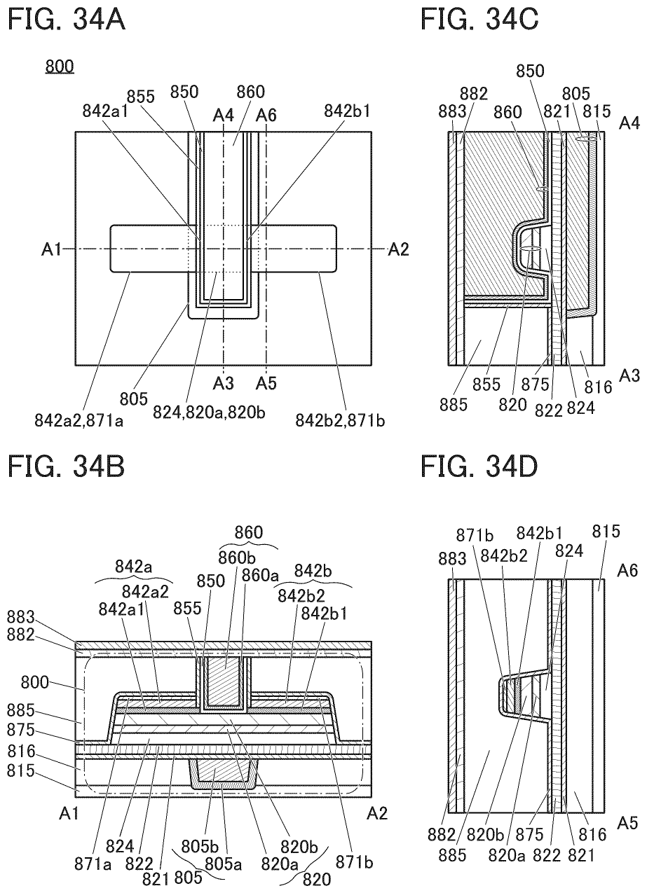

Although the element layer 630 of the semiconductor device 600A in FIG. 29 has a structure in which the transistor MTCK is included, one embodiment of the present invention is not limited thereto. There is no particular limitation on the structure of the transistor included in the semiconductor device of one embodiment of the present invention. One or more kinds to transistors can be used in the semiconductor device of one embodiment of the present invention. For example, one or more of the transistor MTCK illustrated in FIG. 32, a transistor MTCK2 illustrated in FIG. 33, and a transistor 800 illustrated in FIG. 34 can be used. One or both of an OS transistor and a Si transistor can be used in the semiconductor device of one embodiment of the present invention.

### Structure Example 2 of Semiconductor Device

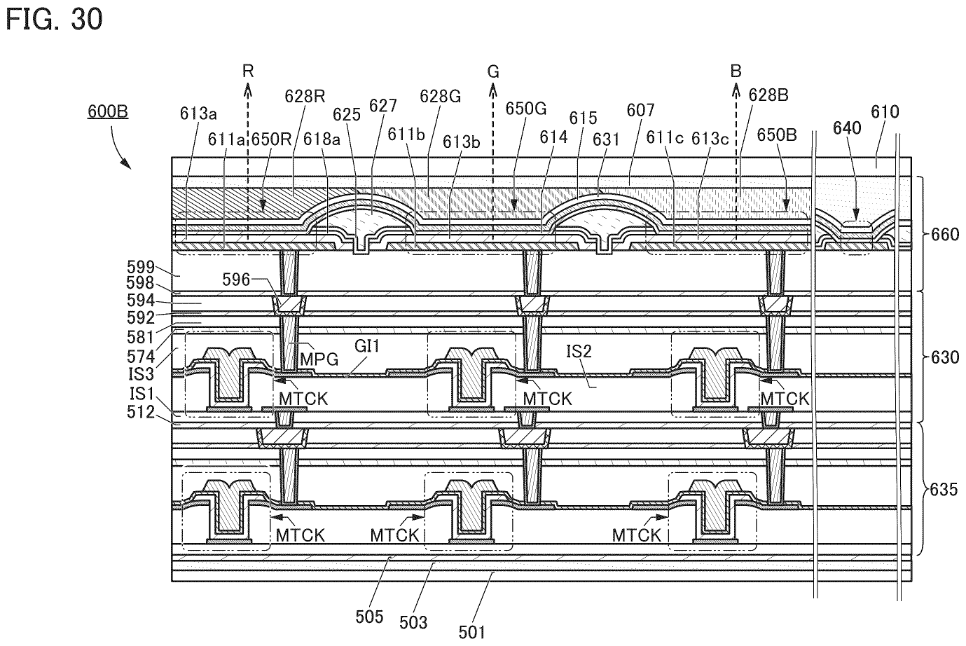

FIG. 30 illustrates a cross-sectional view of a semiconductor device 600B.

The semiconductor device 600B can be a flexible semiconductor device (also referred to as a flexible display) when a substrate having flexibility is used as each of a substrate 501 and the substrate 610. The substrate 501 is bonded to an insulating layer 505 with an adhesive layer 503. The substrate 610 is bonded to the protective layer 631 with the adhesive layer 607. An example of a manufacturing method of the flexible device will be described later in this embodiment.

The element layer 660 of the semiconductor device 600B is different from the element layer 660 of the semiconductor device 600A mainly in that the layer 613a, the layer 613b, and the layer 613c have the same structure and that a coloring layer 628R, a coloring layer 628G, and a coloring layer 628B are provided.

The layer 613a, the layer 613b, and the layer 613c are formed using the same material in the same step. The layer 613a, the layer 613b, and the layer 613c are isolated from each other. When the EL layer is provided in an island shape for each light-emitting device, leakage current between adjacent light-emitting devices (sometimes referred to as horizontal-direction leakage current, horizontal leakage current, or lateral leakage current) can be inhibited. Accordingly, unintentional light emission due to crosstalk can be prevented, and color mixture between adjacent light-emitting devices can be inhibited, so that a semiconductor device with extremely high contrast can be obtained.

The light-emitting devices 650R, 650G, and 650B illustrated in FIG. 30 emit white light, for example. White light emitted from the light-emitting devices 650R, 650G, and 650B passes through the coloring layer 628R, the coloring layer 628G, and the coloring layer 628B, whereby light of a desired color can be obtained.

In the case where a light-emitting device configured to emit white light has a microcavity structure, light with a specific wavelength such as red, green, or blue is sometimes intensified and emitted.

Light emitted from the light-emitting device 650R is extracted as red light to the outside of the semiconductor device 600B through the coloring layer 628R. Similarly, light emitted from the light-emitting device 650G is extracted as green light to the outside of the semiconductor device 600B through the coloring layer 628G. Light emitted from the light-emitting device 650B is extracted as blue light to the outside of the semiconductor device 600B through the coloring layer 628B.

The light-emitting device emitting white light preferably has a tandem structure. A structure example of the light-emitting device having a tandem structure will be described in detail in Embodiment 5.

Alternatively, the light-emitting devices 650R, 650G, and 650B illustrated in FIG. 30 emit blue light, for example. In that case, the layer 613a, the layer 613b, and the layer 613c each include one or more light-emitting layers emitting blue light. In a subpixel emitting blue light, blue light emitted from the light-emitting device 650B can be extracted. In a subpixel emitting red light and a subpixel emitting green light, a color conversion layer is provided between the light-emitting device 650R and the coloring layer 628R and between the light-emitting device 650G and the coloring layer 628G, so that blue light emitted from the light-emitting device 650R or the light-emitting device 650G is converted into light with a longer wavelength, whereby red or green light can be extracted. When light transmitted through the color conversion layer is extracted through the coloring layer, light other than light of a desired color can be absorbed by the coloring layer, and color purity of light exhibited by a subpixel can be improved.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an inkjet method, an etching method using a photolithography method, or the like.

The element layer 630 of the semiconductor device 600B has a structure similar to that of the element layer 630 of the semiconductor device 600A; thus, the detailed description thereof is omitted.

The semiconductor device 600B is different from the semiconductor device 600A in not including the element layer 620 but including an element layer 635. The element layer 635 has a structure similar to that of the element layer 630.

At least part of a transistor included in the element layer 635 is electrically connected to a conductive layer or a transistor included in the element layer 630 through a plug, a wiring, and the like. The wiring layer 670 may be provided between the element layer 630 and the element layer 635.

One or both of a pixel circuit and a driver circuit of the semiconductor device are preferably provided in the element layer 635.

Although FIG. 30 illustrates an example in which two element layers including OS transistors are stacked (the element layer 630 and the element layer 635), the number of stacked element layers is not limited thereto, and may be three or more. In the case where three or more element layers including OS transistors are stacked, for example, it is preferable that the lowermost layer be used for a driver circuit (one or both of a gate driver and a source driver) of the semiconductor device, the uppermost layer be used for a pixel circuit of the semiconductor device, and layers between them be each used for a pixel circuit or a driver circuit.

In the case where a structure is employed in which element layers including OS transistors are stacked as illustrated in FIG. 30, a semiconductor device that inhibits an increase in weight and is not easily broken can be provided. In the case where the element layer 635 has a structure including Si transistors as illustrated in FIG. 29, breakage due to force by bending, twisting, or the like might be caused because a silicon substrate where the Si transistors are provided is poor in flexibility. The element layers including OS transistors illustrated in FIG. 30, on the other hand, can be stacked over a flexible substrate made of a polyimide resin or the like. In that case, a semiconductor device that can be freely changed in shape can be obtained, and the risk of being broken by impact can be reduced.

### Structure Example 3 of Semiconductor Device

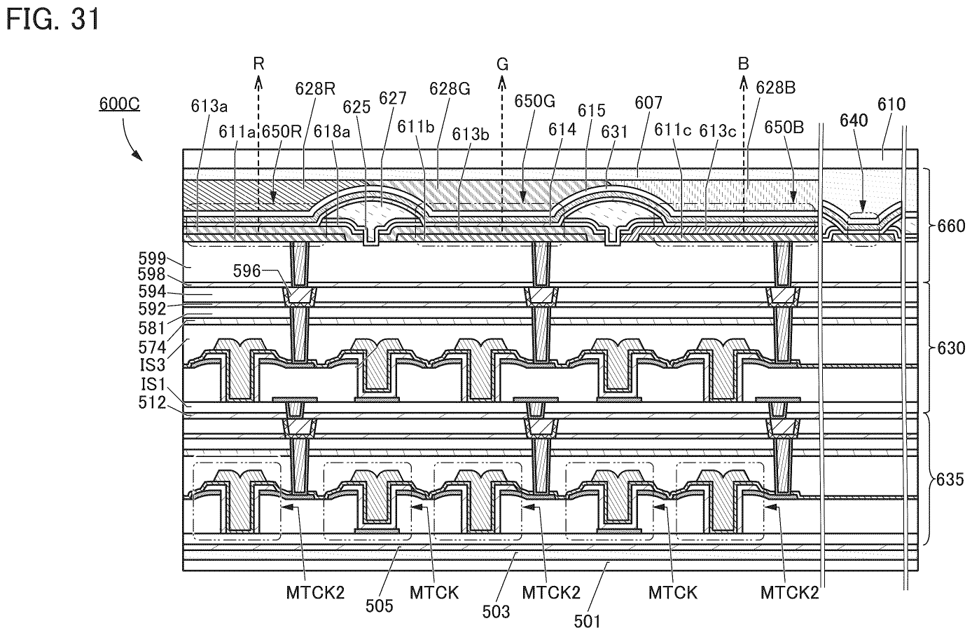

FIG. 31 illustrates a cross-sectional view of a semiconductor device 600C.

The element layer 660 of the semiconductor device 600C has a structure similar to that of the element layer 660 of the semiconductor device 600B; thus, the detailed description thereof is omitted.

The element layer 630 and the element layer 635 of the semiconductor device 600C each include a plurality of the transistors MTCK and a plurality of the transistors MTCK2.

The transistor MTCK has an extremely small channel length and can have a large channel width, so that a high on-state current can be achieved; the details thereof will be described later. The transistor MTCK2, on the other hand, has an extremely small channel width and can have a large channel length, so that an appropriate on-state current can be obtained and the transistor design is facilitated. The transistor MTCK2 and the transistor MTCK can be formed, with manufacturing steps some of which are shared, separately over the same substrate. In a pixel circuit (corresponding to the element layer 630) of the semiconductor device, for example, the transistor MTCK2 can be used as a driving transistor for controlling current flowing through the light-emitting device, and the transistor MTCK can be used as a transistor functioning as a switch. The transistor MTCK and the transistor MTCK2 can be combined to obtain a driver circuit (corresponding to one or both of a gate driver and a source driver, here, the element layer 635) of the semiconductor device. Two kinds of transistors can be used selectively according to the respective purposes of transistors included in the circuits; thus, the semiconductor device can have higher functionality and higher reliability. The stacking order of the element layer 630 and the element layer 635 is not limited to the above. For example, a structure in which the element layer 635 is provided over the element layer 630, that is, a structure in which a driver circuit of a display apparatus is provided over a pixel circuit of the display apparatus may be employed.

The other components are the same as those of the semiconductor device 600B; thus, the above description can be referred to.

### Structure Example 1 of Transistor

FIG. 32A to FIG. 32C illustrate an example of a semiconductor device (showing, for example, a pixel circuit or a driver circuit) including the transistor MTCK. Specifically, FIG. 32A illustrates a schematic plan view of the transistor MTCK. FIG. 32B is a schematic cross-sectional view corresponding to a portion taken along dashed-dotted line A1-A2 in FIG. 32A, and is also a schematic cross-sectional view of the transistor MTCK. FIG. 32C is a schematic cross-sectional view corresponding to a portion taken along dashed-dotted line A3-A4 in FIG. 32A, and is also a schematic cross-sectional view of the transistor MTCK.

In FIG. 32A to FIG. 32C, the direction along the dashed-dotted line A1-A2 is the X direction and the direction along the dashed-dotted line A3-A4 is the Y direction. Furthermore, the direction perpendicular to both the X direction and the Y direction is referred to as the Z direction. The X direction and the Y direction can be perpendicular to each other. The definition of the X direction, the Y direction, and the Z direction applies to some of the following drawings and does not apply to other drawings. In the description of the schematic plan view in FIG. 32A and the like, the right side is referred to as the X direction, the left side is referred to as the −X direction, the upper side is referred to as the Y direction, and the lower side is referred to as the −Y direction in some cases. In the description of the schematic cross-sectional view in FIG. 32B and the like, the right side is referred to as the X direction, the left side is referred to as the −X direction, the upper side is referred to as the Z direction, and the lower side is referred to as the −Z direction in some cases. In the description of the schematic cross-sectional view in FIG. 32C, the right side is referred to as the −Y direction, the left side is referred to as the Y direction, the upper side is referred to as the Z direction, and the lower side is referred to as the −Z direction in some cases.

The transistor MTCK illustrated in FIG. 32A to FIG. 32C includes the insulator IS1 to the insulator IS3, the insulator GI1, a conductor ME1 to a conductor ME3, and a semiconductor SC.

The insulator IS1 functions as a base film above which a source, a drain, and a channel formation region of the transistor MTCK are provided, for example. For the insulator IS1, silicon oxide, silicon oxynitride, silicon nitride oxide, or silicon nitride may be used, for example. For the insulator IS1, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for example, a resin can be used for the insulator IS1. A material combined with any of the above insulating materials as appropriate may be used for the insulator IS1.

The conductor MET is a conductor (sometimes referred to as a terminal, a wiring, or the like) functioning as one of a source and a drain in the transistor MTCK. The conductor ME2 is a conductor (sometimes referred to as a terminal, a wiring, or the like) functioning as the other of the source and the drain in the transistor MTCK.

In FIG. 32A to FIG. 32C, the conductor MET is provided to extend in the Y direction as a wiring, for example. The conductor ME2 is provided to extend in the X direction as a wiring, for example.

For each of the conductor ME1, the conductor ME2, and the conductor ME3, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum or an alloy containing two or more selected from the above metal elements as components or an alloy combining two or more selected from the above metal elements. Alternatively, for each of the conductive film MET, the conductor ME2, and the conductor ME3, for example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus or arsenic), or silicide (e.g., nickel silicide) may be used.

For the conductor MET, the conductor ME2, and the conductor ME3, an oxide semiconductor may be used. Examples of an oxide conductor include an indium oxide, a zinc oxide, an In—Sn oxide (ITO), an In—Zn oxide (also referred to as an IZO (registered trademark)), an In—W oxide, an In—W—Zn oxide, an In—Ti oxide, an In—Ti—Sn oxide, an In—Sn—Si oxide (also referred to as an ITO containing silicon or an ITSO), zinc oxide to which gallium is added, and an In—Ga—Zn oxide. A conductive oxide containing indium is particularly preferable because of its high conductivity.

A stack of a plurality of conductive films formed using the above materials may be used. For example, a stacked-layer structure combining a material containing the above-described metal element and a conductive material containing oxygen may be employed. Specific examples of the stacked-layer structure of conductive films include a stacked-layer structure of an indium oxide and a metal film containing ruthenium. A stacked-layer structure combining a material containing the above-described metal element and a conductive material containing nitrogen may be employed. A stacked-layer structure combining a material containing the above-described metal element, a conductive material containing oxygen, and a conductive material containing nitrogen may be employed.

The insulator IS2 functions as an interlayer film that separates the source and the drain of the transistor MTCK, for example. A material that can be used for the insulator IS1 can be used for the insulating film IS2, for example. In the case where the semiconductor SC1 is a metal oxide functioning as an oxide semiconductor, silicon oxide, silicon oxynitride, or porous silicon oxide is preferably used. These materials are capable of easily forming a region containing oxygen that is released by heating, so that the released oxygen can be supplied to the metal oxide. This reduces the carrier concentration of the metal oxide at the interface of the semiconductor SC1 in contact with the insulator IS2 and in the vicinity of the interface, whereby the interface of the semiconductor SC1 and the vicinity of the interface become i-type or substantially i-type. Accordingly, the interface of the semiconductor SC1 and the vicinity of the interface can function as the channel formation region of the transistor MTCK.

The semiconductor SC1 can be a metal oxide functioning as an oxide semiconductor, for example. In that case, the transistor MTCK is an OS transistor. The metal oxide preferably contains at least indium or zinc, for example. In particular, indium and zinc are preferably contained. In addition to them, an element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin.

More specifically, examples of the metal oxide include an indium oxide, a gallium oxide, a zinc oxide, an indium zinc oxide (also referred to as an In—Zn oxide or an IZO (registered trademark)), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (In—Ga—Sn oxide), a gallium zinc oxide (also referred to as a Ga—Zn oxide or a GZO), an aluminum zinc oxide (also referred to as an Al—Zn oxide or an AZO), an indium aluminum zinc oxide (also referred to as an In—Al—Zn oxide or an IAZO), an indium tin zinc oxide (also referred to as an In—Sn—Zn oxide or an ITZO (registered trademark)), an indium titanium zinc oxide (In—Ti—Zn oxide), an indium gallium zinc oxide (also referred to as an In—Ga—Zn oxide or an IGZO), an indium gallium tin zinc oxide (also referred to as an In—Ga—Sn—Zn oxide or an IGZTO), and an indium gallium aluminum zinc oxide (also referred to as an In—Ga—Al—Zn oxide, an IGAZO, an IGZAO, or an IAGZO). The examples of the metal oxide also include an indium tin oxide containing silicon, a gallium tin oxide (Ga—Sn oxide), and an aluminum tin oxide (Al—Sn oxide). A material that does not contain Zn, typified by an indium oxide or the like, has high compatibility with a Si process and thus is suitable. A material containing Zn, on the other hand, can increase the crystallinity and thus is suitable.

When the semiconductor SC1 is a metal oxide functioning as an oxide semiconductor, it is suitably formed by an ALD (Atomic Layer Deposition) method. When the semiconductor SC1 is formed in a region having a step as illustrated in FIG. 32B and FIG. 32C, the use of an ALD method achieves favorable coverage.

In the case where a metal oxide functioning as an oxide semiconductor is used for the semiconductor SC1, microwave treatment is preferably performed in an oxygen-containing atmosphere during or after the deposition of the metal oxide to reduce the impurity concentration in the metal oxide. Specific examples of impurities include hydrogen and carbon. The microwave treatment can increase the crystallinity of the metal oxide in some cases. Here, the microwave treatment refers to, for example, treatment using an apparatus including a power source that generates high-density plasma with the use of a microwave.

It is preferable to use a metal oxide layer having crystallinity as the semiconductor SC1. For example, a metal oxide layer having a CAAC (c-axis aligned crystal) structure, a polycrystalline structure, a nano-crystal (nc) structure, or the like can be used. With use of the metal oxide layer having crystallinity as the semiconductor SC1, the density of defect states in the semiconductor SC1 can be reduced, which enables the semiconductor device to have high reliability.

For example, an In—Ga—Zn oxide is preferably used for the semiconductor SC1. The In—Ga—Zn oxide is preferably a metal oxide with a composition of In:Ga:Zn=1:1:1 [atomic ratio] or in the neighborhood thereof, a composition of In:Ga:Zn=4:2:3 [atomic ratio] or in the neighborhood thereof, or a composition of In:Ga:Zn=3:1:2 [atomic ratio] or in the neighborhood thereof, in particular. For another example, an In—Zn oxide is preferably used for the semiconductor film SC1A. The In—Zn oxide is further preferably a metal oxide with a composition of In:Zn=4:1 [atomic ratio] or in the neighborhood thereof, in particular.

The semiconductor SC1 preferably has a stacked-layer structure of a plurality of oxide layers that differ in the atomic ratio of metal atoms. For example, a first metal oxide and a second metal oxide formed over the first metal oxide are assumed as the metal oxide. In the case where each metal oxide contains at least indium (In) and the element M, the proportion of the number of atoms of the element M contained in the first metal oxide to the number of atoms of all elements that constitute the first metal oxide is preferably higher than the proportion of the number of atoms of the element M contained in the second metal oxide to the number of atoms of all elements that constitute the second metal oxide. In addition, the atomic ratio of the element M to In in the first metal oxide is preferably higher than the atomic ratio of the element M to In in the second metal oxide.

Specifically, as the first metal oxide, a metal oxide with a composition of In:Ga:Zn=1:3:4 [atomic ratio] or in the neighborhood thereof, a composition of In:Ga:Zn=1:3:2 [atomic ratio] or in the neighborhood thereof, or a composition of In:Ga:Zn=1:1:0.5 [atomic ratio] or in the neighborhood thereof can be used. As the second metal oxide, a metal oxide with In:Ga:Zn=1:1:1 [atomic ratio] or a composition in the neighborhood thereof, In:Ga:Zn=4:2:3 [atomic ratio] or a composition in the neighborhood thereof, or In:Ga:Zn=3:1:2 [atomic ratio] or a composition in the neighborhood thereof is used. Note that the neighborhood of the composition includes ±30% of an intended atomic ratio.

In this case, the second metal oxide serves as a main carrier path. When the first metal oxide has the above structure, the density of defect states at the interface between the first metal oxide and the second metal oxide can be made low. Thus, the influence of interface scattering on carrier conduction is small, and the transistor can have a high on-state current and high frequency characteristics.

In a region of the insulator IS2 where the transistor MTCK is provided, an opening KK1 whose side surface is substantially perpendicular to the XY plane (the taper angle is greater than or equal to 70° and less than or equal to 110°) is formed. The semiconductor SC1 including the channel formation region of the transistor MTCK is provided to be in contact with the conductor MET and the conductor ME2 through the opening KK1.

In the transistor MTCK, the insulator GI1 is provided over the semiconductor SC1. Specifically, the insulator GI1 is positioned above and overlaps with the channel formation region included in the semiconductor SC1 in the plan view. The insulator GI1 functions as a gate insulating film of the transistor MTCK.

For the insulator GI1, a single layer or stacked layers using an insulator containing what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST) is preferably used, for example. Alternatively, for the insulator GI1, an insulator having a high dielectric constant such as an oxide containing aluminum and hafnium, an oxynitride containing aluminum and hafnium, an oxide containing silicon and hafnium, an oxynitride containing silicon and hafnium, or a nitride containing silicon and hafnium may be used. A material that can be used for the insulator IS1 may be used for the insulator GI1. For example, silicon oxide, silicon oxynitride, silicon nitride oxide, or silicon nitride may be used for the insulator GI1.

In the transistor MTCK, the conductor ME3 is provided over the insulator GI1 to fill the opening KK1. The conductor ME3 is a conductor (sometimes referred to as a terminal, a wiring, or the like) functioning as a gate in the transistor MTCK.

In FIG. 32A to FIG. 32C, the conductor ME3 is provided to extend in the Y direction as a wiring, for example.

The insulator IS3 is a film functioning as an interlayer film, for example. The insulator IS3 preferably includes an insulating material with a low dielectric constant. The use of an insulating material with a low dielectric constant for the interlayer film can reduce the parasitic capacitance between wirings.

The materials that can be used for the insulator IS1 can be used for the insulator IS3, for example.

As described above, in the transistor MTCK illustrated in FIG. 32A to FIG. 32C, the conductor ME1 functioning as one of the source and the drain is positioned below the insulator IS2 serving as an interlayer film, and the conductor ME2 functioning as the other of the source and the drain is positioned above the insulator IS2. Thus, the channel formation region of the transistor MTCK is provided along the opening of the insulator IS2.

In the transistor MTCK, the source and the drain are positioned at different levels, so that current flowing through the semiconductor layer flows in the height direction. In other words, the channel length direction can be regarded as having a component of the height direction (the vertical direction); accordingly, the transistor MTCK can also be referred to as a VFET (Vertical Field Effect Transistor), a vertical transistor, a vertical-channel transistor, a vertical-channel-type transistor, and the like.

As illustrated in FIG. 32A to FIG. 32C, when the channel formation region of the transistor is provided along a side surface of the opening of the insulator functioning as an interlayer film, the area occupied by the transistor can be smaller than that in the case where the channel formation region of the transistor is provided along the X-Y plane. Thus, when a circuit is formed using one or both of the transistors MTCK, the area of the circuit can be small. As a result, the semiconductor device including the circuit or a semiconductor device can be downsized.

### Structure Example 2 of Transistor

FIG. 33A illustrates a cross-sectional view of the transistor MTCK2, taken along XZ plane, having a structure different from that in FIG. 32B. FIG. 33B illustrates a cross-sectional view taken along XY plane.

The transistor MTCK2 is different from the transistor MTCK mainly in that the conductor MET is not included, conductors ME2_S and ME2_D are included instead of the conductor ME2, and the semiconductor SC1 has a different shape. The conductor ME2_S functions as a source electrode, and the conductor ME2_D functions as a drain electrode.

The semiconductor SC1 has a ring-like shape. Specifically, the semiconductor SC1 includes a region in contact with a side surface of the conductor ME2_S, a region in contact with a side surface of the conductor ME2_D, and a region in contact with a side surface of the insulator IS2 in the opening KK1. Here, the semiconductor SC1 is not in contact with the top surfaces of the conductors ME2_S and ME2_D. The semiconductor SC1 having such a shape can be formed through processing with anisotropic etching, for example. As illustrated in FIG. 31, the semiconductor SC1 may be in contact with the top surfaces of the conductors ME2_S and ME2_D.

As illustrated in FIG. 33B, widths H of the conductor ME2_S and the conductor ME2_D are smaller than the maximum width D of the opening KK1. In that case, the circumferential direction of the opening KK1 corresponds to the channel length direction of the transistor MTCK2. Here, since the semiconductor SC1 has a ring-like shape, two kinds of current paths (i.e., channels) from the conductor ME2_S to the conductor ME2_D exist. The semiconductor SC1 does not necessarily have a ring-like shape and may be in contact with both the conductor ME2_S and the conductor ME2_D.

The channel length can be controlled by the shape and size of the opening KK1. For example, in the case where the channel length is desired to be increased, the perimeter of the opening KK1 is made long. Although an example in which the opening KK1 has a circular shape in a plan view is described, the present invention is not limited thereto. For example, the opening KK1 can have an elliptical shape or a quadrangular shape with rounded corners besides the circular shape in a plan view. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel width can be increased. Alternatively, an elliptical shape, a polygonal shape with rounded corners, a closed curve shape in which a straight line and a curve are combined, or the like can be employed. In that case, the maximum width of the opening KK1 is preferably calculated as appropriate in accordance with the shape of the uppermost portion of the opening KK1. For example, in the case where the opening portion is square or rectangular in a plan view, the maximum width of the opening KK1 is preferably the length of a diagonal line of the uppermost portion of the opening KK1. The transistor MTCK2 has a distance along the perimeter direction of the opening KK1 as described above, so that current flows in the lateral direction. Furthermore, it can be said that the transistor MTCK2 includes a component making current flow also in the thickness direction of the conductor ME2_S and the conductor ME2_D, i.e., in the height direction (vertical direction); thus, the transistor of one embodiment of the present invention can be referred to as a VLFET (Vertical Lateral Field Effect Transistor).

As illustrated in FIG. 33A, the height of the semiconductor SC1 corresponds to a channel width W of the transistor MTCK2. Thus, the channel width W of the transistor MTCK2 can be controlled by the thickness of the insulator IS2. Accordingly, an extremely minute structure can be obtained in which the channel width of the transistor MTCK2 is smaller than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm).

The transistor MTCK has an extremely small channel length and can have a large channel width, so that a high on-state current can be achieved. The transistor MTCK2, on the other hand, has an extremely small channel width and can have a large channel length, so that an appropriate on-state current can be obtained and the transistor design is facilitated. The transistor MTCK and the transistor MTCK2 can be formed, with manufacturing steps some of which are shared, separately over the same substrate. As in the semiconductor device illustrated in FIG. 31, for example, the transistor MTCK2 can be used as a driving transistor for controlling current flowing through the light-emitting device, and the transistor MTCK can be used as a transistor functioning as a switch. Since the transistor MTCK and the transistor MTCK2 can be combined to form a driver circuit, the semiconductor device can have higher functionality and higher reliability.

### Structure Example 3 of Transistor

FIG. 34A illustrates a top view of the transistor 800. FIG. 34B illustrates a cross-sectional view taken along dashed-dotted line A1-A2 in FIG. 34A. FIG. 34B is also a cross-sectional view of the transistor 800 in the channel length direction. FIG. 34C illustrates a cross-sectional view taken along dashed-dotted line A3-A4 in FIG. 34A. FIG. 34C is also a cross-sectional view of the transistor 800 in the channel width direction. FIG. 34D illustrates a cross-sectional view taken along dashed-dotted line A5-A6 in FIG. 34A. FIG. 34D is also a cross-sectional view of the transistor 800 in the channel width direction. For clarity of the drawing, some components are not illustrated in the top view of FIG. 34A.

The transistor 800 includes a conductor 805 (a conductor 805a and a conductor 805b) provided to be embedded in an insulator 816, an insulator 821 over the insulator 816 and the conductor 805, an insulator 822 over the insulator 821, an insulator 824 over the insulator 822, an oxide 820 (an oxide 820a and an oxide 820b) over the insulator 824, a conductor 842a (a conductor 842a1 and a conductor 842a2) and a conductor 842b (a conductor 842b1 and a conductor 842b2) over the oxide 820, an insulator 871a over the conductor 842a, an insulator 871b over the conductor 842b, an insulator 850 over the oxide 820, and a conductor 860 (a conductor 860a and a conductor 860b) over the insulator 850.

An insulator 875 is provided over the insulators 871a and 871b, and an insulator 885 is provided over the insulator 875. An insulator 855, the insulator 850, and the conductor 860 are placed in an opening provided in the insulator 885 and the insulator 875. An insulator 882 is provided over the insulator 885 and the conductor 860. An insulator 883 is provided over the insulator 882. An insulator 815 is provided below the insulator 816 and the conductor 805. The insulator 855 is provided between the insulator 850 and the conductor 842a2, the conductor 842b2, the insulator 871a, the insulator 871b, the insulator 875, and the insulator 885.

The insulator 815, the insulator 816, the conductor 805, the insulator 821, the insulator 822, the insulator 824, the oxide 820, the conductor 842a, the conductor 842b, the insulator 871a, the insulator 871b, the insulator 875, the insulator 885, the insulator 855, the insulator 850, the conductor 860, the insulator 882, and the insulator 883 may each have a single-layer structure or a stacked-layer structure.

The oxide 820 includes a region functioning as a channel formation region of the transistor 800. The conductor 860 includes a region functioning as a first gate electrode (an upper gate electrode) of the transistor 800. The insulator 850 includes a region functioning as a first gate insulator of the transistor 800. The conductor 805 includes a region functioning as a second gate electrode (a lower gate electrode) of the transistor 800. The insulator 824, the insulator 822, and the insulator 821 each include a region functioning as a second gate insulator of the transistor 800.

The conductor 842a includes a region functioning as one of a source electrode and a drain electrode of the transistor 800. The conductor 842b includes a region functioning as the other of the source electrode and the drain electrode of the transistor 800.

The oxide 820 preferably includes the oxide 820a over the insulator 824 and the oxide 820b over the oxide 820a. Including the oxide 820a under the oxide 820b makes it possible to inhibit diffusion of impurities into the oxide 820b from components formed below the oxide 820a.

Note that the oxide 820 is not limited to having a two-layer structure of the oxide 820a and the oxide 820b. The oxide 820 may have a single-layer structure of the oxide 820b or a stacked-layer structure of three or more layers, for example.

The oxide 820b includes the channel formation region of the transistor 800 and a source region and a drain region provided to sandwich the channel formation region. At least part of the channel formation region overlaps with the conductor 860. The source region overlaps with the conductor 842a, and the drain region overlaps with the conductor 842b. Note that the source region and the drain region can be interchanged with each other.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

The channel formation region, the source region, and the drain region may each be formed not only in the oxide 820b but also in the oxide 820a.

In the oxide 820, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

An oxide semiconductor is preferably used for the oxide 820 (the oxide 820a and the oxide 820b).

The oxide 820 preferably has a stacked-layer structure of a plurality of oxide layers with different chemical compositions. For example, the atomic ratio of the element M to a metal element that is a main component in the metal oxide used for the oxide 820a is preferably greater than the atomic ratio of the element M to a metal element that is a main component in the metal oxide used for the oxide 820b. Moreover, the atomic ratio of the element M to In in the metal oxide used for the oxide 820a is preferably greater than the atomic ratio of the element M to In in the metal oxide used for the oxide 820b. With this structure, impurities and oxygen can be inhibited from diffusing into the oxide 820b from the components formed below the oxide 820a.

Furthermore, the atomic ratio of In to the element M in the metal oxide used for the oxide 820b is preferably greater than the atomic ratio of In to the element Min the metal oxide used for the oxide 820a. With this structure, the transistor 800 can have a high on-state current and excellent frequency characteristics.

When the oxide 820a and the oxide 820b include a common element as the main component besides oxygen, the density of defect states at the interface between the oxide 820a and the oxide 820b can be decreased. The density of defect states at the interface between the oxide 820a and the oxide 820b can be decreased. Thus, the influence of interface scattering on carrier conduction is reduced, and the transistor 800 can have a high on-state current and high frequency characteristics.

Specifically, for the oxide 820a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used. For the oxide 820b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that the neighborhood of the composition includes ±30% of an intended atomic ratio. Gallium is preferably used as the element M. In the case where a single layer of the oxide 820b is provided as the oxide 820, a metal oxide that can be used for the oxide 820a may be used for the oxide 820b. The compositions of the metal oxides that can be used for the oxide 820a and the oxide 820b are not limited to the above. For example, the composition of the metal oxide that can be used for the oxide 820a may be applied to the oxide 820b. Similarly, the composition of the metal oxide that can be used for the oxide 820b may be applied to the oxide 820a.

When the metal oxide is deposited by a sputtering method, the above atomic ratio is not limited to the atomic ratio of the deposited of the metal oxide and may be the atomic ratio of a sputtering target used for depositing the metal oxide.

The oxide 820b preferably has crystallinity. It is particularly preferable to use a CAAC-OS for the oxide 820b.

When an oxide having crystallinity, such as a CAAC-OS, is used for the oxide 820b, oxygen extraction from the oxide 820b by the source electrode or the drain electrode can be inhibited. This can reduce oxygen extraction from the oxide 820b even when heat treatment is performed; thus, the transistor 800 is stable with respect to high temperatures in the manufacturing process (what is called thermal budget).

Examples of materials that can be used for the conductors, the insulators, and the oxide semiconductor included in the transistor 800 include the above-described materials that can be used for the conductor ME1 to the conductor ME3. Typical examples are described below.

The conductor 842a has a stacked structure of the conductor 842al and the conductor 842a2 over the conductor 842al, and the conductor 842b has a stacked structure of the conductor 842b1 and the conductor 842b2 over the conductor 842bl. The conductor 842al and the conductor 842b1 in contact with the oxide 820b are preferably conductors that are not easily oxidized, such as metal nitride. Thus, the conductor 842a and the conductor 842b can be prevented from being oxidized excessively by oxygen contained in the oxide 820b. The conductor 842a2 and the conductor 842b2 are preferably conductors having higher conductivity than the conductor 842a1 and the conductor 842b1, such as a metal layer. Accordingly, the conductor 842a and the conductor 842b can each function as a wiring or an electrode with high conductivity.

For example, tantalum nitride or titanium nitride can be used for the conductor 842a1 and the conductor 842b1, and tungsten can be used for the conductor 842a2 and the conductor 842b2.

The opening formed in the insulator 885 and the insulator 875 overlap with a region between the conductor 842a2 and the conductor 842b2. In the plan view, the side surface of the opening in the insulator 885 is aligned or substantially aligned with the side surface of the conductor 842a2 and the side surface of the conductor 842b2. The conductor 842a1 and the conductor 842b1 are formed to partly extend toward the inside of the opening. A part of the top surface of the conductor 842a1 is in contact with the conductor 842a2, and a part of the top surface of the conductor 842b1 is in contact with the conductor 842b2. Thus, the insulator 855 is in contact with another part of the top surface of the conductor 842a1, another part of the top surface of the conductor 842b1, and the side surface of the conductor 842a2, and the side surface of the conductor 842b2 in the opening. The insulator 850 is in contact with the top surface of the oxide 820, the side surface of the conductor 842a1, the side surface of the conductor 842b1, and the side surface of the insulator 855.

The insulator 855 is preferably an insulator that is not easily oxidized, such as nitride. By anisotropic etching, the insulator 855 is formed in a sidewall shape to be in contact with the sidewall of the opening formed in the insulator 885 and the like (here, the sidewall of the opening corresponds to, for example, the side surface of the insulator 885 or the like). The insulator 855 is formed in contact with the side surface of the conductor 842a2 and the side surface of the conductor 842b2 and has a function of protecting the conductor 842a2 and the conductor 842b2. In order to supply oxygen to the oxide 820b, heat treatment in an atmosphere containing oxygen is preferably performed after the separation into the conductor 842a1 and the conductor 842b1 and before the formation of the insulator 850. At this time, since the insulator 855 is formed in contact with the side surface of the conductor 842a2 and the side surface of the conductor 842b2, excessive oxidation of the conductor 842a2 and the conductor 842b2 can be prevented. The insulator 855 can be formed using silicon nitride, for example.

An insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor 800. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and VoH in the channel formation region of the oxide semiconductor are preferably reduced. Supply of an excess amount of oxygen to the source region and the drain region and excessive reduction in the amount of VoH in the source region and the drain region are preferably inhibited. In addition, a structure in which conductivity of the conductor 860, the conductor 842a, the conductor 842b, and the like is less likely to be reduced is preferably employed. For example, oxidation of the conductor 860, the conductor 842a, the conductor 842b, and the like is preferably inhibited. Note that hydrogen in the oxide semiconductor can form VoH; thus, the hydrogen concentration needs to be reduced in order to reduce the amount of VoH.

The transistor 800 has a structure in which the hydrogen concentration in the channel formation region is reduced, oxidation of the conductor 842a, the conductor 842b, and the conductor 860 is inhibited, and a reduction in the hydrogen concentration in the source region and the drain region is inhibited.

The insulator 850 in contact with the channel formation region of the oxide 820b preferably has a function of capturing or fixing hydrogen. Thus, the hydrogen concentration in the channel formation region of the oxide 820b can be reduced. Accordingly, VoH in the channel formation region can be reduced, so that the channel formation region can be an i-type or substantially i-type region.

The insulator 850 functions as a gate insulator. The insulator 850 is provided in the opening formed in the insulator 885, together with the insulator 855 and the conductor 860. The thickness of the insulator 850 is preferably thin for miniaturization of the transistor 800. The thickness of each layer included in the insulator 850 is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm. Each of the layers included in the insulator 850 at least partly includes a region with the above-described thickness.

To form the insulator 850 having a small thickness, an ALD method is preferably used for deposition. Furthermore, in the case where the insulator 850 and the insulator 855 are provided in the opening in the insulator 885 and the like, an ALD method is preferably employed. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables film formation at a lower temperature.

The thickness of the insulator 855 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 855 has a thickness in the above range, excessive oxidation of the conductor 842a2 and the conductor 842b2 can be inhibited. In this case, at least part of the insulator 855 may have a region with the above-described thickness. When the thickness of the insulator 855 is set excessively large, the time for depositing the insulator 855 by an ALD method is long, which decreases the productivity; for this reason, the thickness of the insulator 855 is preferably in the above range.

A structure in which hydrogen is inhibited from entering the transistor 800 and the like is preferably employed for the semiconductor device illustrated in FIG. 34A and the like. For example, an insulator having a function of inhibiting diffusion of hydrogen is preferably provided to cover one or both of the upper portion and the lower portion of the transistor 800 and the like. Accordingly, each of the insulator 815, the insulator 821, the insulator 822, the insulator 882, and the insulator 883 preferably includes an insulator having a function of inhibiting diffusion of oxygen and impurities such as water and hydrogen. Examples of the insulator include aluminum oxide, magnesium oxide, hafnium oxide, zirconium oxide, an oxide containing aluminum and hafnium (hafnium aluminate), an oxide containing hafnium and zirconium (hafnium zirconium oxide), gallium oxide, silicon nitride, and silicon nitride oxide. For example, silicon nitride, which has a higher hydrogen barrier property, is preferably used for the insulator 883 and the insulator 821. For example, the insulator 882 preferably includes aluminum oxide or the like, which has a function of capturing or fixing hydrogen well. For example, hafnium oxide, which has high capability of capturing or fixing hydrogen and is a high permittivity (high-k) material, is preferably used for the insulator 822. With such a structure where the transistor 800 is surrounded by upper and lower insulators having a function of inhibiting diffusion of oxygen and impurities such as water and hydrogen, excess oxygen and hydrogen can be inhibited from diffusing into the oxide semiconductor. Thus, the semiconductor device can have improved electrical characteristics and reliability.

Here, it is preferable that a region of the insulator 875 not overlapping with the oxide 820 be in contact with the insulator 822, a side end portion of the insulator 875 be in contact with the insulator 855, and an upper end portion of the insulator 855 and upper end portion of the insulator 850 be in contact with the insulator 882. With the above structure, in a region sandwiched between the insulator 883 and the insulator 821, the insulator 885 is isolated from the oxide 820 by the insulator 875, and the insulator 885 is separated from the insulator 850 by the insulator 855. Accordingly, diffusion of impurities contained in the insulator 885, such as water and hydrogen, into the oxide 820 and the insulator 850 can be inhibited. Furthermore, hydrogen contained in the insulator 850 can be captured and fixed in the insulator 882. With such a structure, diffusion of hydrogen into the oxide semiconductor can be further reduced. Thus, the semiconductor device can have improved electrical characteristics and reliability.

In the transistor 800, the conductor 805 is placed to overlap with the oxide 820 and the conductor 860. Here, the conductor 805 is preferably provided to be embedded in an opening portion formed in the insulator 816. Moreover, the conductor 805 is preferably provided to extend in the channel width direction as illustrated in FIG. 34A and FIG. 34C. With such a structure, the conductor 805 functions as a wiring when a plurality of transistors are provided.

As illustrated in FIG. 34B and FIG. 34C, the conductor 805 preferably includes the conductor 805a and the conductor 805b. The conductor 805a is provided in contact with the bottom surface and the sidewall of the opening portion. The conductor 805b is provided to fill a depressed portion that is defined by the conductor 805a and formed along the opening portion. Here, the top surface of the conductor 805 is level or substantially level with the top surface of the insulator 816.

When the conductor 805a is formed using a conductive material having a function of inhibiting diffusion of hydrogen, impurities such as hydrogen contained in the conductor 805b can be prevented from diffusing into the oxide 820 through the insulator 816 and the like. When a conductive material having a function of inhibiting diffusion of oxygen is used for the conductor 805a, the conductivity of the conductor 805b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 805a can have a single-layer structure or a stacked-layer structure of the above conductive material. For example, the conductor 805a preferably contains titanium nitride.

The conductor 805b is preferably formed using a conductive material containing tungsten, copper, or aluminum as its main component. For example, the conductor 805b preferably contains tungsten.

The conductor 805 can function as the second gate electrode. In that case, by changing a potential applied to the conductor 805 not in conjunction with but independently of a potential applied to the conductor 860, the threshold voltage (Vth) of the transistor 800 can be controlled. In particular, by applying a negative potential to the conductor 805, Vth of the transistor 800 can be higher, and its off-state current can be reduced. Thus, a drain current at the time when a potential applied to the conductor 860 is 0 V can be lower in the case where a negative potential is applied to the conductor 805 than in the case where the negative potential is not applied to the conductor 805.

The electrical resistivity of the conductor 805 is designed in consideration of the potential applied to the conductor 805, and the thickness of the conductor 805 is set in accordance with the electrical resistivity. The thickness of the insulator 816 is substantially equal to that of the conductor 805. Here, the conductor 805 and the insulator 816 are preferably as thin as possible in the allowable range of the design of the conductor 805. When the thickness of the insulator 816 is reduced, the absolute amount of impurities such as hydrogen contained in the insulator 816 can be reduced, inhibiting diffusion of the impurities into the oxide 820.

The insulator 824 that is in contact with the oxide 820 preferably includes silicon oxide or silicon oxynitride, for example. Accordingly, oxygen can be supplied from the insulator 824 to the oxide 820, so that oxygen vacancies can be reduced.

The insulator 884 is preferably processed into an island shape in the same manner as the oxide 820. Thus, in the case where a plurality of the transistors 800 are provided, the transistors 800 include the insulators 824 having substantially the same size. Accordingly, substantially the same amount of oxygen is supplied from the insulator 884 to the oxide 820 in the transistors 800. This can reduce variations in electrical characteristics of the transistors 800 in the substrate plane. Note that the structure is not limited to this, and it is possible not to pattern the insulator 824 as in the case of the insulator 822.

A conductive material that is less likely to be oxidized or a conductive material having a function of inhibiting diffusion of oxygen is preferably used for each of the conductor 842a, the conductor 842b, and the conductor 860. Examples of the conductive material include a conductive material containing nitrogen and a conductive material containing oxygen. Thus, a decrease in the conductivity of the conductor 842a, the conductor 842b, and the conductor 860 can be inhibited.

The insulator 871a and the insulator 871b are inorganic insulators functioning as etching stoppers in the processing into the conductor 842a2 and the conductor 842b2 to protect the conductor 842a2 and the conductor 842b2. The insulator 871a and the insulator 871b are respectively in contact with the conductor 842a and the conductor 842b and thus are preferably inorganic insulators that are less likely to oxidize the conductors 842a and 842b. The insulator 871a and the insulator 871b preferably have a stacked-layer structure of a nitride insulator and an oxide insulator, for example.

In this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. In this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect does not easily occur can be provided.

When the transistor 800 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 800 has the S-channel structure, the GAA structure, or the LGAA structure, the channel formation region that is formed at the interface between the oxide 820 and the gate insulator or in the vicinity of the interface can be formed in the entire bulk of the oxide 820. Accordingly, the density of current flowing through the transistor can be increased, which can be expected to increase the on-state current of the transistor or increase the field-effect mobility of the transistor.

In this embodiment, the insulator 824 with an island shape is provided. Accordingly, as illustrated in FIG. 34C, at least part of the bottom surface of the conductor 860 can be positioned lower than the bottom surface of the oxide 820b. Thus, the conductor 860 can be provided to face the top surface and the side surface of the oxide 820b, so that an electric field of the conductor 860 can be applied to the top surface and the side surface of the oxide 820b. When the insulator 824 with an island shape is provided in this manner, the transistor 800 can have an S-channel structure.

The conductor 860 preferably includes the conductor 860a and the conductor 860b placed over the conductor 860a. For example, the conductor 860a is preferably placed to cover the bottom surface and the side surface of the conductor 860b. In this case, a conductive material that is less likely to be oxidized or a conductive material having a function of inhibiting diffusion of oxygen is preferably used for the conductor 860a. When the conductor 860a has a function of inhibiting diffusion of oxygen, the conductivity of the conductor 860b can be inhibited from being lowered because of oxidation due to oxygen contained in the insulator 885 or the like. As the conductive material having a function of inhibiting diffusion of oxygen, for example, titanium, titanium nitride, tantalum, tantalum nitride, ruthenium, or ruthenium oxide is preferably used.

As the conductor 860b, a conductor having high conductivity is preferably used. For example, a conductive material containing tungsten, copper, or aluminum as its main component can be used as the conductor 860b. The conductor 860b may have a stacked-layer structure; for example, a stacked-layer structure of the conductive material and titanium or titanium nitride may be employed.

The insulator 816 and the insulator 885 each preferably have a lower permittivity than the insulator 822. When a material with a low permittivity is used for an interlayer film, parasitic capacitance generated between wirings can be reduced.

### Example of Manufacturing Method of Flexible Device

An example of a manufacturing method of a flexible device will be described below.

After an element layer is formed over a support substrate, the support substrate and the element layer are separated from each other so that the element layer can be transferred to a substrate having flexibility.

Here, layers including components of the device are collectively referred to as an element layer. In the case of manufacturing a flexible semiconductor device, for example, the element layer includes an element such as a transistor. Furthermore, in the case of manufacturing a flexible semiconductor device, for example, the element layer includes at least one of a display element, a wiring electrically connected to the display element, elements such as transistors used in a pixel and a circuit, optical members such as a coloring layer and a light-blocking layer, and the like.

Furthermore, here, each of two flexible members between which an element layer is sandwiched is referred to as a substrate (or a substrate having flexibility). A substrate includes an extremely thin film or the like with a thickness greater than or equal to 10 nm and less than or equal to 300 μm, for example.

A method can be employed in which, for example, a peeling layer and an insulating layer are stacked over a support substrate first, an element layer is formed over the insulating layer, separation is performed between the support substrate and the element layer, and the element layer is transferred to a substrate. In that case, a material is selected such that separation occurs at the interface between the support substrate and the peeling layer, at the interface between the peeling layer and the insulating layer, or in the peeling layer. In this method, a material having high heat resistance is preferably used for the support substrate and the peeling layer because the upper limit of the temperature applied when the element layer is formed can be increased, so that an element layer including a highly reliable element can be formed.

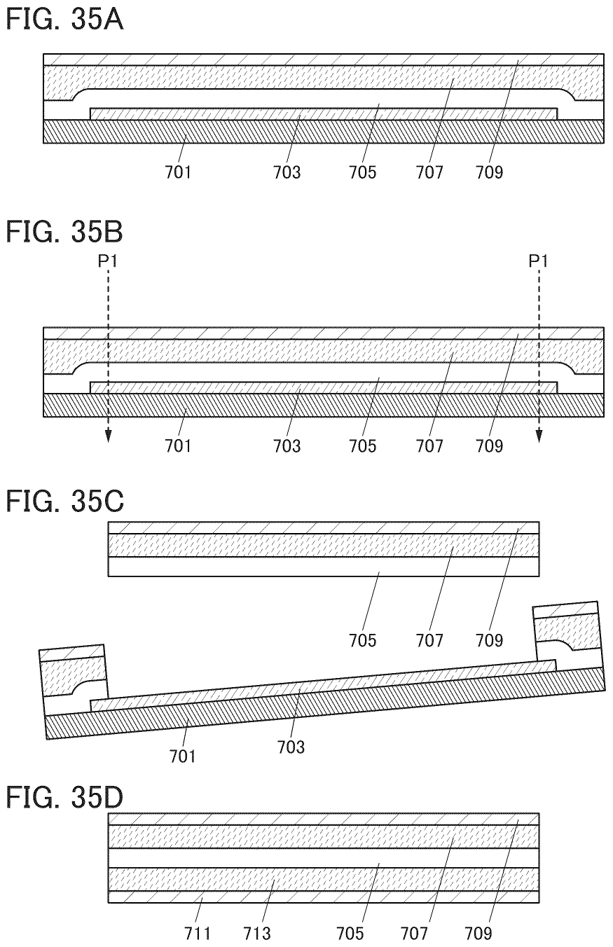

A specific example of the manufacturing method will be described below with reference to FIG. 35.

First, an island-shaped peeling layer 703 is formed over a support substrate 701, and a layer 705 to be peeled is formed over the peeling layer 703. After that, the support substrate 701 and a substrate 709 having flexibility are attached to each other with an adhesive layer 707, and the adhesive layer 707 is cured (FIG. 35A).

As the support substrate 701, a substrate having heat resistance high enough to withstand at least the processing temperature in a manufacturing process is used. Examples of the support substrate 701 include a glass substrate, a quartz substrate, a sapphire substrate, a semiconductor substrate, a ceramic substrate, a metal substrate, a resin substrate, and a plastic substrate.

As the semiconductor substrate, a disc-like substrate (wafer) is suitable and can be, for example, a silicon (Si) substrate (also referred to as a silicon wafer), a silicon carbide (SiC) substrate, or a gallium nitride (GaN) substrate.

An insulating film such as a silicon oxide film, a silicon oxynitride film, a silicon nitride film, or a silicon nitride oxide film is preferably formed as a base film between the support substrate 701 and the peeling layer 703, in which case contamination from the support substrate 701 can be prevented.

The peeling layer 703 can be formed to have a single-layer structure or a stacked-layer structure using, for example, one or more of an element selected from tungsten, molybdenum, titanium, tantalum, niobium, nickel, cobalt, zirconium, zinc, ruthenium, rhodium, palladium, osmium, iridium, and silicon; an alloy material containing the element; a compound material containing the element; and the like. A crystal structure of a layer containing silicon may be any of amorphous, microcrystal, and polycrystal. Furthermore, a metal oxide such as aluminum oxide, gallium oxide, zinc oxide, titanium dioxide, indium oxide, an indium tin oxide, an indium zinc oxide, or an In—Ga—Zn oxide may be used.

The peeling layer 703 can be formed by, for example, a sputtering method, a plasma CVD method, a coating method (including a spin coating method, a droplet discharging method, a dispensing method, and the like), or a printing method.

The thickness of the peeling layer 703 is preferably greater than or equal to 10 nm and less than or equal to 200 nm, further preferably greater than or equal to 20 nm and less than or equal to 100 nm.

The peeling layer 703 is preferably formed using a high-melting-point metal material such as tungsten, titanium, or molybdenum, in which case the degree of freedom of the process for forming the layer 705 to be peeled can be increased. As the peeling layer 703, for example, a tungsten layer, a molybdenum layer, a layer including a mixture of tungsten and molybdenum, a layer including an oxide or an oxynitride of tungsten, a layer including an oxide or an oxynitride of molybdenum, or a layer including an oxide or an oxynitride of a mixture of tungsten and molybdenum may be formed. The mixture of tungsten and molybdenum corresponds to an alloy of tungsten and molybdenum, for example.

As the peeling layer 703, a stacked-layer structure of a metal film and a metal oxide film may be used. Specific examples include a stacked-layer structure of tungsten and tungsten oxide, a stacked-layer structure of molybdenum and molybdenum oxide, and a stacked-layer structure of titanium and titanium oxide. Such a stacked-layer structure of a metal film and a metal oxide film may be formed by utilizing the fact that, when a layer including the metal is formed and an insulating film formed of an oxide is formed thereover, a layer including an oxide of the metal is formed at the interface between the metal layer and the insulating film. Alternatively, the layer including an oxide of the metal may be formed by performing thermal oxidation treatment, oxygen plasma treatment, nitrous oxide (N₂O) plasma treatment, treatment with a highly oxidizing solution such as ozone water, or the like on a surface of the layer including the metal. Plasma treatment or heat treatment may be performed in an atmosphere of oxygen, nitrogen, or nitrous oxide alone, or a mixed gas atmosphere of the gas and another gas. Surface condition of the peeling layer 703 is changed by the plasma treatment or the heat treatment, whereby adhesion between the peeling layer 703 and an insulating film formed later can be controlled.

An organic resin may be used for the peeling layer 703. Examples of the organic resin include a polyimide resin, an acrylic resin, an epoxy resin, a polyamide resin, a polyimide-amide resin, a siloxane resin, a benzocyclobutene-based resin, and a phenol resin.

The peeling layer 703 is not necessarily provided in the case where peeling at the interface between the support substrate 701 and the layer 705 to be peeled is possible.

Although an example in which the island-shaped peeling layer 703 is formed is described here, one embodiment of the present invention is not limited thereto. In this step, a material is selected such that separation occurs at the interface between the support substrate 701 and the peeling layer 703, at the interface between the peeling layer 703 and the layer 705 to be peeled, or in the peeling layer 703 when the support substrate 701 and the layer 705 to be peeled are separated from each other. Although an example in which separation occurs at the interface between the layer 705 to be peeled and the peeling layer 703 is described in this embodiment, one embodiment of the present invention is not limited thereto depending on the combination of materials used for the peeling layer 703 and the layer 705 to be peeled. In the case where the layer 705 to be peeled has a stacked-layer structure, a layer in contact with the peeling layer 703 is particularly referred to as a first layer.

There is no particular limitation on a layer formed as the layer 705 to be peeled. An insulating layer (first layer) formed to be in contact with the peeling layer 703 is preferably formed as a single layer or a multilayer using at least one of a silicon nitride film, a silicon oxynitride film, a silicon oxide film, a silicon nitride oxide film, and the like. Without limitation thereto, an optimum material can be selected depending on a material used for the peeling layer 703.

The insulating layer can be formed by a sputtering method, a plasma CVD method, a coating method, a printing method, or the like; when the insulating layer is formed by a plasma CVD method at a deposition temperature higher than or equal to 250° C. and lower than or equal to 400° C. for example, a dense film with extremely high moisture resistance can be obtained. The thickness of the insulating layer is preferably greater than or equal to 10 nm and less than or equal to 3000 nm, further preferably greater than or equal to 200 nm and less than or equal to 1500 nm.

At least one of component of a device, such as a transistor or a display element, is formed over the first layer, whereby the layer 705 to be peeled can be formed.

The support substrate 701 and the substrate 709 are preferably attached to each other in a reduced-pressure atmosphere.

The adhesive layer 707 is placed to overlap with at least the peeling layer 703 and the layer 705 to be peeled. An end portion of the adhesive layer 707 may be positioned inward from that of the peeling layer 703. In that case, strong adhesion between the support substrate 701 and the substrate 709 can be inhibited; thus, a decrease in the yield of a subsequent peeling process can be inhibited.

For the adhesive layer 707, a variety of curable adhesives such as a photocurable adhesive like an ultraviolet curable adhesive, a reactive curable adhesive, a thermosetting adhesive, and an anaerobic adhesive can be used, for example. Examples of these adhesives include an epoxy resin, an acrylic resin, a silicone resin, a phenol resin, a polyimide resin, an imide resin, a PVC resin, a PVB resin, and an EVA resin. A material with low moisture permeability, such as an epoxy resin, is particularly preferable. For the adhesive, a material having fluidity low enough to dispose the material only in a desired region is preferably used. For example, an adhesive sheet, a bonding sheet, or a sheet-like or film-like adhesive can be used. An OCA (optical clear adhesive) film can be suitably used, for example.

The adhesive may have adhesion before attachment or exhibit adhesion after attachment by heating, light irradiation, or the like.

The resin may include a drying agent. For example, a substance that adsorbs moisture by chemical adsorption, such as an oxide of an alkaline earth metal (e.g., calcium oxide or barium oxide), can be used. Alternatively, a substance that adsorbs moisture by physical adsorption, such as zeolite or silica gel, may be used. The drying agent is preferably included because it can inhibit deterioration of a functional element due to entry of moisture in the air and can improve the reliability of the device.

For the substrate 709 having flexibility, for example, a polyester resin such as polyethylene terephthalate (PET) or polyethylene naphthalate (PEN), a poly acrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used. For the substrate 709, a variety of materials such as glass, quartz, a resin, a metal, an alloy, and a semiconductor (e.g., silicon) that are thin enough to be flexible may be used.

Next, a separation starting point is formed (FIG. 35B).

There is no particular limitation on a method for forming the separation starting point, and irradiation with laser light, application of mechanical force, etching of the peeling layer 703, and permeation of a liquid into the separation interface are given as examples. Alternatively, separation may be performed by heating or cooling the support substrate 701 by utilizing a difference in thermal expansion coefficient of the two layers that form the separation interface.

Alternatively, the peeling starting point may be formed first so that peeling proceeds from the starting point. The peeling starting point can be formed by a method such as local heating of part of the first layer or the peeling layer 703 with laser light or the like, or physical cutting or penetration of part of the first layer or the peeling layer 703 with a sharp item.

Although FIG. 35B illustrates an example in which the separation starting point is formed from the substrate 709 side, the separation starting point may be formed from the support substrate 701 side.

A region where the adhesive layer 707 in a cured state, the layer 705 to be peeled, and the peeling layer 703 overlap with one another is irradiated with laser light, for example (see an arrow P1 in FIG. 35B). At least part of the first layer is removed, whereby the peeling starting point can be formed. In that case, not only the first layer but also another layer in the layer 705 to be peeled, the peeling layer 703, and the adhesive layer 707 may be partly removed.

Then, the layer 705 to be peeled and the support substrate 701 are separated from each other from the formed separation starting point (FIG. 35C). Consequently, the layer 705 to be peeled can be transferred from the support substrate 701 to the substrate 709 having flexibility.

For example, the layer 705 to be peeled and the support substrate 701 can be separated from each other from the separation starting point by physical force (e.g., a peeling process with a human hand or a tool, or a separation process by rotation of a roller).

The support substrate 701 and the layer 705 to be peeled may be separated from each other by a liquid such as water permeating the interface between the peeling layer 703 and the layer 705 to be peeled. When the liquid permeates between the peeling layer 703 and the layer 705 to be peeled through capillarity, separation can be easily performed. Furthermore, an adverse effect of static electricity caused at the time of peeling on a functional element included in the layer 705 to be peeled (e.g., breakage of a semiconductor element by static electricity) can be inhibited.

In the case where the peeling layer 703 has a stacked-layer structure of a metal film and a metal oxide film and separation occurs at the interface between the metal film and the metal oxide film (or in the vicinity of the interface) or in the metal oxide film, for example, part of the peeling layer 703 (here, the metal oxide film) may remain on the layer 705 to be peeled side. The peeling layer remaining on the layer 705 to be peeled side may be removed afterwards.

In the case where a plurality of devices are formed over the support substrate 701 and the support substrate 701 is divided into the devices so that the plurality of devices are each taken as a chip, a step of cutting the support substrate 701 with a dicing line (also referred to as a scribe line, a dividing line, or a cutting line) may also serve as one or both of the step of forming the separation starting point and the separation step.

Next, the exposed layer 705 to be peeled is attached to a substrate 711 with an adhesive layer 713, and the adhesive layer 713 is cured (FIG. 35D).

For the substrate 711, a material similar to the material that can be used for the substrate 709 can be used.

For the adhesive layer 713, a material similar to the material that can be used for the adhesive layer 707 can be used.

The layer 705 to be peeled and the substrate 711 are preferably attached to each other in a reduced-pressure atmosphere.

In this manner, the layer 705 to be peeled can be sandwiched between a pair of substrates having flexibility (the substrate 711 and the substrate 709).

By the above method, a flexible device can be manufactured. When the layer 705 to be peeled has the structure described above as an example, semiconductor device having flexibility can be manufactured, for example.

Although not described in detail here, as a method for manufacturing a flexible device, a method can be given in which an element layer is formed over a substrate having no flexibility and the substrate is thinned by polishing or the like to have flexibility.

At least part of this embodiment can be implemented in appropriate combination with the other embodiments described in this specification.

### Embodiment 5

In this embodiment, a light-emitting device that can be used in the semiconductor device of one embodiment of the present invention will be described.

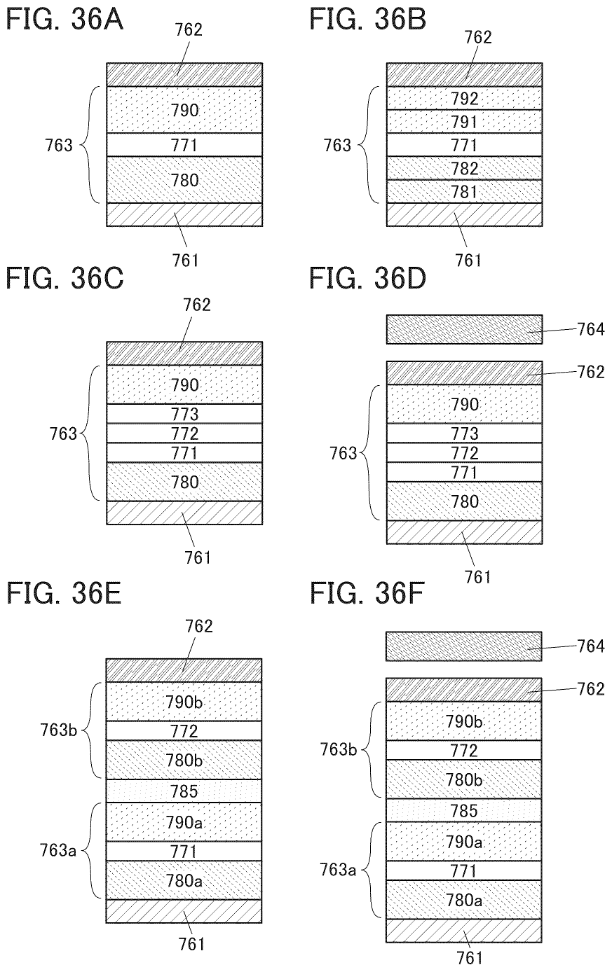

As illustrated in FIG. 36A, the light-emitting device includes an EL layer 763 between a pair of electrodes (a lower electrode 761 and an upper electrode 762). The EL layer 763 can be formed with a plurality of layers such as a layer 780, a light-emitting layer 771, and a layer 790.

The light-emitting layer 771 includes at least a light-emitting substance (also referred to as a light-emitting material).

In the case where the lower electrode 761 is an anode and the upper electrode 762 is a cathode, the layer 780 includes one or more of a layer including a substance having a high hole-injection property (hole-injection layer), a layer including a substance having a high hole-transport property (hole-transport layer), and a layer including a substance having a high electron-blocking property (electron-blocking layer). Furthermore, the layer 790 includes one or more of a layer including a substance having a high electron-injection property (electron-injection layer), a layer including a substance having a high electron-transport property (electron-transport layer), and a layer including a substance having a high hole-blocking property (hole-blocking layer). In the case where the lower electrode 761 is a cathode and the upper electrode 762 is an anode, the structures of the layer 780 and the layer 790 are interchanged.

The structure with the layer 780, the light-emitting layer 771, and the layer 790, which is provided between the pair of electrodes, can function as a single light-emitting unit, and the structure in FIG. 36A is referred to as a single structure in this specification.

FIG. 36B is a variation example of the EL layer 763 included in the light-emitting device illustrated in FIG. 36A. Specifically, the light-emitting device illustrated in FIG. 36B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Structures in which a plurality of light-emitting layers (light-emitting layers 771, 772, and 773) are provided between the layer 780 and the layer 790 as illustrated in FIG. 36C and FIG. 36D are other variations of a single structure. Although FIG. 36C and FIG. 36D each illustrate an example in which three light-emitting layers are included, the number of light-emitting layers in a light-emitting device having a single structure may be two or four or more. A light-emitting device having a single structure may include a buffer layer between two light-emitting layers. The buffer layer can be formed using a material that can be used for the hole-transport layer or the electron-transport layer, for example.

A structure in which a plurality of light-emitting units (a light-emitting unit 763a and a light-emitting unit 763b) are connected in series with a charge-generation layer 785 (also referred to as an intermediate layer) therebetween as illustrated in FIG. 36E and FIG. 36F is referred to as a tandem structure in this specification. A tandem structure may be referred to as a stack structure. A tandem structure enables a light-emitting device capable of high-luminance light emission. Furthermore, the amount of current needed for obtaining a predetermined luminance can be smaller in a tandem structure than in a single structure; thus, a tandem structure enables higher reliability.

FIG. 36D and FIG. 36F each illustrate an example in which the semiconductor device includes a layer 764 overlapping with the light-emitting device. FIG. 36D illustrates an example in which the layer 764 overlaps with the light-emitting device illustrated in FIG. 36C, and FIG. 36F illustrates an example in which the layer 764 overlaps with the light-emitting device illustrated in FIG. 36E. In FIG. 36D and FIG. 36F, a conductive film that transmits visible light is used for the upper electrode 762 so that light is extracted to the upper electrode 762 side.

One or both of a color conversion layer and a color filter (coloring layer) can be used as the layer 764.

In FIG. 36C and FIG. 36D, light-emitting substances that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 36D for converting blue light emitted from the light-emitting device into light with a longer wavelength, so that red or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of a desired color can be absorbed by the coloring layer, and color purity of light exhibited by a subpixel can be improved.

In FIG. 36C and FIG. 36D, light-emitting substances that emit light of different colors may be used for the light-emitting layer 771, the light-emitting layer 772, and the light-emitting layer 773. When the light-emitting layer 771, the light-emitting layer 772, and the light-emitting layer 773 emit light of complementary colors, white light emission can be obtained. The light-emitting device having a single structure preferably includes a light-emitting layer including a light-emitting substance emitting blue light and a light-emitting layer including a light-emitting substance emitting visible light with a longer wavelength than blue light, for example.

A color filter is preferably provided as the layer 764 illustrated in FIG. 36D. When white light passes through a color filter, light of a desired color can be obtained.

In the case where the light-emitting device having a single structure includes three light-emitting layers, for example, a light-emitting layer including a light-emitting substance emitting red (R) light, a light-emitting layer including a light-emitting substance emitting green (G) light, and a light-emitting layer including a light-emitting substance emitting blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer including a light-emitting substance emitting blue (B) light and a light-emitting layer including a light-emitting substance emitting yellow (Y) light are preferably included. This structure may be referred to as a BY single structure.

In the light-emitting device that emits white light, two or more kinds of light-emitting substances are preferably included. To obtain white light emission by using two light-emitting layers, light-emitting substances are selected such that emission colors of the two light-emitting layers are complementary colors. For example, when emission colors of a first light-emitting layer and a second light-emitting layer are complementary colors, the light-emitting device can emit white light as a whole. To obtain white light emission by using three or more light-emitting layers, the light-emitting device is configured to emit white light as a whole by combining emission colors of the three or more light-emitting layers.

In FIG. 36C and FIG. 36D, the layer 780 and the layer 790 may each have a stacked-layer structure of two or more layers as illustrated in FIG. 36B.

In FIG. 36E and FIG. 36F, light-emitting substances that emit light of the same color, or the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In each of the subpixel that emits red light and the subpixel that emits green light, a color conversion layer is provided as the layer 764 illustrated in FIG. 36F for converting blue light emitted from the light-emitting device into light with a longer wavelength, so that red or green light can be extracted. As the layer 764, both a color conversion layer and a coloring layer are preferably used.

In FIG. 36E and FIG. 36F, light-emitting substances that emit light of different colors may be used for the light-emitting layer 771 and the light-emitting layer 772. When the light-emitting layer 771 and the light-emitting layer 772 emit light of complementary colors, white light emission can be obtained. A color filter is preferably provided as the layer 764 illustrated in FIG. 36F. When white light passes through a color filter, light of a desired color can be obtained.

Although FIG. 36E and FIG. 36F each illustrate an example in which the light-emitting unit 763a includes one light-emitting layer 771 and the light-emitting unit 763b includes one light-emitting layer 772, one embodiment of the present invention is not limited to the example. Each of the light-emitting unit 763a and the light-emitting unit 763b may include two or more light-emitting layers.

Although FIG. 36E and FIG. 36F each illustrate an example of a light-emitting device including two light-emitting units, one embodiment of the present invention is not limited to the example. The light-emitting device may include three or more light-emitting units. Note that a structure including two light-emitting units and a structure including three light-emitting units may be referred to as a two-unit tandem structure and a three-unit tandem structure, respectively.

In each of FIG. 36E and FIG. 36F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. Furthermore, the layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

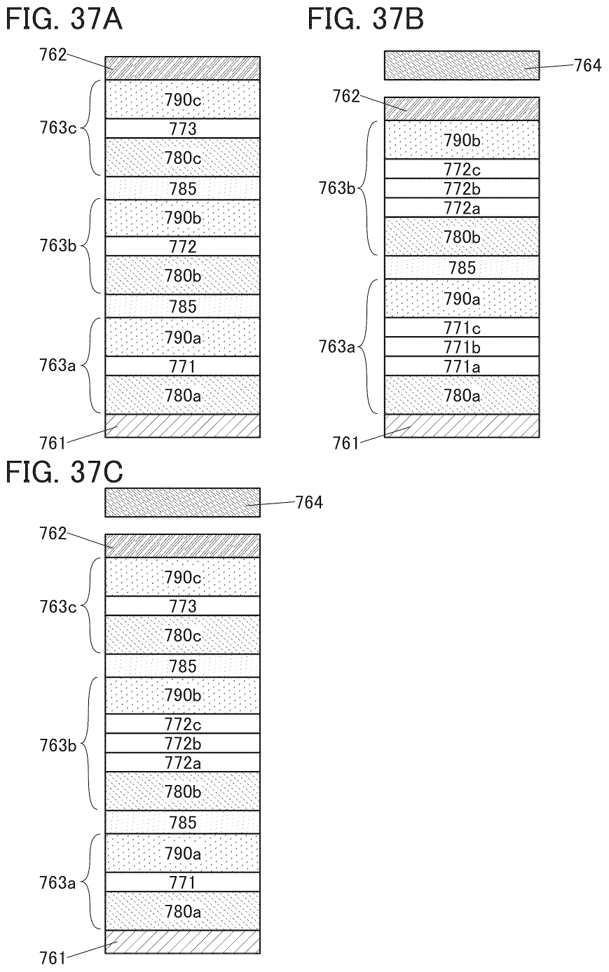

As examples of the light-emitting device with a tandem structure, structures illustrated in FIG. 37A to FIG. 37C can be given.

FIG. 37A illustrates a structure including three light-emitting units. In FIG. 37A, a plurality of light-emitting units (the light-emitting unit 763a, the light-emitting unit 763b, and a light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. The layer 780c can have a structure applicable to the layer 780a and the layer 780b, and the layer 790c can have a structure applicable to the layer 790a and the layer 790b.

In FIG. 37A, the light-emitting layer 771, the light-emitting layer 772, and the light-emitting layer 773 can include light-emitting substances that emit light of the same color. Specifically, a structure where the light-emitting layer 771, the light-emitting layer 772, and the light-emitting layer 773 each include a blue (B) light-emitting substance (what is called a three-unit tandem structure of B\B\B) can be employed. Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 37A, light-emitting substances that emit light of different colors can be used for some or all of the light-emitting layer 771, the light-emitting layer 772, and the light-emitting layer 773. Examples of the combination of emission colors for the light-emitting layer 771, the light-emitting layer 772, and the light-emitting layer 773 include a combination of blue (B) for two of them and yellow (Y) for the other; and a combination of red (R) for one of them, green (G) for another, and blue (B) for the other.

FIG. 37B illustrates a tandem light-emitting device in which light-emitting units each including a plurality of light-emitting layers are stacked. FIG. 37B illustrates a structure in which two light-emitting units (light-emitting unit 763a and light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 37B, the light-emitting unit 763a is configured to emit white (W) light by selecting light-emitting substances for the light-emitting layer 771a, the light-emitting layer 771b, and the light-emitting layer 771c such that their emission colors are complementary colors. Furthermore, the light-emitting unit 763b is configured to emit white (W) light by selecting light-emitting substances for the light-emitting layer 772a, the light-emitting layer 772b, and the light-emitting layer 772c such that their emission colors are complementary colors. In other words, the structure illustrated in FIG. 37B is a two-unit tandem structure of W\W. There is no particular limitation on the stacking order of light-emitting substances that emit light of complementary colors, and a practitioner can select an optimum stacking order as appropriate. Although not illustrated, a three-unit tandem structure of W\W\W or a tandem structure with four or more units may be employed.

Other examples of the structure of a light-emitting device having a tandem structure include a B\Y or Y\B two-unit tandem structure including a light-emitting unit that emits yellow (Y) light and a light-emitting unit that emits blue (B) light; an R⋅G\B or B\R⋅G two-unit tandem structure including a light-emitting unit that emits red (R) and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\Y\G\B three-unit tandem structure including a light-emitting unit that emits blue (B) light, a light-emitting unit that emits yellowish green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a⋅b” means that one light-emitting unit contains a light-emitting substance that emits light of a and a light-emitting substance that emits light of b.

Alternatively, a light-emitting unit including one light-emitting layer and a light-emitting unit including a plurality of light-emitting layers may be used in combination as illustrated in FIG. 37C.

Specifically, in the structure illustrated in FIG. 37C a plurality of light-emitting units (light-emitting unit 763a, light-emitting unit 763b, and light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 37C can be, for example, a three-unit tandem structure of B\R⋅G⋅YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the semiconductor device includes a light-emitting device emitting infrared light, a conductive film transmitting visible light and infrared light is preferably used for the electrode through which light is extracted, and a conductive film reflecting visible light and infrared light is preferably used for the electrode through which light is not extracted.

A conductive film transmitting visible light may be used also for the electrode through which light is not extracted. In that case, the electrode is preferably placed between a reflective layer and the EL layer 763. In other words, light emitted from the EL layer 763 may be reflected by the reflective layer to be extracted from the semiconductor device.

Examples of a material for the pair of electrodes of the light-emitting device include a metal, an alloy, an electrically conductive compound, and a mixture thereof. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing an appropriate combination of any of these metals. Other examples of the material include an indium tin oxide (In—Sn oxide, also referred to as ITO), an In—Si—Sn oxide (also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a micro optical resonator (microcavity) structure. Therefore, one of the pair of electrodes of the light-emitting device preferably includes an electrode having properties of transmitting and reflecting visible light (transflective electrode), and the other preferably includes an electrode having a property of reflecting visible light (reflective electrode). When the light-emitting device has a microcavity structure, light obtained from the light-emitting layer can be resonated between the electrodes, whereby light emitted from the light-emitting device can be intensified. When the light-emitting device has a microcavity structure, the color purity can be increased.

That is, as the electrode through which light is extracted in the light-emitting device, an electrode having a visible-light-transmitting property (a transparent electrode) or a semi-transmissive and semi-reflective electrode can be used.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer including any of a substance having a high hole-injection property, a substance having a high hole-transport property, a hole-blocking material, a substance having a high electron-transport property, an electron-blocking material, a substance having a high electron-injection property, a substance having a bipolar property (also referred to as a substance with a high electron-transport property and a high hole-transport property or a bipolar material), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a substance that exhibits thermally activated delayed fluorescence (a thermally activated delayed fluorescent (TADF) material), and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, any of after-mentioned substances with a high hole-transport property that can be used for the hole-transport layer can be used. As the electron-transport material, it is possible to use any of after-mentioned substances with a high electron-transport property that can be used for the electron-transport layer. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of the light-emitting device can be achieved at the same time.

The hole-injection layer injects holes from the anode to the hole-transport layer and includes a substance having a high hole-injection property. Examples of the substance having a high hole-injection property include an aromatic amine compound and a composite material including a hole-transport material and an acceptor material (electron-accepting material).

As the hole-transport material, any of after-mentioned substances with a high hole-transport property that can be used for the hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferable because it is stable in the air, has a low hygroscopic property, and is easy to handle. Alternatively, an organic acceptor material containing fluorine can be used. An organic acceptor material such as a quinodimethane derivative, a chloranil derivative, or a hexaazatriphenylene derivative can be used.

As the substance having a high hole-injection property, a material containing a hole-transport material and the above-described oxide of a metal belonging to Group 4 to Group 8 of the periodic table (typically, molybdenum oxide) may be used, for example.

The hole-transport layer transports holes injected from the anode by the hole-injection layer, to the light-emitting layer. The hole-transport layer includes a hole-transport material. The hole-transport material is preferably a substance having a hole mobility higher than or equal to 1×10⁻⁶ cm²/Vs. Note that other substances can also be used as long as the substances have a hole-transport property higher than an electron-transport property. As the hole-transport material, substances having a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer is a layer having a hole-transport property and including a material that can block an electron. Among the above-described hole-transport materials, a material having an electron-blocking property can be used for the electron-blocking layer.

Since the electron-blocking layer has a hole-transport property, the electron-blocking layer can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer includes an electron-transport material. The electron-transport material is preferably a substance having an electron mobility higher than or equal to 1×10⁻⁶ cm²/Vs. Other substances can also be used as long as the substances have an electron-transport property higher than a hole-transport property. As the electron-transport material, any of the following substances having ahigh electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer is a layer having an electron-transport property and including a material that can block a hole. Among the above-described electron-transport materials, a material having a hole-blocking property can be used for the hole-blocking layer.

Since the hole-blocking layer has an electron-transport property, the hole-blocking layer can also be referred to as an electron-transport layer. Among electron-transport layers, a layer having a hole-blocking property can also be referred to as a hole-blocking layer.

The electron-injection layer injects electrons from the cathode to the electron-transport layer and includes a substance having a high electron-injection property. As the substance having a high electron-injection property, an alkali metal, an alkaline earth metal, or a compound thereof can be used. As the substance having a high electron-injection property, a composite material including an electron-transport material and a donor material (electron-donating material) can also be used.

The LUMO level of the substance having a high electron-injection property preferably has a small difference (specifically, less than or equal to 0.5 eV) from the work function of a material used for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may include an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

The lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably includes an acceptor material. For example, the charge-generation region preferably includes the above-described hole-transport material and acceptor material that can be used for the hole-injection layer.

The charge-generation layer preferably includes a layer including a substance having a high electron-injection property. The layer can also be referred to as an electron-injection buffer layer. The electron-injection buffer layer is preferably provided between the charge-generation region and the electron-transport layer. Providing the electron-injection buffer layer can reduce an injection barrier between the charge-generation region and the electron-transport layer; thus, electrons generated in the charge-generation region can be easily injected into the electron-transport layer.

The electron-injection buffer layer preferably includes an alkali metal or an alkaline earth metal, and can include an alkali metal compound or an alkaline earth metal compound, for example. Specifically, the electron-injection buffer layer preferably includes an inorganic compound containing an alkali metal and oxygen or an inorganic compound containing an alkaline earth metal and oxygen, and further preferably includes an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer including a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) to transfer electrons smoothly.

For the electron-relay layer, a phthalocyanine-based material such as copper(II) phthalocyanine (abbreviation: CuPc) or zinc phthalocyanine (abbreviation: ZnPc), or a metal complex having a metal-oxygen bond and an aromatic ligand is preferably used.

The charge-generation region, the electron-injection buffer layer, and the electron-relay layer cannot be clearly distinguished from one another on the basis of the cross-sectional shape or properties in some cases.

The charge-generation layer may include a donor material instead of an acceptor material. For example, the charge-generation layer may include a layer including the above-described electron-transport material and donor material that can be used for the electron-injection layer.

When the charge-generation layer is provided between two light-emitting units to be stacked, an increase in driving voltage can be inhibited.

At least part of this embodiment can be implemented in appropriate combination with the other embodiments described in this specification.

(Supplementary Notes on the Description in this Specification and the Like)

The description of the above embodiments and each structure in the embodiments are noted below.

One embodiment of the present invention can be constituted by combining, as appropriate, the structure described in each embodiment and example with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

In each embodiment, content described in the embodiment is content described using a variety of diagrams or content described with text disclosed in the specification.

By combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

In this specification and the like, the terms such as “film” and “layer” can be interchanged with each other depending on the case or according to circumstances. For example, the term “conductive layer” can be replaced with the term “conductive film” in some cases. As another example, the term “insulating film” can be changed into the term “insulating layer” in some cases.

In this specification and the like, a switch has a function of controlling whether current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap each other or a region where a channel is formed.

In this specification and the like, the expression “A and B are connected” means the case where A and B are electrically connected as well as the case where A and B are directly connected. Here, the expression “A and B are electrically connected” means the case where electric signals can be transmitted and received between A and B when an object having any electric action is present between A and B.

### REFERENCE NUMERALS

30: element layer, 31: logic circuit portion, 40: element layer, 50: display control portion, 51: driver circuit portion, 52: driver circuit, 53: driver circuit, 61: display region, 62: pixel circuit, 90: element layer, 91: light-emitting device, 92: terminal portion, 99: sealing substrate, 100: semiconductor device

1. A semiconductor device comprising:
a display portion,
wherein the display portion comprises a first element layer comprising a light-emitting device and a second element layer comprising a first transistor,
wherein the second element layer is positioned below the first element layer,
wherein the first transistor comprises an oxide semiconductor in a semiconductor layer comprising a channel formation region,
wherein the first transistor is a transistor included in a pixel circuit configured to control driving of the light-emitting device, and
wherein the display portion has a diagonal size greater than or equal to 1.0 inches and less than or equal to 2.5 inches.

2. A semiconductor device comprising:
a display portion,
wherein the display portion comprises a first element layer comprising a light-emitting device and a second element layer comprising a first transistor,
wherein the second element layer is positioned below the first element layer,
wherein the first transistor comprises an oxide semiconductor in a semiconductor layer comprising a channel formation region,
wherein the first transistor is a transistor included in a pixel circuit,
wherein the light-emitting device is an organic EL element,
wherein the pixel circuit is configured to control luminance of the organic EL element, and
wherein the display portion has a diagonal size greater than or equal to 1.0 inches and less than or equal to 2.5 inches.

3. A semiconductor device comprising:
a display portion,
wherein the display portion comprises a first element layer comprising a light-emitting device, a second element layer comprising a first transistor, and a third element layer comprising a second transistor,
wherein the second element layer is positioned below the first element layer,
wherein the third element layer is positioned below the second element layer,
wherein the first transistor is a transistor included in a pixel circuit,
wherein the second transistor is a transistor included in a driver circuit,
wherein the light-emitting device is an organic EL element,
wherein the pixel circuit is configured to control luminance of the organic EL element,
wherein the driver circuit is configured to control driving of the pixel circuit, and
wherein the display portion has a diagonal size greater than or equal to 1.0 inches and less than or equal to 2.5 inches.

4. The semiconductor device according to claim 3,
wherein each of the first transistor and the second transistor comprises an oxide semiconductor in a semiconductor layer comprising a channel formation region.

5. The semiconductor device according to claim 3,
wherein the first transistor comprises an oxide semiconductor in a semiconductor layer comprising a channel formation region, and
wherein the second transistor comprises silicon in a semiconductor layer comprising a channel formation region.

6. An electronic device comprising the semiconductor device according to claim 1,
wherein the semiconductor device is provided in a housing, and
wherein the housing is provided with an operation portion and a band.

7. An electronic device comprising the semiconductor device according to claim 2,
wherein the semiconductor device is provided in a housing, and
wherein the housing is provided with an operation portion and a band.

8. An electronic device comprising the semiconductor device according to claim 3,
wherein the semiconductor device is provided in a housing, and
wherein the housing is provided with an operation portion and a band.
